(19) United States
(12) Patent Application Publication
(10) Pub. No.: US 2025/0031516 A1
(43) Pub. Date: Jan. 23, 2025

(54) DISPLAY DEVICE

(71) Applicant: Samsung Display Co., Ltd., Yongin-si (KR)

(72) Inventors: HYERIM KIM, Yongin-si (KR); GYEONGHEON KIM, Yongin-si (KR); HANBYUL JANG, Yongin-si (KR); HEEJIN KIM, Yongin-si (KR); JIHYUN SEO, Yongin-si (KR)

(21) Appl. No.: 18/639,830

(22) Filed: Apr. 18, 2024

(30) Foreign Application Priority Data
Jul. 7, 2023 (KR) 10-2023-0088093

(51) Int. Cl. H10K 50/12; C09K 11/06; H10K 50/13; H10K 85/30; H10K 101/30

(52) U.S. Cl. CPC H10K 50/12; C09K 11/06; H10K 50/13; C09K 2211/1029; C09K 2211/1044; C09K 2211/185; H10K 85/346; H10K 2101/30

(57) ABSTRACT

A display device including a circuit layer and a display element layer on the circuit layer and including a light emitting element is provided. The light emitting element includes a first electrode, a first emission layer which includes a first dopant and is provided on the first electrode, a second emission layer which includes a second dopant different from the first dopant and is provided on the first emission layer, and a second electrode provided on the second emission layer. A triplet excited state energy level (T1) of the second dopant may be higher than that of the first dopant, and the thickness of the first emission layer is about 10% to about 50% based on 100% of the sum of the thickness of the first emission layer and the thickness of the second emission layer. The display device may have improved side-surface luminance ratio and excellent display efficiency.

### CROSS-REFERENCE TO RELATED APPLICATION

This application claims priority to and the benefit of Korean Patent Application No. 10-2023-0088093, filed on Jul. 7, 2023, in the Korean Intellectual Property Office, the entire content of which is incorporated herein by reference.

### BACKGROUND

### 1. Field

The present disclosure relates to a display device including two emission layers composed of different dopants.

### 2. Description of the Related Art

The development of an organic light emitting display device as an image display device is being actively conducted. The organic light emitting display device includes a so-called “self-luminescent” light emitting element in an emission layer and including a luminescent material. Holes and electrons injected, respectively, from a first electrode and a second electrode recombine in an emission layer to generate an exciton, which then transitions (e.g., relaxes, from an excited state to a ground state) whereby the luminescent material of the emission layer emits light to implement display (e.g., of an image).

In recent years, flexible electronic devices including flexible display devices that are slidable or foldable are being developed. Unlike their rigid electronic device counterparts, flexible electronic devices may be folded, rolled, and/or bent. Because these devices may be changed in their shape, may be viewed by a user in more than one suitable viewing angle, where the display quality may vary with viewing angle, methods for improving their luminance and display efficiency are desired or required.

Implementation of light-emitting elements to flexible electronic devices requires (or there is a desire for), improvements in the light efficiency, lifespan, and/or the like of flexible display devices. Therefore, the need or desire exists for the development of materials for a light-emitting elements capable of stably achieving such characteristics or desires.

### SUMMARY

One or more aspects of embodiments of the present disclosure is directed toward a display device having improved luminance ratio in the side surface thereof and exhibiting excellent or suitable display efficiency.

According to one or more embodiments, the present disclosure provides a display device including a circuit layer and a display element layer which is provided on the circuit layer and includes a light emitting element, wherein the light emitting element includes: a first electrode; a first emission layer which includes a first dopant and is provided on the first electrode; a second emission layer which includes a second dopant different from the first dopant and is provided on the first emission layer; and a second electrode provided on the second emission layer, wherein a triplet excited state energy level (T1) of the second dopant is higher or greater than a triplet excited state energy level (T1) of the first dopant and a thickness of the first emission layer is about 10% to about 50% based on 100% of a sum of the thickness of the first emission layer and a thickness of the second emission layer.

In one or more embodiments, the second emission layer may be directly provided on the first emission layer.

In one or more embodiments, the difference between the triplet excited state energy level of the second dopant and the triplet excited state energy level of the first dopant may be at most about 0.15 electron volt (eV).

In one or more embodiments, the triplet excited state energy level of the first dopant may be about 2.05 eV to about 2.25 eV.

In one or more embodiments, the triplet excited state energy level of the second dopant may be about 2.26 eV to about 2.35 eV.

In one or more embodiments, a peak emission wavelength (λₘₐₓ) of the first dopant may be longer than a peak emission wavelength (λₘₐₓ) of the second dopant.

In one or more embodiments, the difference between the peak emission wavelength of the first dopant and the peak emission wavelength of the second dopant may be at most about 10 nanometer (nm).

In one or more embodiments, the peak emission wavelength of the first dopant may be about 520 nm to about 570 nm.

In one or more embodiments, the peak emission wavelength of the second dopant may be about 500 nm to about 560 nm.

In one or more embodiments, a highest occupied molecular orbital (HOMO) energy level of the first dopant may be higher or greater than a highest occupied molecular orbital (HOMO) of the second dopant.

In one or more embodiments, the difference between the HOMO energy level of the first dopant and the HOMO energy level of the second dopant may be at most about 0.25 eV.

In one or more embodiments, the HOMO energy level of the first dopant may be about −4.50 eV to about −4.40 eV.

In one or more embodiments, the HOMO energy level of the second dopant may be about −4.70 eV to about −4.55 eV.

In one or more embodiments, an overlap degree of an emission spectrum of the first dopant and a spectrum tristimulus value may be greater than an overlap degree of an emission spectrum of the second dopant and the spectrum tristimulus value.

In one or more embodiments, at least one of the first dopant or the second dopant may include a metal complex compound including (e.g., containing) platinum (Pt) as a central metal.

In one or more embodiments, one (e.g., a first one) of the first dopant or the second dopant may include a first metal complex compound containing platinum (Pt) as a central metal, and the other (e.g., a second one of the first dopant or the second dopant) may include a second metal complex compound including (e.g., containing) platinum (Pt), iridium (Ir), titanium (Ti), cobalt (Co), copper (Cu), zinc (Zn), zirconium (Zr), ruthenium (Ru), rhodium (Rh), palladium (Pd), rhenium (Re), gold (Au), or osmium (Os) as a central metal.

In one or more embodiments, the first dopant may include a compound represented by Formula DA-1.

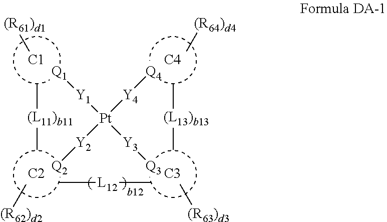

In Formula DA-1, Q₁ to Q₄ may each independently be C or N, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms, Y1 to Y4 may each independently be a direct linkage, *—O—*, *—S—*, a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, L₁₁ to L₁₃ may each independently be a direct linkage,

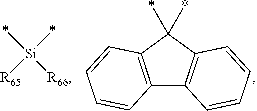

*—O—*, *—S—*, a substituted or unsubstituted divalent amine group, a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or may be bonded to an adjacent group to form a ring, and d1 to d4 may each independently be an integer of 0 to 4.

In one or more embodiments, the light emitting element may further include: a charge generation layer provided between the first electrode and the first emission layer; and a third emission layer provided between the first electrode and the charge generation layer, and the difference between a peak emission wavelength of the third emission layer and a peak emission wavelength of the second emission layer may be at most about 10 nm.

In one or more embodiments, the light emitting element may further include: a charge generation layer provided between the second emission layer and the second electrode; and a third emission layer provided between the charge generation layer and the second electrode, and the difference between a peak emission wavelength of the third emission layer and the peak emission wavelength of the second emission layer may be at most about 10 nm.

In one or more embodiments, the display device may have a side-surface luminance ratio of at least about 41.0.

In one or more embodiments, the display device may include at least one folding axis and the display device may be divided into a folding region which is foldable between (e.g., with respect to) the at least one folding axis and a non-folding region adjacent to the folding region.

In one or more embodiments of the present disclosure, a display device includes a circuit layer and a display element layer which is provided on the circuit layer and includes a first light emitting element, a second light emitting element, and a third light emitting element spaced and/or apart in one direction perpendicular to the thickness direction, wherein the first light emitting element emits (e.g., is to emit) a first light, the second light emitting element emits (e.g., is to emit) a second light having a wavelength shorter than a wavelength of the first light, and the third light emitting element emits (e.g., is to emit) a third light having a wavelength shorter than the wavelength of the second light, the second light emitting element includes: a first electrode; a first emission layer which includes a first dopant and is provided on the first electrode; a second emission layer which includes a second dopant different from the first dopant and is provided on the first emission layer; and a second electrode provided on the second emission layer, wherein a triplet excited state energy level (T1) of the second dopant is greater or higher than a triplet excited state energy level (T1) of the first dopant and a thickness of the first emission layer is about 10% to about 50% based on 100% of a sum of the thickness of the first emission layer and a thickness of the second emission layer.

In one or more embodiments, the display device may have a side-surface luminance ratio of at least about 41.0.

### BRIEF DESCRIPTION OF THE DRAWINGS

The preceding and other features of the disclosure will become more apparent by describing in further detail embodiments thereof with reference to the accompanying drawings, which are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view illustrating a display device of one or more embodiments of the present disclosure;

FIG. 2 is a cross-sectional view illustrating the display device of one or more embodiments of the present disclosure;

FIG. 3 is a cross-sectional view illustrating a light emitting element according to one or more embodiments of the present disclosure;

FIG. 4 is a cross-sectional view illustrating a light emitting element according to one or more embodiments of the present disclosure;

FIG. 5 is a cross-sectional view illustrating a light emitting element according to one or more embodiments of the present disclosure;

FIG. 6 is a cross-sectional view illustrating a light emitting element according to one or more embodiments of the present disclosure;

FIG. 7 is a cross-sectional view illustrating a light emitting element according to one or more embodiments of the present disclosure;

FIG. 8 is a cross-sectional view illustrating a light emitting element according to one or more embodiments of the present disclosure;

FIG. 9 is a cross-sectional view illustrating a light emitting element according to one or more embodiments of the present disclosure;

FIG. 10 is a cross-sectional view illustrating a light emitting element according to one or more embodiments of the present disclosure;

FIG. 11 is a cross-sectional view illustrating a light emitting element according to one or more embodiments of the present disclosure;

FIG. 12 is a cross-sectional view illustrating a display device of one or more embodiments of the present disclosure;

FIG. 13 is a cross-sectional view illustrating a display device of one or more embodiments of the present disclosure;

FIG. 14 is a cross-sectional view illustrating a display device of one or more embodiments of the present disclosure;

FIG. 15 is a cross-sectional view illustrating a display device of one or more embodiments of the present disclosure;

FIG. 16A is a perspective view illustrating an unfolded state of an electronic device according to one or more embodiments of the present disclosure;

FIG. 16B is a perspective view illustrating a folding operation of the electronic device according to one or more embodiments of the present disclosure;

FIG. 16C is a perspective view illustrating a folding operation of the electronic device according to one or more embodiments of the present disclosure;

FIG. 17 is an exploded perspective view of the electronic device according to one or more embodiments of the present disclosure; and

FIG. 18 is a view illustrating the inside of a vehicle in which display devices of one or more embodiments of the present disclosure are provided.

### DETAILED DESCRIPTION

Hereinafter, a preferred embodiment according to the disclosure is described in more detail with reference to the accompanying drawings. It should be noted that in the following description, only portions necessary for understanding an operation according to the disclosure are described, and descriptions of other portions are omitted in order not to obscure the subject matter of the disclosure. The present disclosure may be modified in many alternate forms, and thus specific embodiments will be exemplified in the drawings and described in more detail in the detailed description. It should be understood, however, that it is not intended to limit the present disclosure to the particular forms disclosed, but rather, is intended to cover all modifications, equivalents, and alternatives falling within the spirit and scope of the present disclosure.

In the present specification, when a component (or a region, a layer, a portion, and/or the like) is referred to as being “on,” “connected to,” or “coupled to” another component, it refers to that the component may be directly provided on/connected to/coupled to the other component, or that a third component may be provided therebetween.

Like reference numerals refer to like components throughout, and duplicative descriptions thereof may not be provided. Also, in the drawings, the thicknesses, ratios, and dimensions of the components are exaggerated for effective description of technical contents. The term “and/or” includes all of one or more combinations that can be defined by associated items.

It will be understood that, although the terms “first,” “second,” and/or the like may be utilized herein to describe one or more suitable components, these components should not be limited by these terms. These terms are only utilized to distinguish one component from another. For example, a first component could be termed a second component, and, similarly, a second component could be termed a first component, without departing from the scope of the present disclosure. The terms of a singular form may include plural forms unless the context clearly indicates otherwise.

Throughout the specification, in a case where a certain portion “includes”, the case refers to that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations. The terms of a singular form include plural forms unless otherwise specified. For example, “a,” “an,” and “the” are intended to include the plural forms as well, unless the context clearly indicates otherwise.

In some embodiments, terms such as “below,” “under,” “on,” and “above” may be utilized to describe the relationship between components illustrated in the drawings. The terms are utilized as a relative concept and are described with reference to the direction indicated in the drawings.

It should be understood that the terms “comprise,” “comprises,” “comprising,” “has,” “having,” “have,” “include,” “includes,” and/or “including,” are intended to specify the presence of stated features, integers, steps, operations, components, parts, or combinations thereof in the specification, but do not preclude the presence or addition of one or more other features, integers, steps, operations, components, parts, or combinations thereof.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The term “and/or” includes all combinations of one or more of the associated listed elements.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “in a lower portion of” another layer, film, region, or plate, it can be not only directly under the layer, film, region, or plate, but intervening layers, films, regions, or plates may also be present. In some embodiments, it will be understood that when a part is referred to as being “on” another part, it can be provided above the other part, or provided under the other part as well.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component”, “component’-free”, and/or the like refers to that the “component” not being added, selected or utilized as a component in the composition, but the “component” of less than a suitable amount may still be included due to other impurities and/or external factor.

Unless otherwise defined, all terms (including chemical, technical and scientific terms) utilized herein have the same meaning as commonly understood by one of ordinary skill in the art to which the present disclosure belongs. In some embodiments, it will be understood that terms, such as those defined in commonly utilized dictionaries, should be interpreted as having a meaning that is consistent with their meaning in the context of the relevant art and will not be interpreted in an idealized or overly formal sense unless expressly so defined herein.

### Definitions

In the present disclosure, when particles are spherical, “diameter” indicates an average particle diameter, and when the particles are non-spherical, the “diameter” indicates a major axis length. The diameter (or size) of the particles may be measured by particle size analysis, dynamic light scattering, scanning electron microscopy, and/or transmission electron microscope photography. When the size of the particles is measured utilizing a particle size analyzer, the average particle diameter (or size) may be referred to as D50. The term “D50” as utilized herein refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. Particle size analysis may be performed with a HORIBA LA-950 laser particle size analyzer.

In the specification, the term “substituted or unsubstituted” may refer to that a group is unsubstituted or substituted with at least one substituent selected from the group consisting of a deuterium atom, a halogen atom, a cyano group, a nitro group, an amine group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “an adjacent group” may refer to a substituent substituted at an atom which is directly linked to an atom substituted with a corresponding substituent, another substituent substituted at an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbon atoms in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. The number of carbon atoms in the alkynyl group is not specifically limited, but is 2 to 30, 2 to 20, or 2 to 10. Specific examples of the alkynyl group may include an ethynyl group, a propynyl group, and/or the like, but the embodiment of the present disclosure is not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group and has the concept including a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

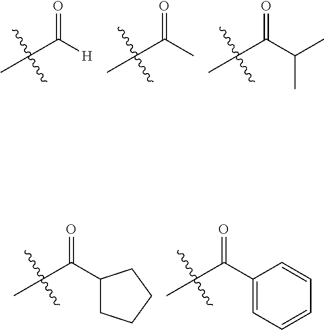

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

In the specification, a boryl group may refer to that a boron atom is bonded to the alkyl group or the aryl group as defined herein. The boron group includes an alkyl boron group and an aryl boron group. Examples of the boron group may include a dimethylboron group, a diethylboron group, a t-butylmethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group among an alkylthio group, an alkylsulfoxy group, an alkylaryl group, an alkylamino group, an alkyl phosphorus group, an alkyl silyl group, and an alkyl amine group is the same as the examples of the alkyl group as described herein.

In the specification, the aryl group among an aryloxy group, an arylthio group, an arylsulfoxy group, an arylamino group, an arylboron group, an arylsilyl group, an arylamine group is the same as the examples of the aryl group as described herein.

In the specification, a direct linkage may refer to a single bond. In the specification, “

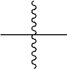

”and “ [symbol] ” refer to a position to be linked.

### Display Device

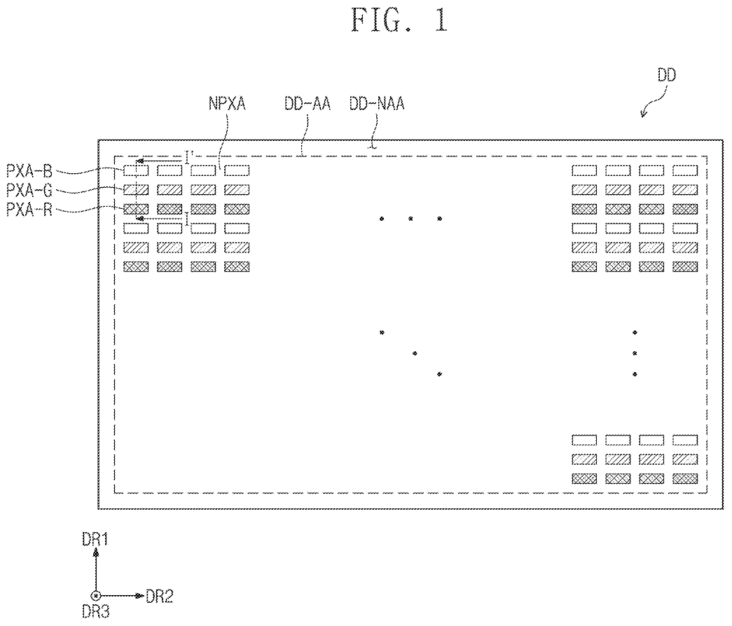

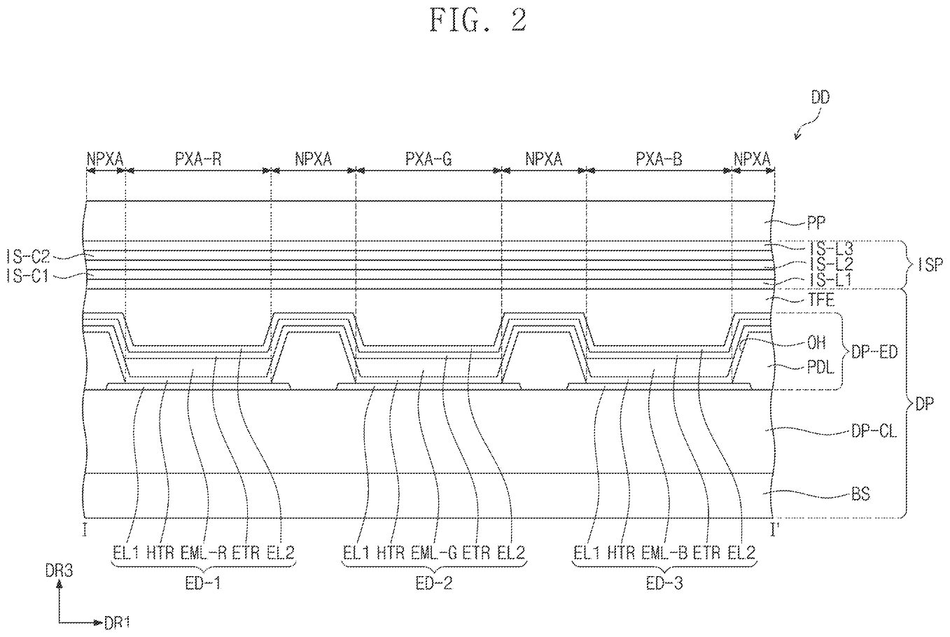

Hereinafter, embodiments of the present disclosure will be described with reference to the accompanying drawings. FIG. 1 is a plan view of the display device DD of one or more embodiments. FIG. 2 is a cross-sectional view illustrating the display device DD of the embodiment. FIG. 2 is a cross-sectional view illustrating a part taken along line I-I′ of FIG. 1.

The display device DD of one or more embodiments may include a display panel DP. In some embodiments, the display device DD may further include an input sensing layer ISP provided on the display panel DP and an optical layer PP provided on the input sensing layer ISP. The display device DD may include light emitting elements ED-1, ED-2, and ED-3.

The display panel DP may include a base layer BS, a circuit layer DP-CL provided on the base layer BS, a display element layer DP-ED provided on the circuit layer DP-CL, and an encapsulation layer TFE provided on the display element layer DP-ED.

The base layer BS may be a member providing a base surface on which the circuit layer DP-CL is provided. The base layer BS may be a flexible substrate which is bendable, foldable, or rollable. The base layer BS may be a glass substrate, a metal substrate, or a polymer substrate. However, the embodiment of the present disclosure is not limited thereto, and the base layer BS may include an inorganic layer, an organic layer, or a composite material layer.

The base layer BS may include a single layer or multiple layers. For example, the base layer BS may include a first synthetic resin layer, a multi-layered or single-layered inorganic layer, and a second synthetic resin layer provided on the multi-layered or single-layered inorganic layer. Each of the first and second synthetic resin layers may include a polyimide-based resin. Also, each of the first and second synthetic resin layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, the term “something-based” resin refers to including a functional group of “something.”

The circuit layer DP-CL is provided on the base layer BS, and the circuit layer DP-CL may include an insulation layer, a semiconductor pattern, a conductive pattern, a signal line, and/or the like. For example, the circuit layer DP-CL may include a switching transistor and a driving transistor for driving light emitting elements ED-1, ED-2, and ED-3 of the display element layer DP-ED.

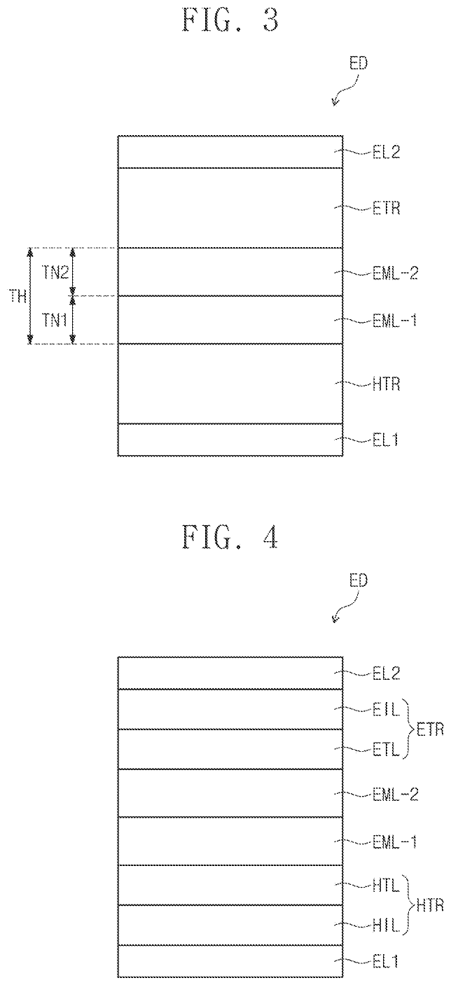

The display element layer DP-ED may include a pixel defining film PDL and the light emitting elements ED-1, ED-2, and ED-3. Each of the light emitting elements ED-1, ED-2, and ED-3 may have a structure of each light emitting element ED according to FIGS. 3 to 10, which will be described later. Each of the light emitting elements ED-1, ED-2, and ED-3 may include a first electrode EL1, a hole transport region HTR, emission layers EML-R, EML-G, and EML-B, an electron transport region ETR, and a second electrode EL2.

Referring to FIG. 2, the emission layers EML-R, EML-G, and EML-B of the light emitting elements ED-1, ED-2, and ED-3 may be provided in an opening OH defined in the pixel defining film PDL. The hole transport region HTR, the electron transport region ETR, and the second electrode EL2 may be provided as a common layer throughout the light emitting elements ED-1, ED-2, ED-3. However, the embodiment of the present disclosure is not limited thereto, and unlike the configuration illustrated in FIG. 2, the hole transport region HTR and the electron transport region ETR may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2 and ED-3. The encapsulation layer TFE may seal the display element layer DP-ED. The encapsulation layer TFE may be provided on the second electrode EL2 and may be provided filling the openings OH.

The encapsulation layer TFE may be a thin film encapsulation layer. The encapsulation layer TFE may be a single layer or formed by stacking a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The input sensing layer ISP may be provided on the display panel DP. The input sensing layer ISP may sense an external input, convert the external input to a set or predetermined input signal, and provide the input signal to the display panel DP. For example, in the display device DD of one or more embodiments, the input sensing layer ISP may be a touch sensing unit that senses a touch. The input sensing layer ISP may recognize a user's direct touch, a user's indirect touch, a direct touch of an object, an indirect touch of an object, and/or the like.

The input sensing layer ISP may sense at least one of a location or force (pressure) of the externally applied touch. The display panel DP may receive an input signal from the input sensing layer ISP, and generate an image corresponding to the input signal. For example, the input sensing layer ISP may sense the external input in a capacitive manner. However, this is example, and a driving manner of the input sensing layer ISP is not limited to any one embodiment.

The input sensing layer ISP may be formed on the display panel DP through a substantially continuous process. In this case, the input sensing layer ISP may be directly provided on the display panel DP. For example, a separate adhesive member may not be provided between the input sensing layer ISP and the display panel DP. In some embodiments, the input sensing layer ISP may be coupled to the display panel DP through the adhesive member. The adhesive member may include a typical adhesive or pressure adhesive.

In the specification, that one component is directly provided on another component refers to that a third component is not provided between one component and another component. For example, that one component is directly provided on another component refers to that one component is in contact with another component.

The input sensing layer ISP may include a base insulating layer IS-L1, a first conductive layer IS-C1 provided on the base insulating layer IS-L1, a first insulating layer IS-L2 provided on the first conductive layer IS-C1, a second conductive layer IS-C2 provided on the first insulating layer IS-L2, and a second insulating layer IS-L3 provided on the second conductive layer IS-C2. Unlike the configuration illustrated, the base insulating layer IS-L1 may not be provided.

Each of the base insulating layer IS-L1, the first insulating layer IS-L2, and the second insulating layer IS-L3 may include a single layer or multiple layers. Each of the base insulating layer IS-L1, the first insulating layer IS-L2, and the second insulating layer IS-L3 may include an organic material or inorganic material. Each of the base insulating layer IS-L1, the first insulating layer IS-L2, and the second insulating layer IS-L3 may include at least one of silicon nitride, silicon oxynitride, or silicon oxide. In some embodiments, each of the base insulating layer IS-L1, the first insulating layer IS-L2, and the second insulating layer IS-L3 may include an epoxy-based resin, an acrylic-based resin, or an imide-based resin.

Each of the first conductive layer IS-C1 and the second conductive layer IS-C2 may include a single layer or multiple layers. Each of the first conductive layer IS-C1 and the second conductive layer IS-C2 may include a metal layer or a transparent conductive layer as a single layer. The metal layer may include molybdenum (Mo), silver (Ag), titanium (Ti), copper (Cu), aluminum (AI), or an alloy thereof. The transparent conductive layer may include a transparent conductive oxide such as indium tin oxide (ITO), indium zinc oxide (IZO), or indium tin zinc oxide (ITZO). In some embodiments, the transparent conductive layer may include a conductive polymer such as PEDOT, a metal nanowire, graphene, and/or the like.

Each of the first conductive layer IS-C1 and the second conductive layer IS-C2 may include a three-layered structure of ITO/Ag/ITO. In some embodiments, each of the first conductive layer IS-C1 and the second conductive layer IS-C2 may include at least one metal layer and at least one transparent conductive layer.

The optical layer PP may be provided on the input sensing layer ISP. When the input sensing layer ISP is not included, the optical layer PP may be provided on the display panel DP. The optical layer PP may control reflected light in the display panel DP due to external light. The optical layer PP may include, for example, a polarization layer or a color filter layer. In some embodiments, unlike the configuration illustrated in the drawings, the optical layer PP may not be provided.

Referring to FIGS. 1 and 2, an active region DD-AA and a peripheral region DD-NAA may be defined in the display device DD. The active region DD-AA may be a region which is activated in response to an electrical signal. The peripheral region DD-NAA may be a region that is located to be adjacent to at least one side of the active region DD-AA. The peripheral region DD-NAA may be provided around (e.g., surrounding) the active region DD-AA. However, the embodiment of the present disclosure is not limited thereto, and unlike the configuration illustrated, a part of the peripheral region DD-NAA may not be provided. A driving circuit or a driving wiring for driving the active region DD-AA may be arranged in the peripheral region DD-NAA.

The active region DD-AA may include a non-light emitting region NPXA and light emitting regions PXA-R, PXA-G and PXA-B. Each of the light emitting regions PXA-R, PXA-G, and PXA-B may be a region in which light generated by the respective light emitting elements ED-1, ED-2, and ED-3 is emitted. The light emitting regions PXA-R, PXA-G, and PXA-B may be spaced and/or apart from each other on a plane.

Each of the light emitting regions PXA-R, PXA-G, and PXA-B may be a region divided (defined) by the pixel defining film PDL. The non-light emitting regions NPXA may be regions between the adjacent light emitting regions PXA-R, PXA-G, and PXA-B, which correspond to the pixel defining film PDL. In the specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be provided in openings OH defined in the pixel defining film PDL and separated from each other. At least one among the emission layers EML-R, EML-G, and EML-B of the light emitting elements ED-1, ED-2, and ED-3 may include a first emission layer EML-1 (see FIG. 3) and a second emission layer EML-2 (see FIG. 3) which will be described later.

The light emitting regions PXA-R, PXA-G, and PXA-B may be divided into a plurality of groups according to the colors of light generated from the light emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light emitting elements ED-1, ED-2 and ED-3 may be to emit light beams having wavelengths different from each other. In one or more embodiments, the display device DD may include a first light emitting element ED-1, a second light emitting element ED-2, and a third light emitting element ED-3 spaced and/or apart from each other in a first direction DR1 perpendicular to a third direction DR3. The first light emitting element ED-1 may be to emit first light, the second light emitting element ED-2 may be to emit second light having a wavelength shorter than a wavelength of the first light, and the third light emitting element ED-3 may be to emit third light having a wavelength shorter than a wavelength of the second light. For example, the first light emitting element ED-1 may be to emit red light, the second light emitting element ED-2 may be to emit green light, and the third light emitting element ED-3 may be to emit blue light. The second light emitting element ED-2 may include the first emission layer EML-1 (see FIG. 3) and the second emission layer EML-2 (see FIG. 3) as described elsewhere herein. The red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit light beams in substantially the same wavelength range or at least one light emitting element may be to emit a light beam in a wavelength range different from the others. For example, the first to third light emitting elements ED-1, ED-2, and ED-3 may all emit blue light.

The light emitting regions PXA-R, PXA-G, and PXA-B in the display device DD may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In some embodiments, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD.

In some embodiments, the areas of the respective light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

The drawings such as FIG. 1 illustrate the first to third directional axes DR1, DR2, and DR3, and the directions indicated by the first to third directional axes DR1, DR2 and DR3 described in this specification are relative concepts and may be converted into other directions. In some embodiments, the directions indicated by the first to third directions DR1, DR2 and DR3 may be described as first to third directions, and the same reference symbols may be utilized. In the specification, the first directional axis DR1 and the second directional axis DR2 are orthogonal to each other, and the third directional axis DR3 may be the normal direction with respect to the plane defined by the first directional axis DR1 and the second directional axis DR2.

The thickness direction of the display device DD may be a direction parallel to the third directional axis DR3. An upper side (or an upper surface) and a lower side (or a lower surface) may be defined with respect to the third directional axis DR3. The cross-section refers to a surface parallel to the thickness direction DR3, and the plane refers to a surface perpendicular to the thickness direction DR3. The plane refers to a plane defined by the first directional axis DR1 and the second direction axis DR2.

FIGS. 3 to 7 are cross-sectional views schematically illustrating light emitting elements ED according to embodiments. The light emitting element ED according to one or more embodiments may include a first electrode EL1, a first emission layer EML-1 provided on the first electrode EL1, a second emission layer EML-2 provided on the first emission layer EML-1, and a second electrode EL2 provided on the second emission layer EML-2. In some embodiments, the light emitting element ED may further include a hole transport region HTR provided between the first electrode EL1 and the first emission layer EML1, and an electron transport region ETR provided between the second emission layer EML-2 and the second electrode EL2.

In one or more embodiments, the first emission layer EML-1 may include a first dopant, and the second emission layer EML-2 may include a second dopant different from the first dopant. The triplet excited state energy level (T1) of the second dopant may be higher or greater than a triplet excited state energy level (T1) of the first dopant. The thickness TN1 of the first emission layer EML-1 may be about 50% or less based on 100% of the total thickness TH of the first and second emission layers EML-1 and EML-2. Accordingly, the display device DD including the first emission layer EML-1 and the second emission layer EML-2 may exhibit excellent or suitable display quality and display efficiency. The first emission layer EML-1 and the second emission layer EML-2 are described in more detail elsewhere herein.

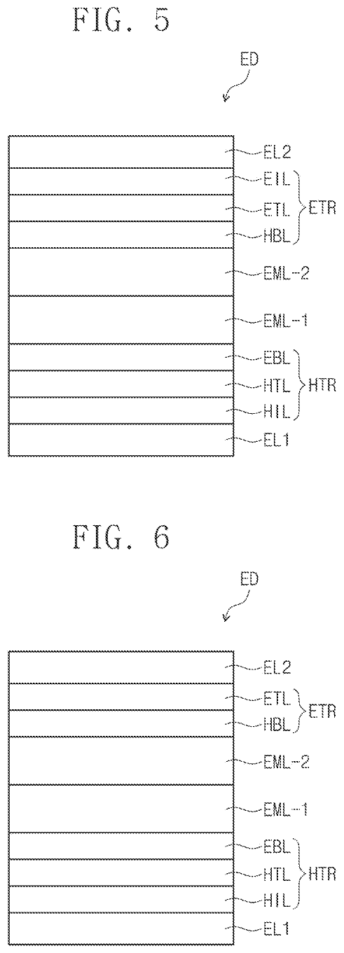

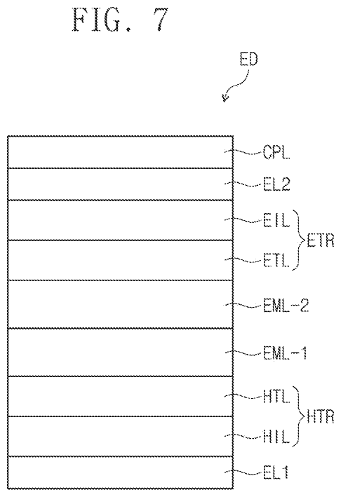

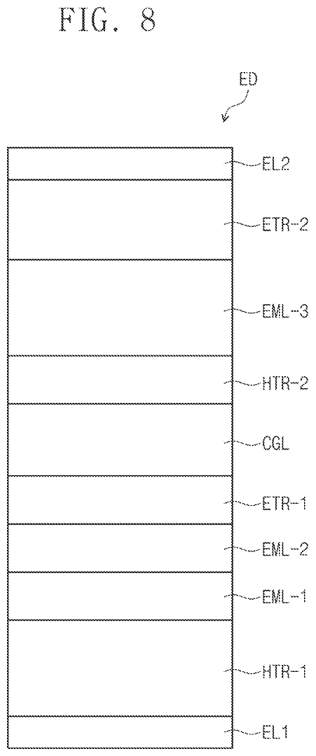

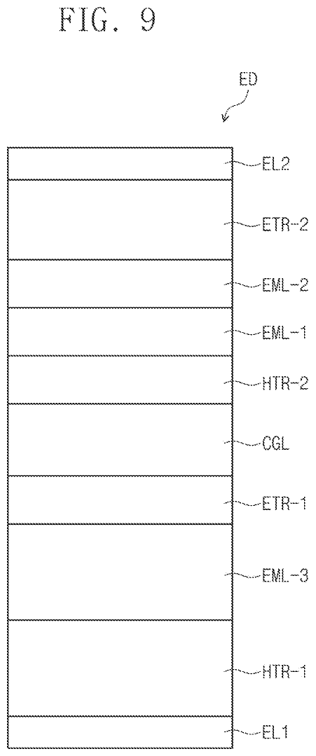

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 3, FIG. 6 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron transport layer ETL and a hole blocking layer HBL. Compared with FIG. 4, FIG. 7 illustrates a cross-sectional view of a light emitting element ED of one or more embodiments including a capping layer CPL provided on a second electrode EL2.

The first emission layer EML-1 including the first dopant may be provided to be adjacent to the hole transport region HTR, and the second emission layer EML-2 including the second dopant may be provided to be adjacent to the electron transport region ETR. For example, the first emission layer EML-1 may be provided to be adjacent to the electron blocking layer EBL, and the second emission layer EML-2 may be provided to be adjacent to the hole blocking layer HBL. The second emission layer EML-2 may be directly provided on the first emission layer EML-1. The first emission layer EML-1 may be in contact with the second emission layer EML-2. A separate functional layer (e.g., a hole transport region, an electron transport region, a charge generation layer, and/or the like) may not be provided between the first emission layer EML-1 and the second emission layer EML-2.

The first emission layer EML-1 may include the first dopant, and the second emission layer EML-2 may include the second dopant that is different from the first dopant. Each of the first dopant and the second dopant may include a metal complex compound in which a ligand is bonded to a central metal. The central metal of the first dopant may be the same as or different from the central metal of the second dopant. At least one of the first dopant or the second dopant may include a metal complex compound containing platinum (Pt) as a central metal. For example, one (e.g., a first one) among the first dopant or the second dopant may include a first metal complex compound including (e.g., containing) platinum (Pt) as a central metal, and the other (a second one of the first dopant or the second dopant) may include a second metal complex compound including (e.g., containing) platinum (Pt), iridium (Ir), titanium (Ti), cobalt (Co), copper (Cu), zinc (Zn), zirconium (Zr), ruthenium (Ru), rhodium (Rh), palladium (Pd), rhenium (Re), gold (Au), or osmium (Os) as a central metal.

The first dopant may include a compound represented by Formula DA-1. The first emission layer EML-1 may include a compound represented by Formula DA-1. The compound represented by Formula DA-1 may be the metal complex compound containing platinum (Pt) as a central metal.

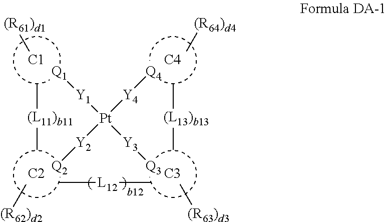

In Formula DA-1, Q₁ to Q₄ may each independently be C or N. For example, Q₁ and Q₃ may be N, and Q₂ and Q₄ may be C. In some embodiments, Q₁ and Q₃ may be C, and Q₂ and Q₄ may be N.

C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms. For example, C1 to C4 may each independently be a substituted or unsubstituted phenyl group, a substituted or unsubstituted pyridine group, or a substituted or unsubstituted imidazole group.

Y₁ to Y₄ may each independently be a direct linkage, *—O—*, *—S—*, a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. For example, Y₁ to Y₄ may each independently be a direct linkage or *—O—*. In Y₁ to Y₄, “—*” refers to a position linked to platinum (Pt) and Q₁ to Q₄.

L₁₁ to L₁₃ may each independently be a direct linkage,*—O—*, *—S—*,

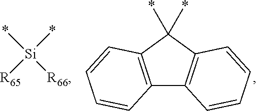

a substituted or unsubstituted divalent amine, group, a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” refers to a position linked to C1 to C4.

b11 to b13 may each independently be 0 or 1. When b11 is 0, C1 and C2 may not be linked to each other. When b12 is 0, C2 and C3 may not be linked to each other. When b13 is 0, C3 and C4 may not be linked to each other.

R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R61 to R66 may be a hydrogen atom, a substituted or unsubstituted isopropyl group, a substituted or unsubstituted n-butyl group, a substituted or unsubstituted t-butyl group, or a substituted or unsubstituted phenyl group. However, this is only an example, and the embodiments of the present disclosure are not limited thereto.

d1 to d4 may each independently be an integer of 0 to 4. When d1 is an integer of 2 or greater, a plurality of R₆₁'s may be the same as each other or at least one may be different from the others. When d1 is 0, the compound represented by Formula DA-1 may not be substituted with R₆₁. The case where d1 is 4 and four R₆₁'s are hydrogen atoms may be the same as the case where d1 is 0. When d2 is an integer of 2 or greater, a plurality of R₆₂'s may be the same as each other or at least one may be different from the others. When d2 is 0, the compound represented by Formula DA-1 may not be substituted with R₆₂. The case where d2 is 4 and four R₆₂'s are hydrogen atoms may be the same as the case where d2 is 0. When d3 is an integer of 2 or greater, a plurality of R₆₃'s may be the same as each other or at least one may be different from the others. When d3 is 0, the compound represented by Formula DA-1 may not be substituted with R₆₃. The case where d3 is 4 and four R₆₃'s are hydrogen atoms may be the same as the case where d3 is 0. When d4 is an integer of 2 or greater, a plurality of R₆₄'s may be the same as each other or at least one may be different from the others. When d4 is 0, the compound represented by Formula DA-1 may not be substituted with R₆₄. The case where d4 is 4 and four R₆₄'s are hydrogen atoms may be the same as the case where d4 is 0.

The first compound may include any one selected from among the compounds in Compound Group 1. The first emission layer EML-1 may include any one selected from among the compounds in Compound Group 1:

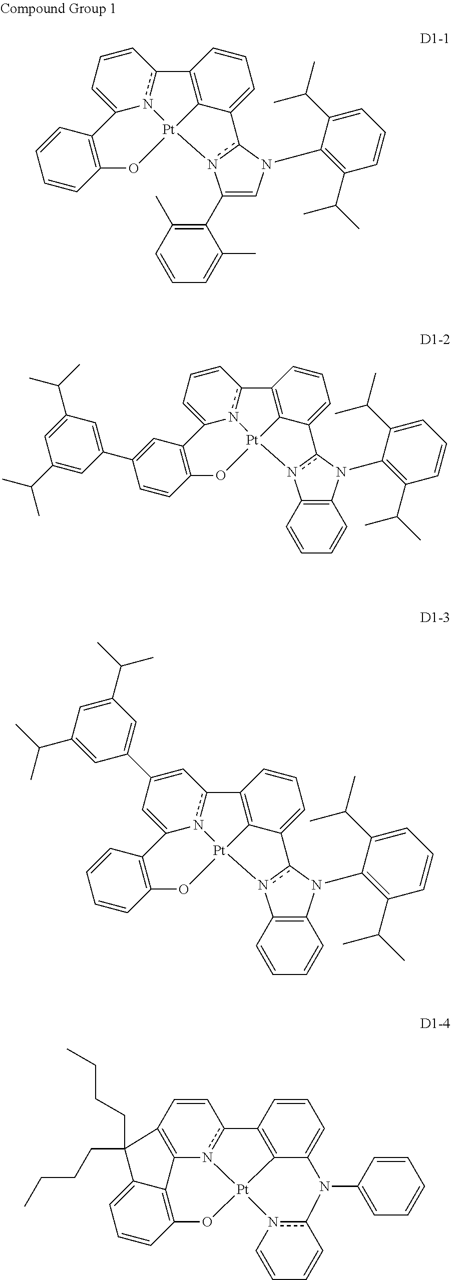

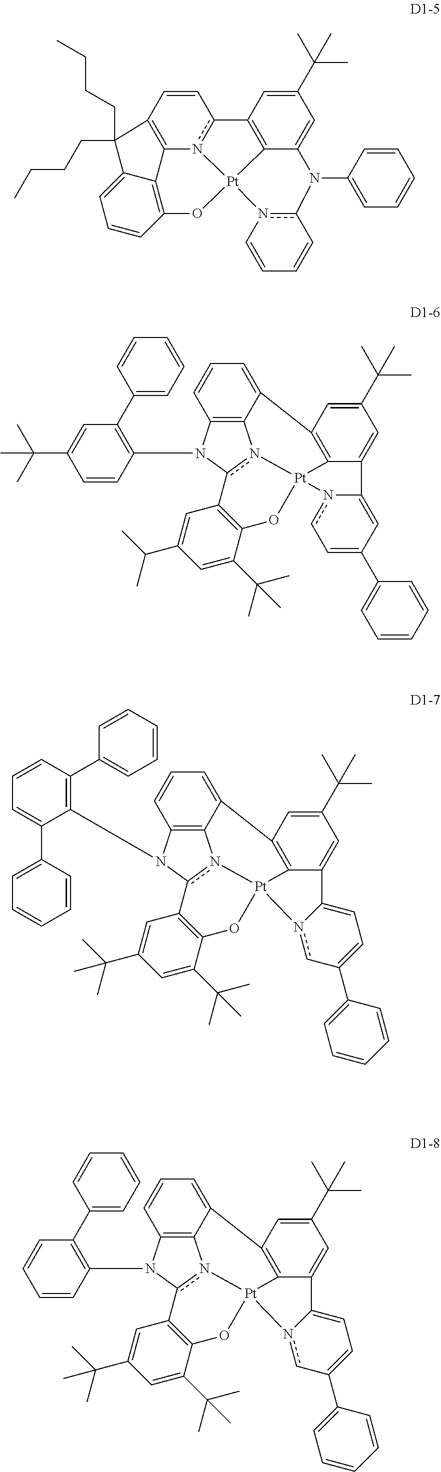

The second dopant may include any one selected from among the compounds in Compound Group 2. The second emission layer EML-2 may include any one selected from among the compounds in Compound Group 2:

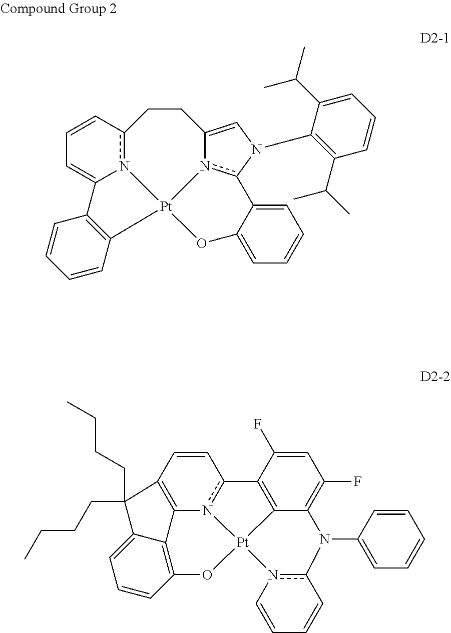

Table 1 shows peak emission wavelengths (λmax), highest occupied molecular orbital (HOMO) energy levels, and triplet excited state energy levels (T1) of the compounds shown in Compound Groups 1 and 2.

TABLE 1

| Compound | λₘₐₓ (nm) | HOMO (eV) | T1 (eV) |
|---|---|---|---|
| D1-1 | 529 | −4.45 | 2.14 |
| D1-2 | 549 | −4.45 | 2.08 |
| D1-3 | 540 | −4.50 | 2.10 |
| D1-4 | 532 | −4.47 | 2.18 |
| D1-5 | 540 | −4.45 | 2.16 |
| D1-6 | 548 | −4.44 | 2.20 |
| D1-7 | 550 | −4.45 | 2.12 |
| D1-8 | 543 | −4.46 | 2.12 |
| D2-1 | 516 | −4.59 | 2.27 |
| D2-2 | 504 | −4.70 | 2.26 |

The first dopant may be a highly efficient phosphorescent dopant. An emission spectrum of the first dopant may have a large degree of overlap with a spectrum tristimulus value. An emission spectrum of the second dopant may have a small degree of overlap with the spectrum tristimulus value. Accordingly, the first dopant may be a phosphorescent dopant that achieves relatively high efficiency, and the second dopant may serve to adjust a side-surface luminance ratio.

The display device DD (see FIG. 1) including the first emission layer EML-1 including the first dopant that is a highly efficient phosphorescent dopant and the second emission layer EML-2 including the second dopant that serves to adjust the side-surface luminance ratio may have an improved side-surface luminance ratio and exhibit excellent or suitable display efficiency. The display device DD (see FIG. 1) including the first emission layer EML-1 and the second emission layer EML-2 may exhibit excellent or suitable display quality.

As the light has straightness, in a display device implementing light, brightness and/or color varies with an angle at which the display device is viewed. A comparable display device shows relatively low luminance in the side surface when the luminance in the front surface of the display device is compared with the luminance in the side surface of the display device. The comparable display device has a large change in luminance according to the viewing angle, and shows luminance that is lowered in the side surface.

In the comparable display device, only a single emission layer including a highly efficient phosphorescent dopant is provided in order to improve efficiency, and in this case, the side-surface luminance ratio is reduced. As the emission spectrum of the phosphorescent dopant more greatly (e.g., much) overlaps the spectrum tristimulus value, the efficiency increases, but the side-surface luminance ratio decreases. In contrast, the display device DD of one or more embodiments may include the first emission layer EML-1 including the first dopant that is a highly efficient phosphorescent dopant and the second emission layer EML-2 including the second dopant that serves to adjust the side-surface luminance ratio, thereby improving the side-surface luminance ratio and exhibiting excellent or suitable display efficiency.

In one or more embodiments, a triplet excited state energy level (T1) of the second dopant may be higher or greater than a triplet excited state energy level (T1) of the first dopant. The triplet excited state energy level (T1) of the first dopant may be about 2.05 eV to about 2.25 eV. The triplet excited state energy level (T1) of the second dopant may be about 2.26 eV to about 2.35 eV. A difference between the triplet excited state energy level (T1) of the second dopant and the triplet excited state energy level (T1) of the first dopant may be about 0.15 eV or less. The difference between the triplet excited state energy level (T1) of the second dopant and the triplet excited state energy level (T1) of the first dopant may be greater than about 0.0 eV. For example, the difference between the triplet excited state energy level (T1) of the second dopant and the triplet excited state energy level (T1) of the first dopant may be about 0.01 eV or more.

A peak emission wavelength (λₘₐₓ) of the first dopant may be longer than a peak emission wavelength (λₘₐₓ) of the second dopant. The peak emission wavelength (λₘₐₓ) may refer to a wavelength representing the highest intensity in the emission spectrum of the dopant. The peak emission wavelength (λₘₐₓ) of the first dopant may be about 520 nm to about 570 nm. The peak emission wavelength (λₘₐₓ) of the second dopant may be about 500 nm to about 560 nm. The difference between the peak emission wavelength (λₘₐₓ) of the first dopant and the peak emission wavelength (λₘₐₓ) of the second dopant may be about 10 nm or less. The difference between the peak emission wavelength (λₘₐₓ) of the first dopant and the peak emission wavelength (λₘₐₓ) of the second dopant may be greater than about 0 nm. For example, the difference between the peak emission wavelength (max) of the first dopant and the peak emission wavelength (λₘₐₓ) of the second dopant may be about 1 nm or more.

A highest occupied molecular orbital (HOMO) energy level of the first dopant may be higher or greater than a highest occupied molecular orbital (HOMO) that of the second dopant. As the HOMO energy level is a negative number, an absolute value of the HOMO energy level of the first dopant may be smaller than an absolute value of the HOMO energy level of the second dopant. The HOMO energy level of the first dopant may be shallower (e.g., smaller or less than) than the HOMO energy level of the second dopant.

The HOMO energy level of the first dopant may be about −4.50 eV to about-4.40 eV. The HOMO energy level of the second dopant may be about −4.70 eV to about −4.55 eV. A difference between the HOMO energy level of the first dopant and the HOMO energy level of the second dopant may be about 0.25 eV or less. The difference between the HOMO energy level of the first dopant and the HOMO energy level of the second dopant may be greater than about 0.00 eV. For example, the difference between the HOMO energy level of the first dopant and the HOMO energy level of the second dopant may be about 0.01 eV or more.

As described herein, the emission spectrum of the first dopant may have a large degree of overlap with the spectrum tristimulus value. Thus, the peak emission wavelength (λₘₐₓ) of the first dopant may be longer than that of the second dopant. The peak emission wavelength of the second dopant serving to adjust the side-surface luminance ratio may be a relatively short wavelength. The HOMO energy level of the first dopant may be higher or greater than that of the second dopant. The triplet excited state energy level (T1) of the second dopant may be higher or greater than that of the first dopant. The display device DD (see FIG. 1) including the first and second emission layers EML-1 and EML-2 including the first and second dopants satisfying the peak emission wavelength range/differences as described herein, the HOMO energy level range/differences as described herein, and/or the triplet excited state energy level range/differences as described herein may exhibit excellent or suitable display efficiency and excellent or suitable display quality.

In one or more embodiments, a thickness TN1 of the first emission layer EML-1 may be about 10% to about 50% based on 100% of a total thickness TH of the first and second emission layers EML-1 and EML-2. The total thickness TH of the first and second emission layers EML-1 and EML-2 may be obtained by adding the thickness TN1 of the first emission layer EML-1 and the thickness TN2 of the second emission layer EML-2. For example, the thickness TN1 of the first emission layer EML-1 may be about 15% to 50% based on 100% of the total thickness TH of the first and second emission layers EML-1 and EML-2. The thickness TN1 of the first emission layer EML-1 may be about 50 angstrom (Å) to about 165 Å. However, this is example, and the thickness TN1 value of the first emission layer EML-1 is not limited thereto.

The display device DD (see FIG. 1) including the first emission layer EML-1 satisfying the herein-described thickness range based on 100% of the total thickness TH of the first emission layers EML-1 and EML-2 may exhibit excellent or suitable side-surface luminance ratio and excellent or suitable display efficiency. In contrast, the side-surface luminance ratio of the display device including the first emission layer EML-1 of which the thickness is greater than about 50% based on 100% of the total thickness TH of the first emission layers EML-1 is reduced. The side-surface luminance ratio refers to a luminance ratio in the side surface at 45° with respect to the front surface. The front surface may have an angle of 90°.

When the thickness TN1 of the first emission layer EML-1 is greater than about 50% based on 100% of the total thickness TH of the first and second emission layers EML-1 and EML-2, the thickness TN2 of the second emission layer EML-2 is relatively reduced. Accordingly, the characteristics of improving the side-surface luminance ratio of the second emission layer EML-2 including the second dopant is not expressed, and the side-surface luminance ratio of the display device DD (see FIG. 1) is reduced. Also, based on 100% of the total thickness TH of the first and second emission layers EML-1 and EML-2, the first emission layer EML-1 having a thickness TN1 of less than about 10% may not achieve high efficiency, and thus the display efficiency of the display device DD (see FIG. 1) is reduced. On the other hand, in one or more embodiments, the display device DD (see FIG. 1) including the first emission layer EML-1 having a thickness TN1 of about 10% to about 50% based on 100% of the total thickness TH of the first emission layers EML-1 may have improvements in the side-surface luminance ratio and display efficiency.

Each of the first emission layer EML-1 and the second emission layer EML-2 may include a single host or a plurality of hosts. When each of the first emission layer EML-1 and the second emission layer EML-2 includes a single host, the host included in the first emission layer EML-1 may be the same as or different from the host included in the second emission layer EML-2. When one of the first emission layer EML-1 and the second emission layer EML-2 includes a single host and the other one includes a plurality of hosts, the single host may be the same as any one among the plurality of hosts. On the other hand, when one of the first emission layer EML-1 and the second emission layer EML-2 includes a single host and the other includes a plurality of hosts, the single host may be different from the plurality of hosts. When each of the first emission layer EML-1 and the second emission layer EML-2 includes a plurality hosts, the plurality of hosts included in the first emission layer EML-1 and the plurality of hosts included in the second emission layer EML-2 may be the same as each other or at least one may be different from others.

Each of the first emission layer EML-1 and the second emission layer EML-2 may include at least one of a first host compound represented by Formula HT-1, or a second host compound represented by Formula ET-1. The first host compound represented by Formula HT-1 may be a hole transporting host material.

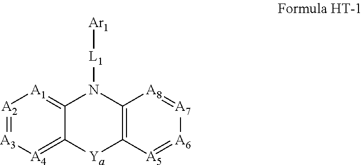

In Formula HT-1, A₁ to A₈ may each independently be N or CR₅₁. For example, all of A₁ to A₈ may be CR₅₁. In some embodiments, any one among A₁ to A₈ may be N, and the rest may be CR₅₁.

L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, or a substituted or unsubstituted divalent carbazole group. However, this is example, and the embodiment of the present disclosure is not limited thereto.

Yₐ may be a direct linkage, CR₅₂R₅₃, or SiR₅₄R₅₅. For example, the two benzene rings linked to the nitrogen atom in Formula HT-1 are linked via a direct linkage,

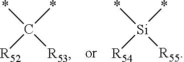

In Formula HT-1, when Yₐ is a direct linkage, the first host compound represented by Formula HT-1 may include a carbazole moiety.

Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, or a substituted or unsubstituted biphenyl group. However, this is example, and the embodiment of the present disclosure is not limited thereto.

R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₅₁ to R₅₅ may each independently be a hydrogen atom, a deuterium atom, or an unsubstituted methyl group, or an unsubstituted phenyl group. However, this is example, and the embodiment of the present disclosure is not limited thereto.

The first host compound represented by Formula HT-1 may be represented by any one selected from among compounds represented in Compound Group HT. For example, the first emission layer EML-1 and/or the second emission layer EML-2 may include at least one selected from among the compounds represented in Compound Group HT as a hole transporting host material. In Compound Group HT, D refers to a deuterium atom, and Ph refers to an unsubstituted phenyl group.

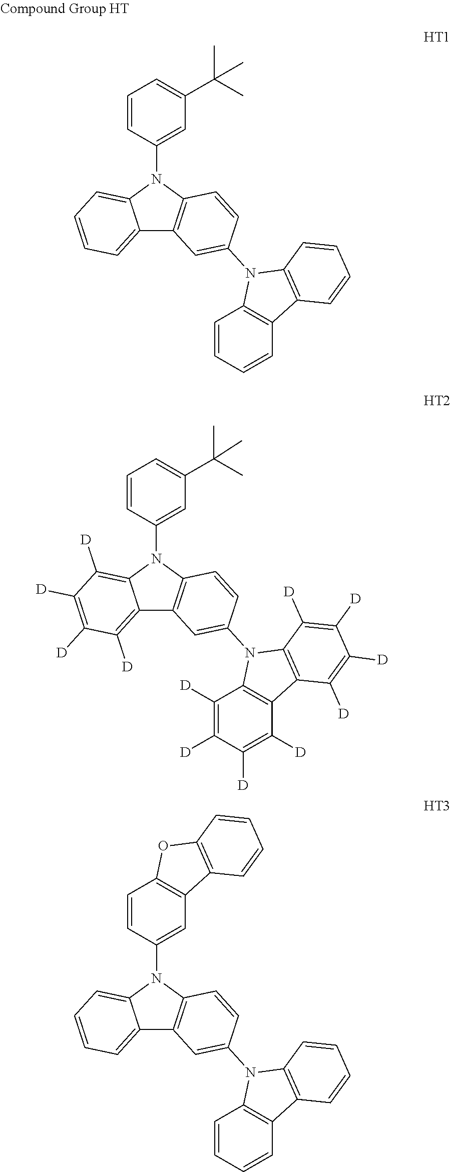

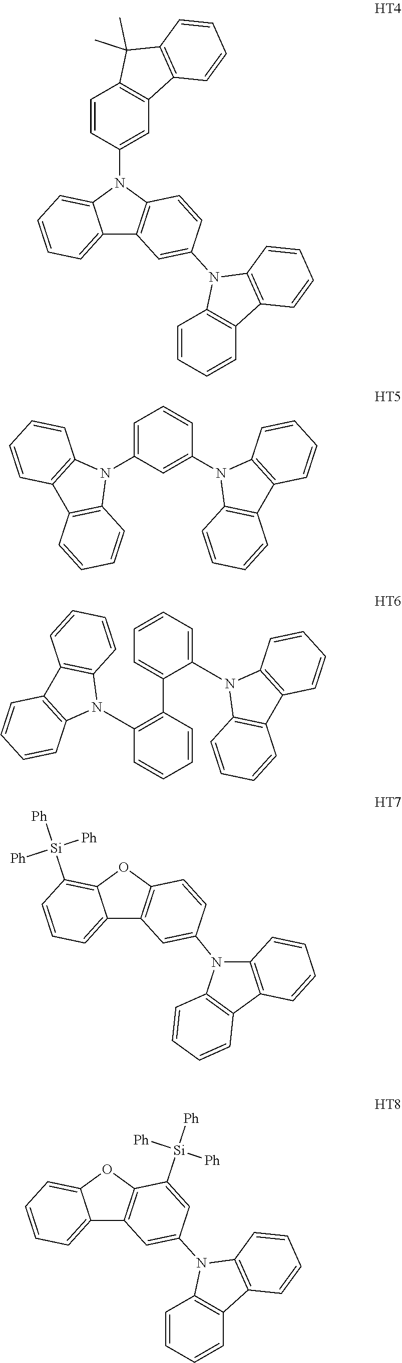

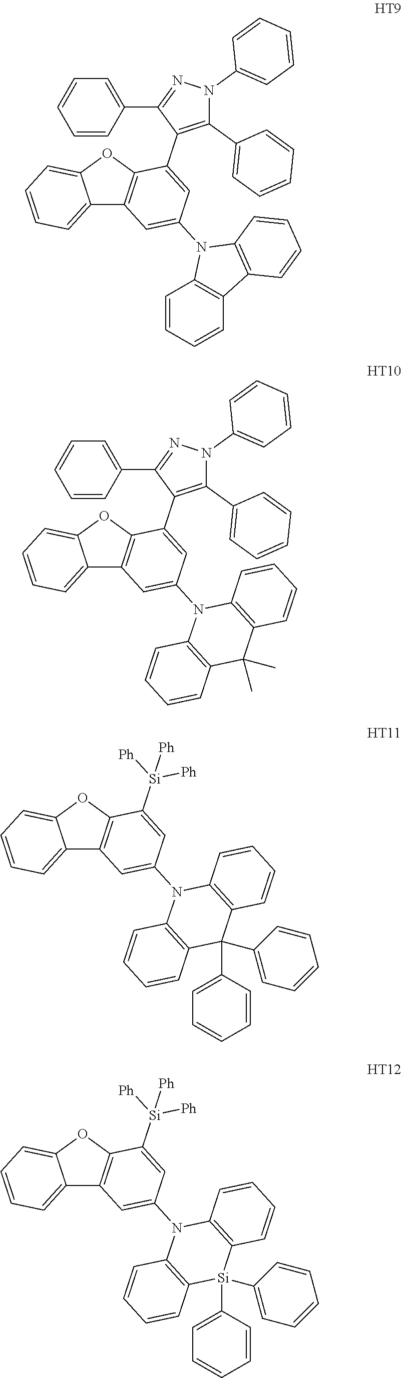

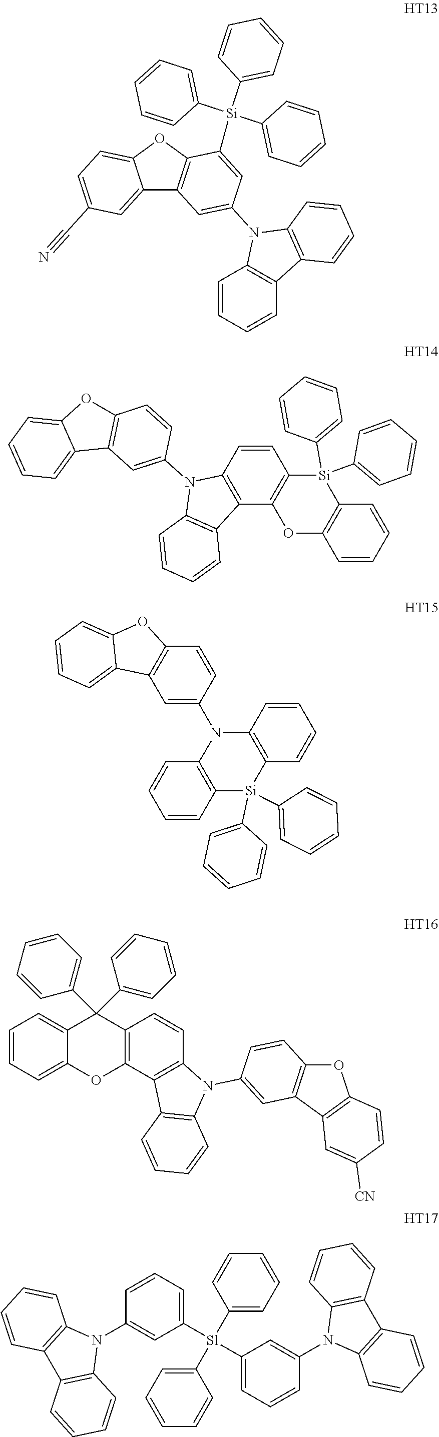

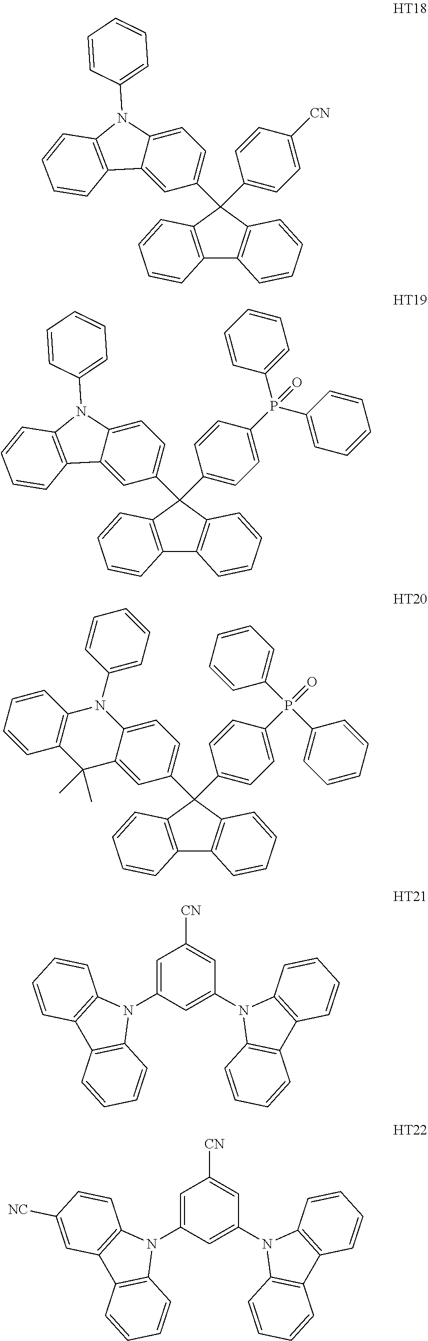

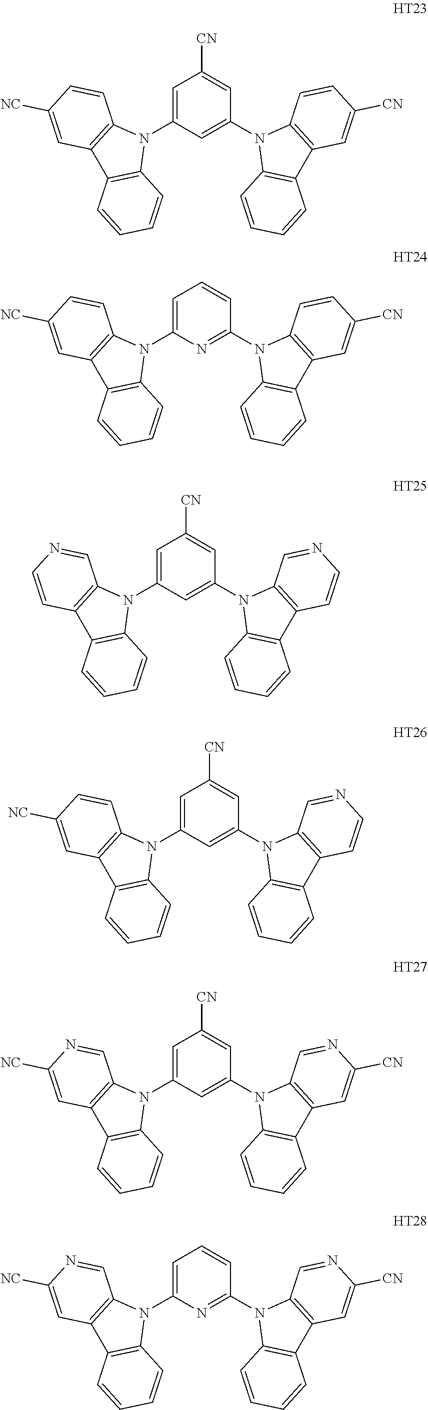 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

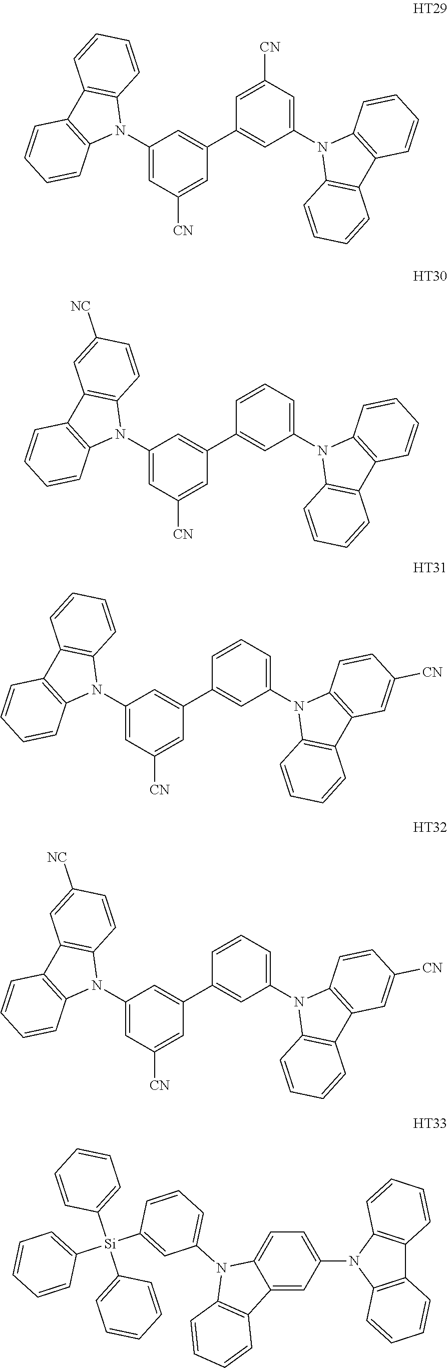 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

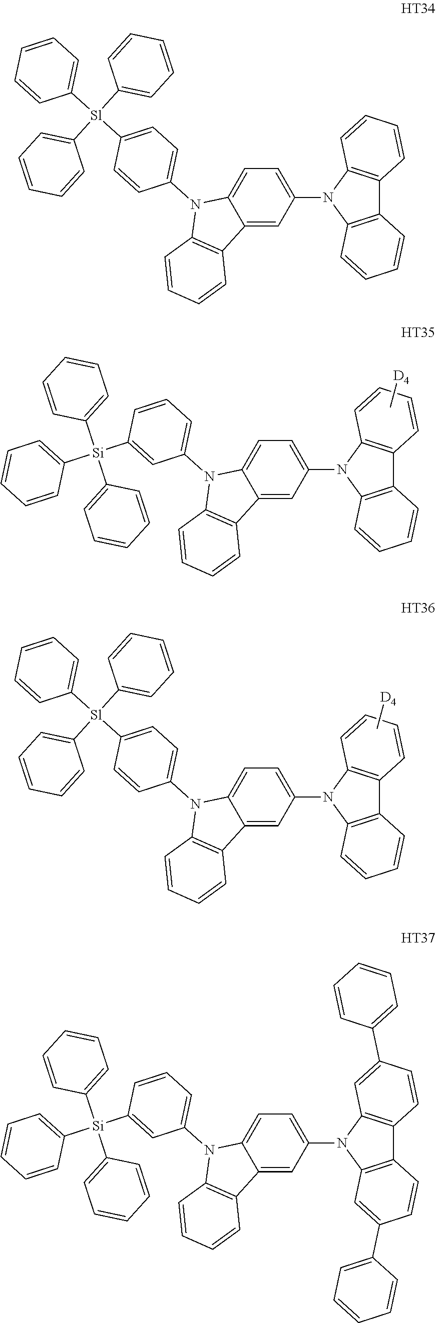

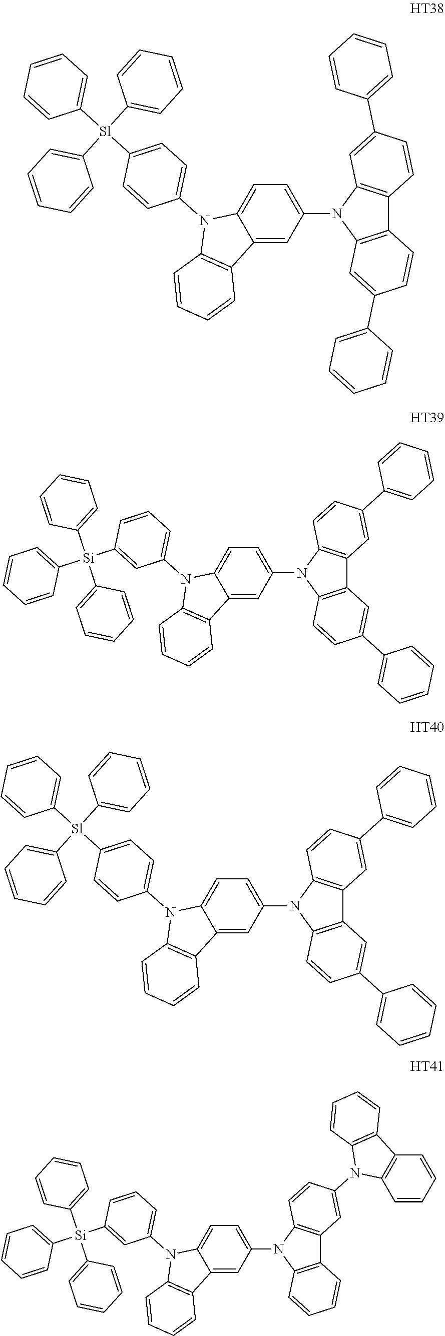

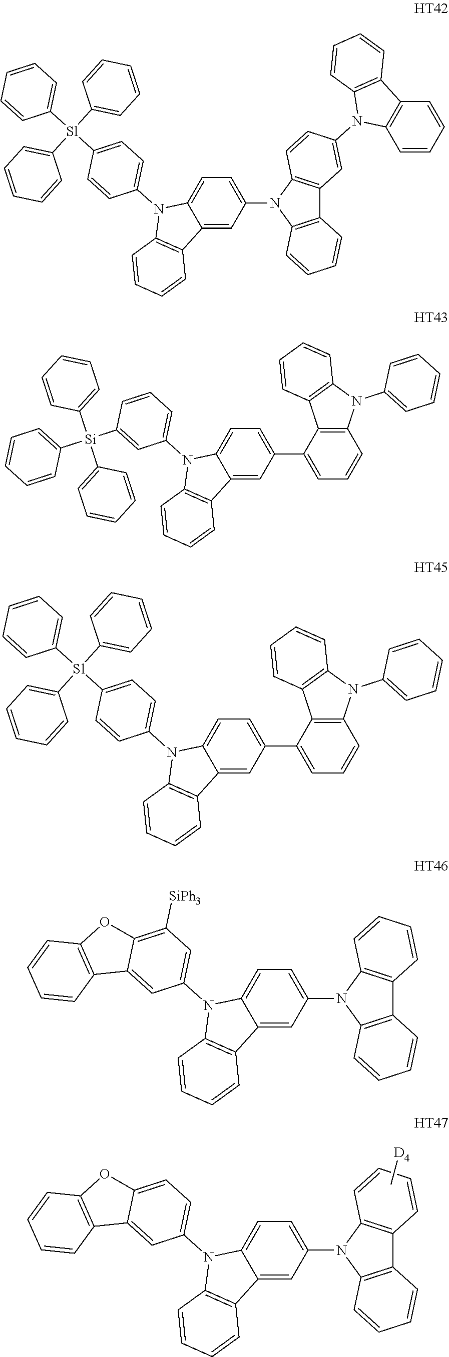

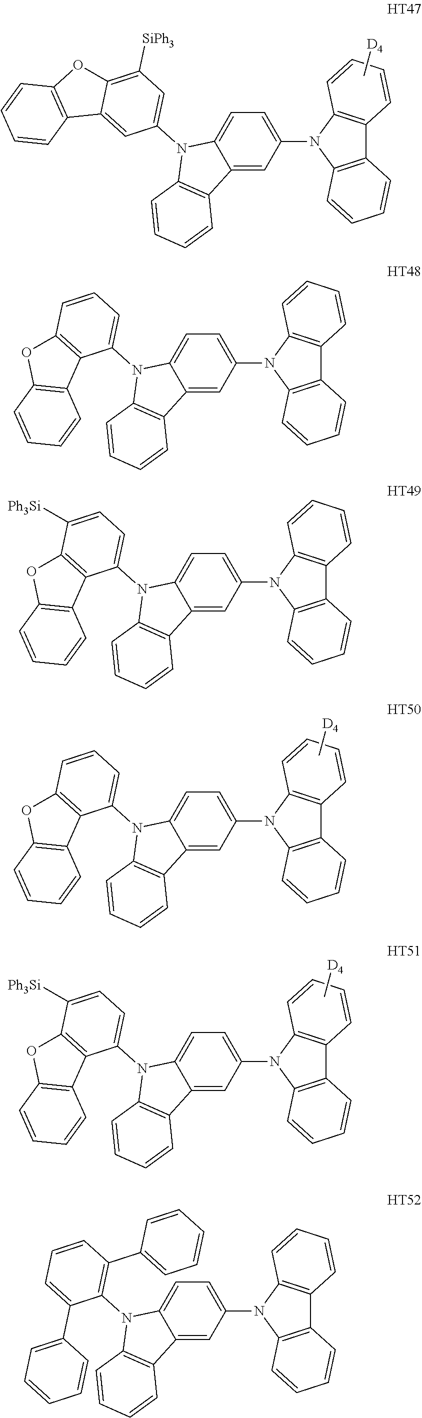

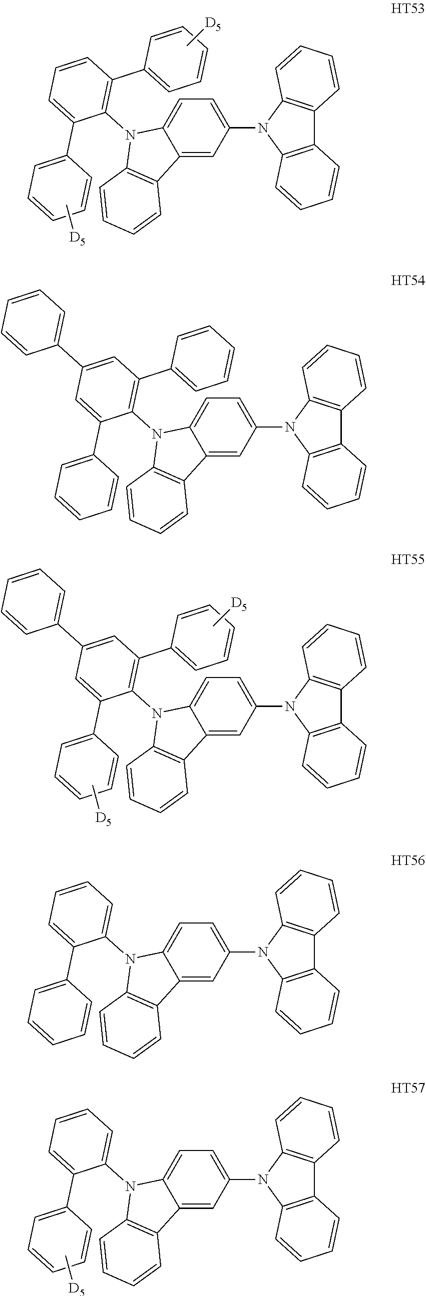

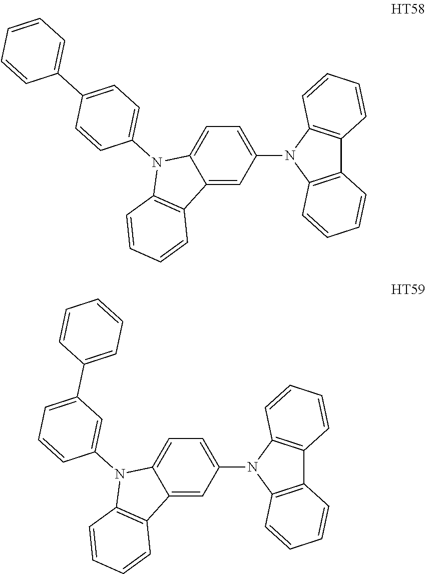 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

The second host compound represented by Formula ET-1 may be an electron transporting host material. The second host compound represented by Formula ET-1 may include a nitrogen-containing ring group as a central structure.

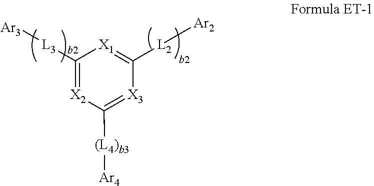

In Formula ET-1, at least one selected from among X₁ to X₃ may be N, and the rest (e.g., each of the remaining X₁ to X₃) may be CR₅₆. For example, one selected from among X₁ to X₃ may be N, and the rest (e.g., each of the remaining X₁ to X₃) may each independently be CR₅₆. In this case, the second host compound represented by Formula ET-1 may include a pyridine moiety. In some embodiments, two among X₁ to X₃ may be N, and the one remaining X₁ to X₃ may be CR₅₆. In this case, the second host compound represented by Formula ET-1 may include a pyrimidine moiety. In some embodiments, X₁ to X₃ may all be N. In this case, the second host compound represented by Formula ET-1 may include a triazine moiety. R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

b1 to b3 may each independently be an integer of 0 to 10. L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 is an integer of 2 or greater, L₂ is a substituted or unsubstituted arylene group having 6 to 30 ring-forming carbon atoms, or a substituted or unsubstituted heteroarylene group having 2 to 30 ring-forming carbon atoms. When b2 is an integer of 2 or greater, L₃ is a substituted or unsubstituted arylene group having 6 to 30 ring-forming carbon atoms, or a substituted or unsubstituted heteroarylene group having 2 to 30 ring-forming carbon atoms. When b3 is an integer of 2 or greater, L₄ is a substituted or unsubstituted arylene group having 6 to 30 ring-forming carbon atoms, or a substituted or unsubstituted heteroarylene group having 2 to 30 ring-forming carbon atoms.

The second host compound may be represented by any one selected from among compounds in Compound Group ET. The first emission layer EML-1 and/or the second emission layer EML-2 may include at least one selected from among the compounds represented in Compound Group ET as an electron transporting host material. In Compound Group ET, D refers to a deuterium atom, and Ph refers to an unsubstituted phenyl group.

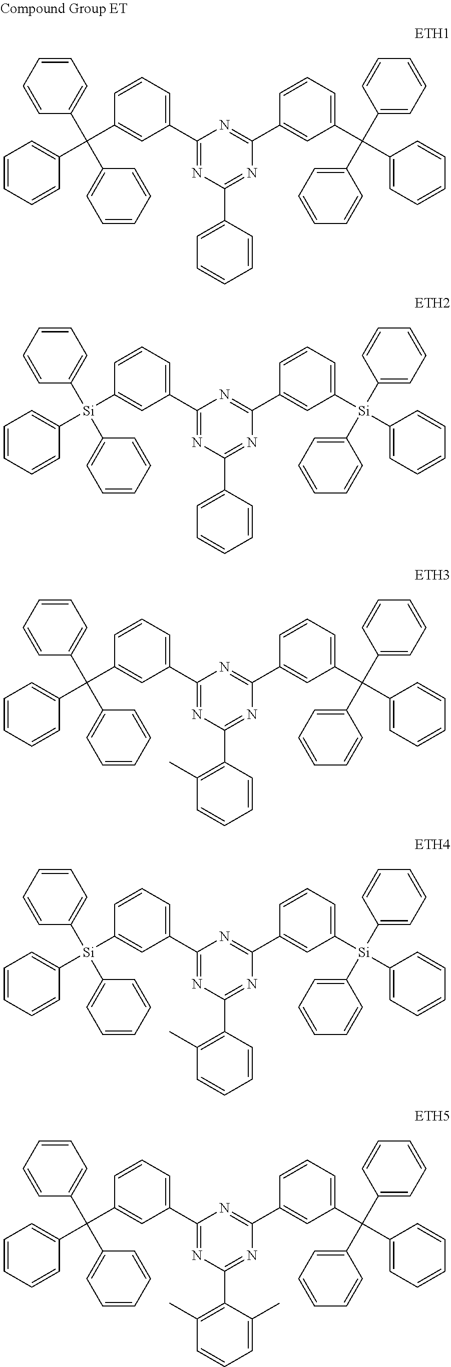

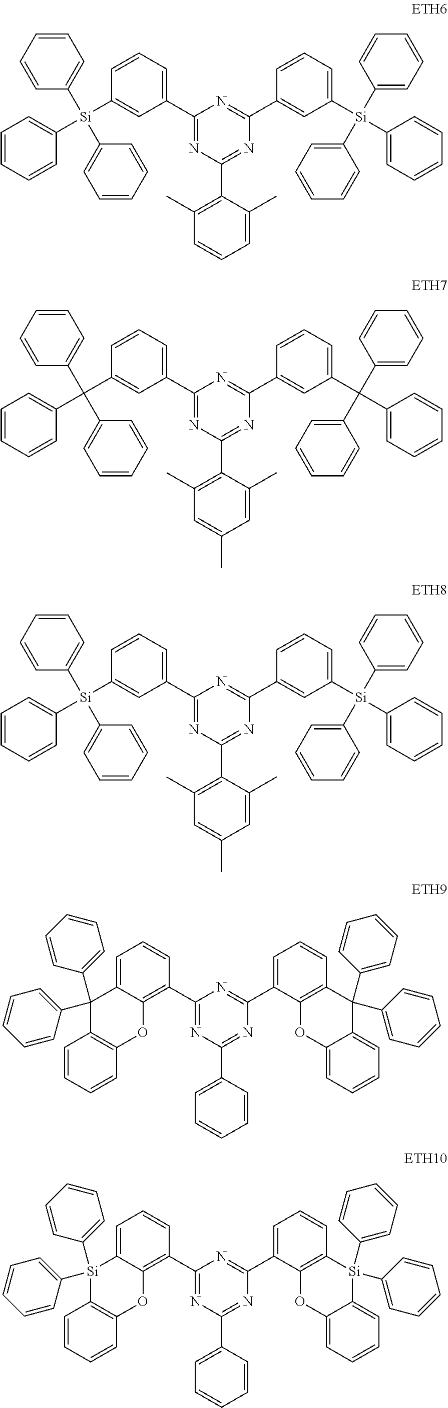

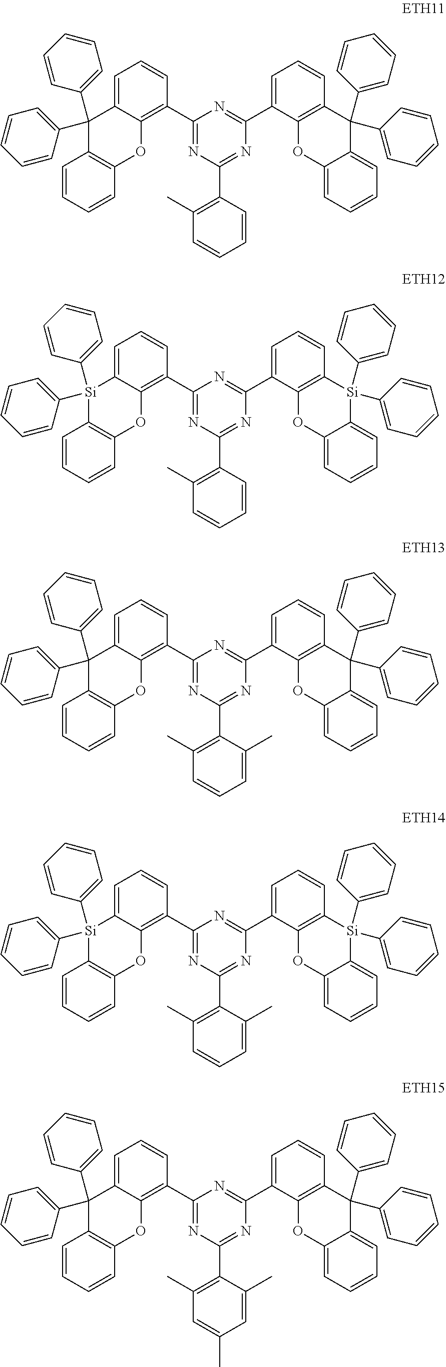

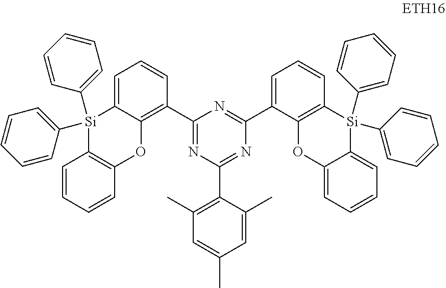 [SMILES: Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

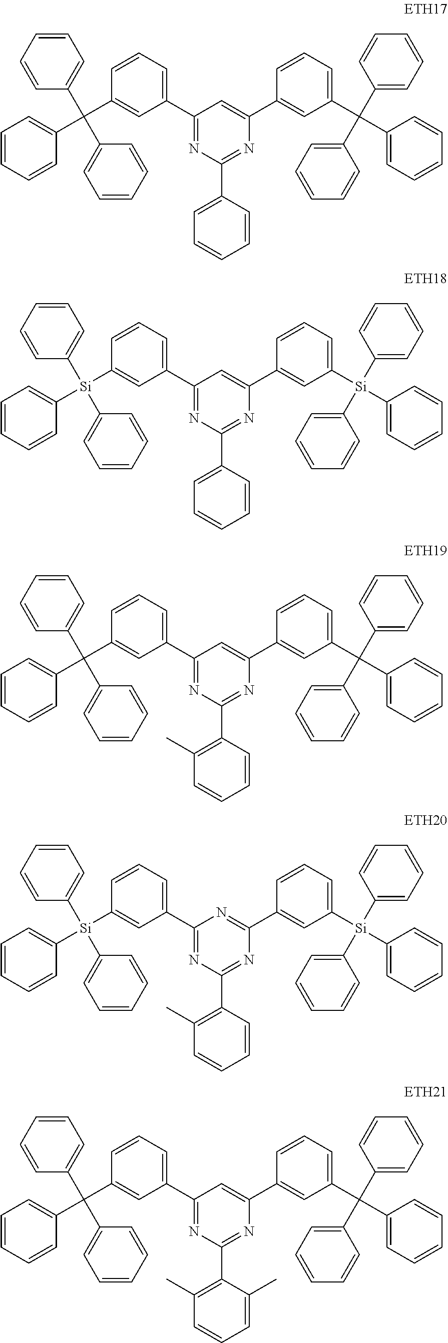

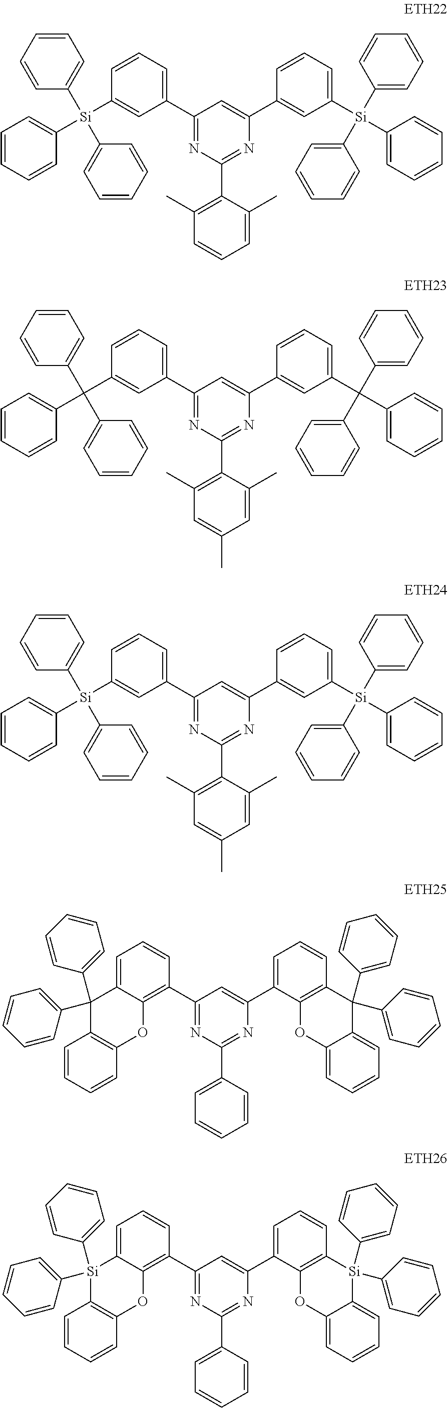

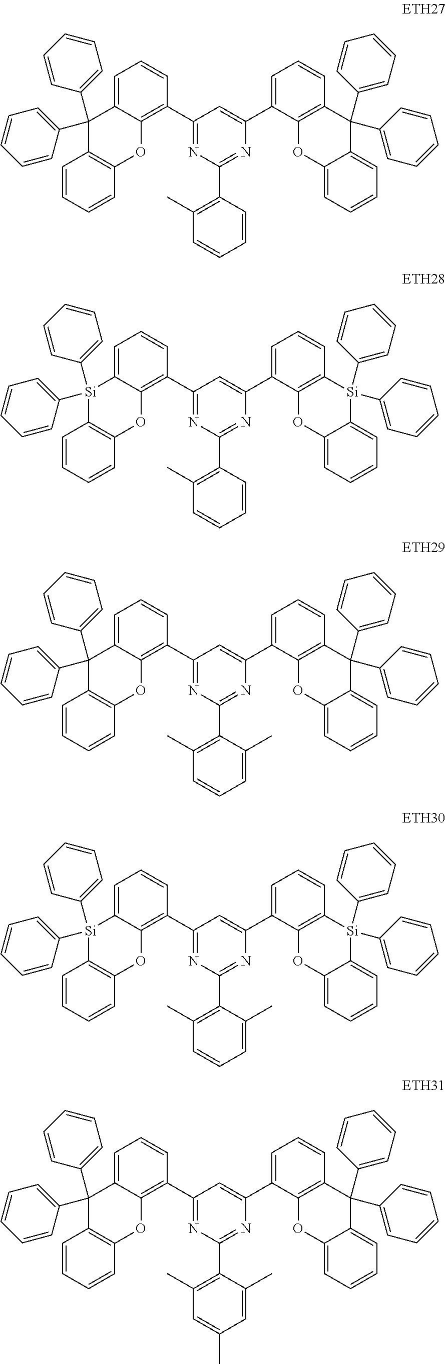

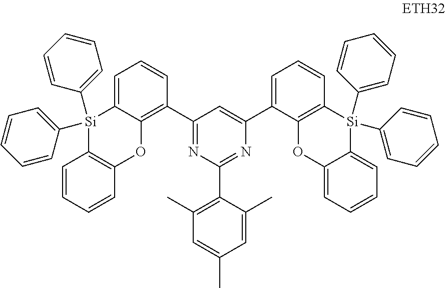 [SMILES: Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

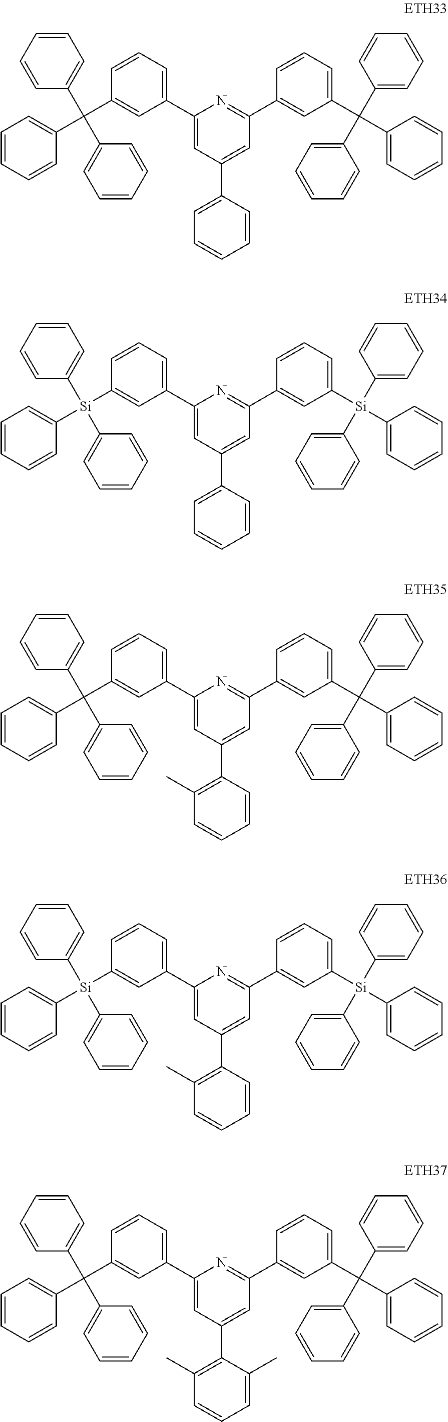

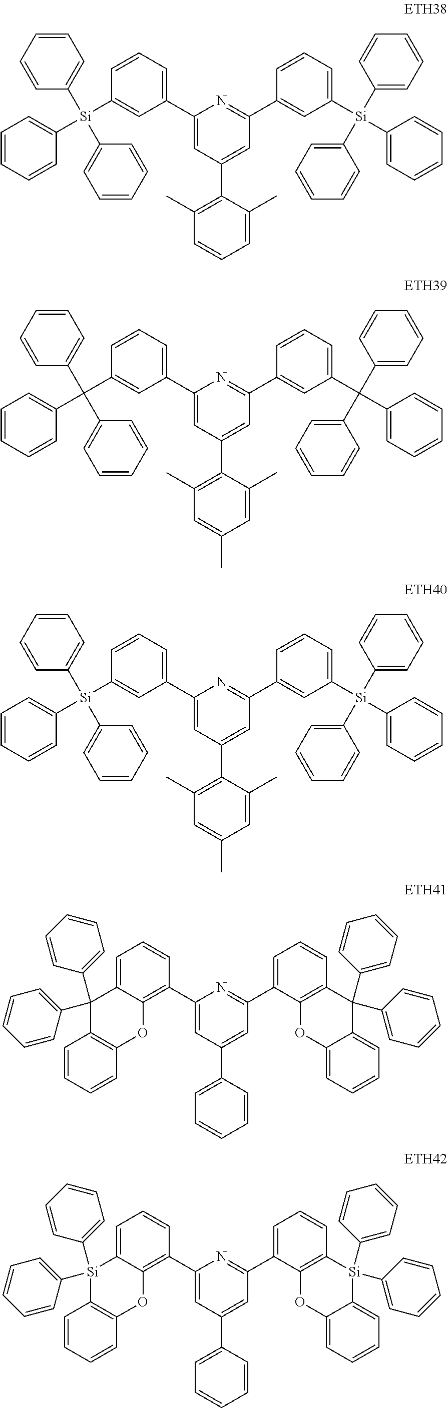

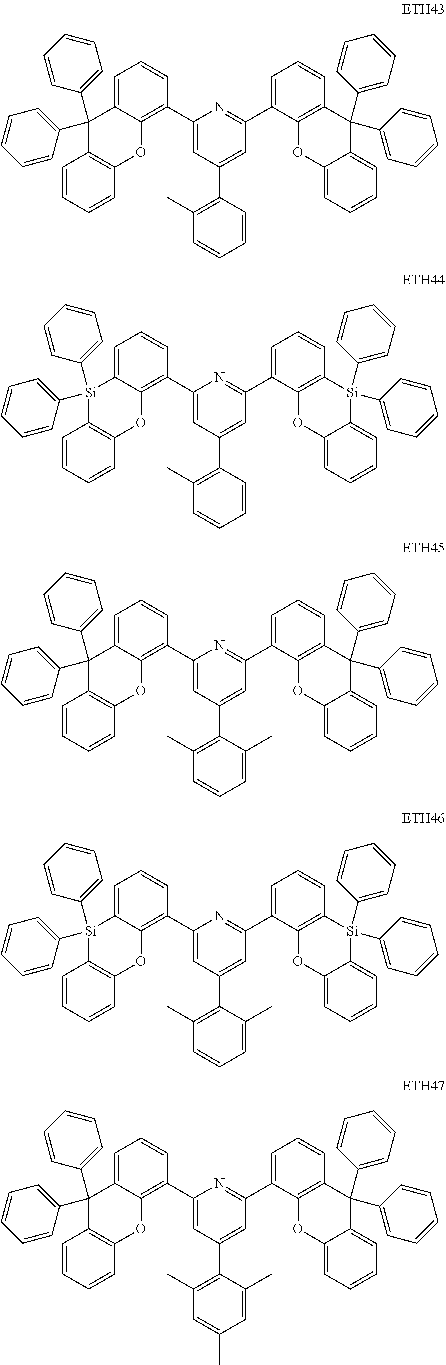

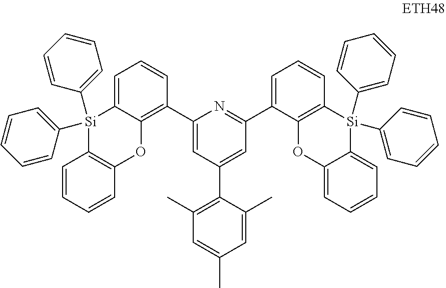 [SMILES: Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

For example, at least one selected from among the first and second emission layers EML-1 and EML-2 may include the first host compound and the second host compound, and the first host compound and the second host compound may form an exciplex. In at least one selected from among the first and second emission layers EML-1 and EML-2, the exciplex may be formed by the hole transporting host and the electron transporting host. In the exciplex, the energy is transferred to the first dopant and/or the second dopant, and thus light may be emitted.

Table 2 shows peak emission wavelengths (λₘₐₓ), HOMO energy levels, and dopant triplet excited state energy levels (T1) of the dopants provided to the display devices of Examples according to one or more embodiments and to Comparative Examples.

TABLE 2

| Dopant | λₘₐₓ (nm) | HOMO (eV) | T1 (eV) |
|---|---|---|---|
| Dopant A1 | 531 | −4.46 | 2.20 |
| Dopant A2 | 521 | −4.60 | 2.31 |
| Dopant A3 | 509 | −4.53 | 2.14 |
| Dopant R1 | 525 | −4.52 | 2.24 |

Referring to Table 2, the dopants A1 to A3 have a peak emission wavelength of about 500 nm to about 570 nm. The dopant A1 satisfies the HOMO energy level of the first dopant according to one or more embodiments. The HOMO energy level of the first dopant according to one or more embodiments may be about −4.50 eV to about −4.40 eV. The dopant A2 satisfies the HOMO energy level of the second dopant according to one or more embodiments. The HOMO energy level of the second dopant according to one or more embodiments may be about −4.70 eV to about −4.55 eV. The difference between the peak emission wavelength of the dopant A1 and the peak emission wavelength of the dopant A2 is about 10 nm or less. The difference between the HOMO energy level of the dopant A1 and the HOMO energy level of the dopant A2 is at most about 0.25 eV (e.g., or less). The difference between the triplet excited state energy level of the dopant A1 and the triplet excited state energy level of the dopant A2 is at most about 0.15 eV (e.g., or less). For example, the dopant A1 and the dopant A2 satisfy the difference in peak emission wavelength, the difference in HOMO energy level, and the difference in triplet excited state energy level according to one or more embodiments.

Table 3 shows an evaluation of driving voltages, efficiencies, and side-surface luminance ratios in display devices of Examples according to one or more embodiments and to Comparative Examples. In Table 3, the driving voltage, the light efficiency, and the luminance are evaluated at a current density of 10 milliampere per square centimeter (mA/cm²), and the side-surface luminance ratio shows a ratio of the luminance at the front surface (angle) 90° and the side surface (angle) 45°. The light efficiency represents a relative value with the value measured in the display device of Comparative Example 1 set as 100%. The display devices of Comparative Examples and Examples are different in thicknesses of the first and second emission layers and types (kinds) of the first and second dopants, and other configurations may each independently be the same.

In Table 3, each of “First emission layer” and “Second emission layer” shows a dopant included in the emission layer and a thickness of the emission layer. In the light emitting element of Example 1, dopant A1 is included in the first emission layer, dopant A2 is included in the second emission layer, and the thickness of each of the first emission layer and the second emission layer is about 165 Å. In the display devices of Examples and Comparative Examples, the total thickness of the emission layers is the same. Unlike the display devices of Examples 1 and 2, the display devices of Comparative Examples 1 to 4 include a single emission layer. When the side-surface luminance ratio is at least about 41.0 (e.g., or more), it is determined hat it is reliable.

TABLE 3

| | First | Second | | | |
|---|---|---|---|---|---|
| | emission | emission | | | Side- |
| | layer | layer | Driving | Light | surface |
| Element | (dopant/ | (dopant/ | voltage | effi- | luminance |
| examples | thickness) | thickness) | (V) | ciency | ratio |
| Example 1 | Dopant A1/ | Dopant A2/ | 3.39 | 109% | 41.0 |
| | 165 Å | 165 Å | | | |
| Example 2 | Dopant A1/ | Dopant A2/ | 3.44 | 104% | 41.6 |
| | 65 Å | 265 Å | | | |
| Comparative | Dopant R1/330 Å | | 3.35 | 100% | 42.0 |
| Example 1 | | | | | |
| Comparative | Dopant A1/330 Å | | 3.30 | 110% | 36.0 |
| Example 2 | | | | | |
| Comparative | Dopant A2/330 Å | | 3.25 | 88% | 45.0 |
| Example 3 | | | | | |
| Comparative | Dopant A3/330 Å | | 4.50 | 50% | 50.0 |
| Example 4 | | | | | |
| Comparative | Dopant A1/ | Dopant A2/ | 3.39 | 109% | 39.0 |
| Example 5 | 265 Å | 65 Å | | | |
| Comparative | Dopant A2/ | Dopant A1/ | 3.35 | 102% | 40.9 |
| Example 6 | 65 Å | 265 Å | | | |
| Comparative | Dopant A2/ | Dopant A1/ | 3.37 | 99% | 41.2 |
| Example 7 | 165 Å | 165 Å | | | |
| Comparative | Dopant A2/ | Dopant A1/ | 3.42 | 90% | 41.9 |
| Example 8 | 265 Å | 65 Å | | | |
| Comparative | Dopant A1/ | Dopant A3/ | 4.30 | 62% | 47.0 |
| Example 9 | 165 Å | 165 Å | | | |

Referring to Table 3, it may be seen that the display devices of Comparative Examples 2 and 5 and Examples 1 and 2 exhibit relatively high efficiency as compared with the display devices of Comparative Examples 1, 3, 4, and 6 to 9. It may be seen that the display devices of Comparative Examples 1, 3, 4, and 7 to 9 and Examples 1 and 2 exhibit excellent or suitable side-surface luminance ratios. Taken together, it may be seen that the display devices of Examples 1 and 2 have an improved side-surface luminance ratio and exhibit excellent or suitable efficiency. The display devices of Examples 1 and 2 include the first emission layer and the second emission layer according to one or more embodiments. In the display devices of Examples 1 and 2, the triplet excited state energy level of dopant A2 included in the second emission layer is higher or greater than that of dopant A1 included in the first emission layer. In some embodiments, in the display devices of Examples 1 and 2, the thickness of the first emission layer is about 50% or less based on 100% of the total thickness of the first emission layer and the second emission layer. Based on 100% of the total thickness of the first emission layer and the second emission layer, the thickness of the first emission layer in Example 1 is about 50%, and the thickness of the first emission layer in Example 2 is about 20%. Accordingly, it may be seen that the display device including the first emission layer and the second emission layer according to one or more embodiments has an improved side-surface luminance ratio and exhibits excellent or suitable display efficiency.

It is believed that the display devices of Comparative Examples 1 to 4 include a single emission layer and exhibit relatively low efficiency or a relatively small side-surface luminance ratio. It is believed that the display device of Comparative Example 5 exhibits a relatively small side-surface luminance ratio because the thickness of the first emission layer is greater than about 50% based on 100% of the total thickness of the first and second emission layers. In the display devices of Comparative Examples 6 to 9, the triplet excited state energy level of the dopant included in the second emission layer is lower than that of the dopant included in the first emission layer. Accordingly, it is believed that the display devices of Comparative Examples 6 to 9 exhibit relatively low efficiency or a relatively small side-surface luminance ratio.

The first emission layer EML-1 and the second emission layer EML-2 may further include a material, which will be described, in addition to the first dopant and the second dopant as described herein. In some embodiments, any one or two of the first to third light emitting elements ED-1, ED-2, and/or ED-3 (see FIG. 2) may include the first dopant and the second dopant, and the remaining light emitting elements may include a material which will be described. For example, the second light emitting element ED-2 (see FIG. 2) may include the first dopant and the second dopant.

Each of the first emission layer EML-1 and the second emission layer EML-2 may further include an anthracene derivative, a pyrene derivative, a fluoranthene derivative, a chrysene derivative, a dihydrobenzanthracene derivative, a carbazole derivative, a triazine derivative, or a triphenylene derivative. Any one or two of the first to third light emitting elements ED-1, ED-2, and ED-3 (see FIG. 2) may include an anthracene derivative, a pyrene derivative, a fluoranthene derivative, a chrysene derivative, a dihydrobenzanthracene derivative, a carbazole derivative, a triazine derivative, or a triphenylene derivative.

The first emission layer EML-1 and the second emission layer EML-2 may further include a compound represented by Formula E-1. Any one or two of the first to third light emitting elements ED-1, ED-2, and/or ED-3 (see FIG. 2) may also include a compound represented by Formula E-1.

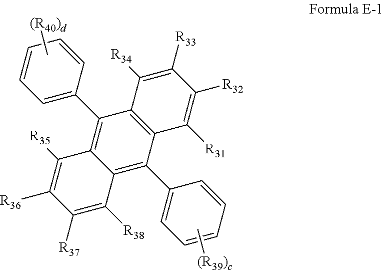

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one selected from among

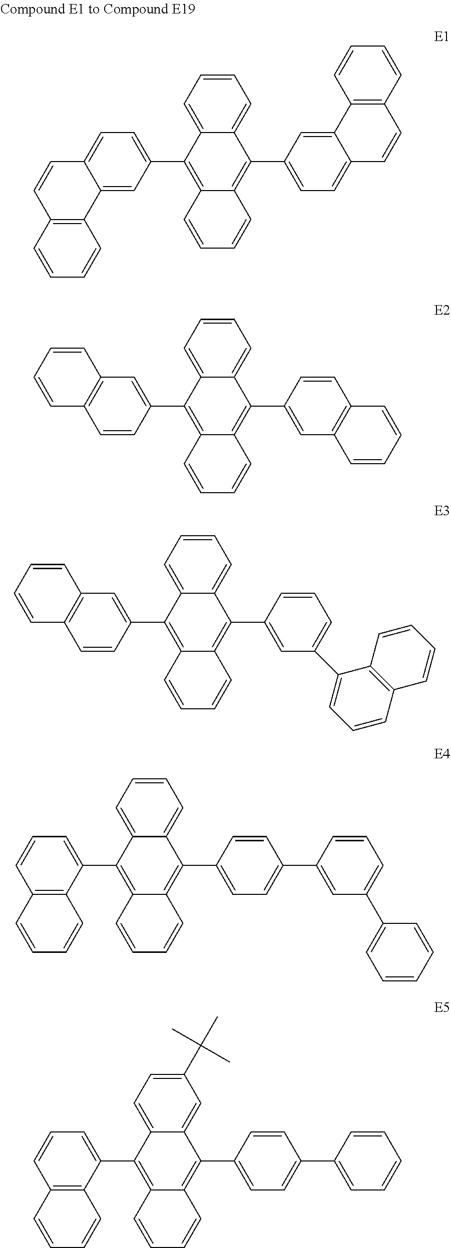

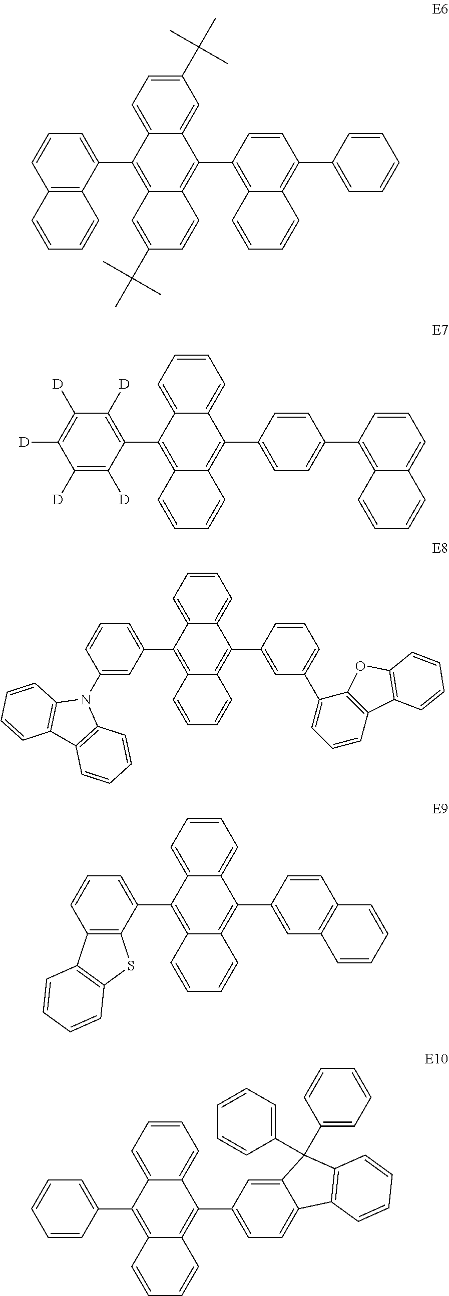

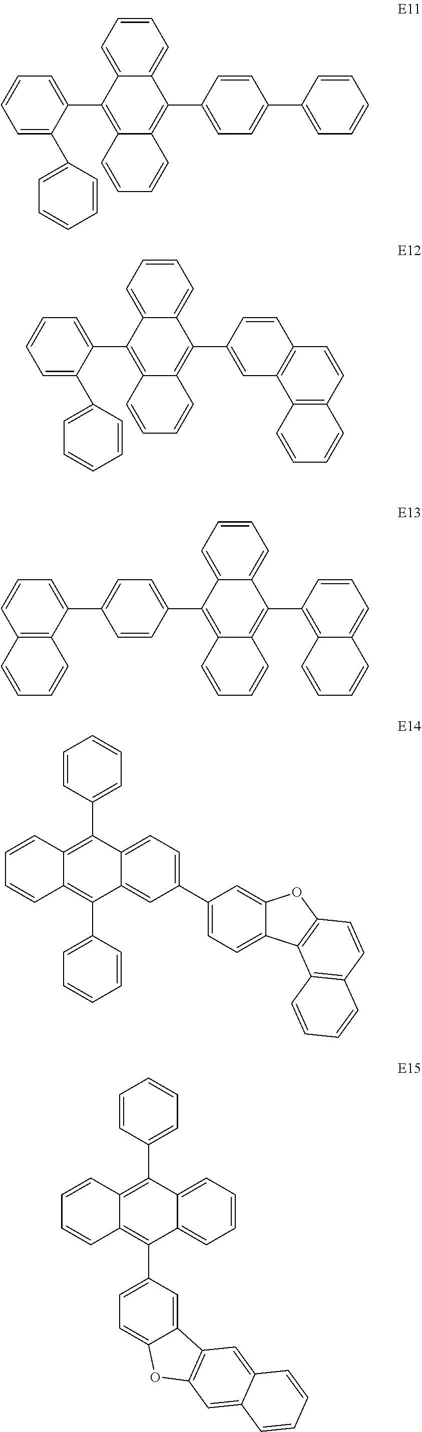

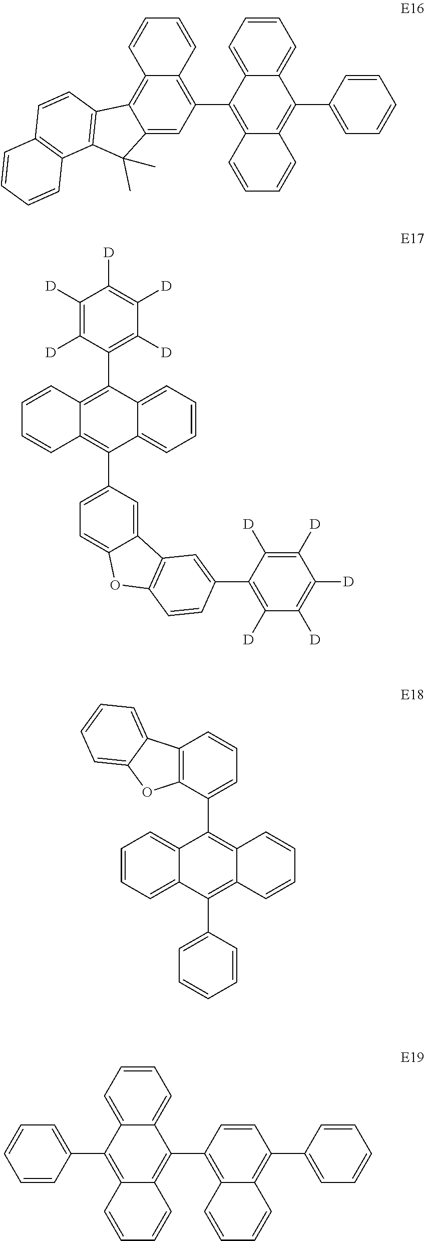

The first emission layer EML-1 and/or the second emission layer EML-2 may include a compound represented by Formula E-2a or Formula E-2b. Any one or two of the first to third light emitting elements ED-1, ED-2, and/or ED-3 (see FIG. 2) may also include a compound represented by Formula E-2a or Formula E-2b. The compound represented by Formula E-2a or Formula E-2b may be utilized as a phosphorescent host material.

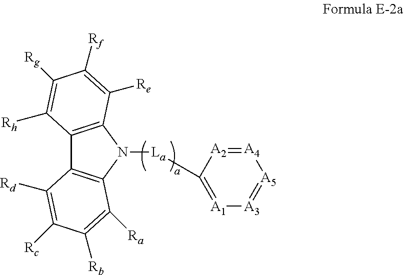

In Formula E-2a, a may be an integer of 0 to 10, La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. In Formula E-2a, two or three selected from among A₁ to A₅ may be N, and the rest may be CRᵢ.

Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, and/or the like, as a ring-forming atom.

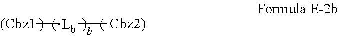

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2. However, the compounds listed in Compound Group E-2 are example, and the compound represented by Formula E-2a or Formula E-2b is not limited to those represented in Compound Group E-2.

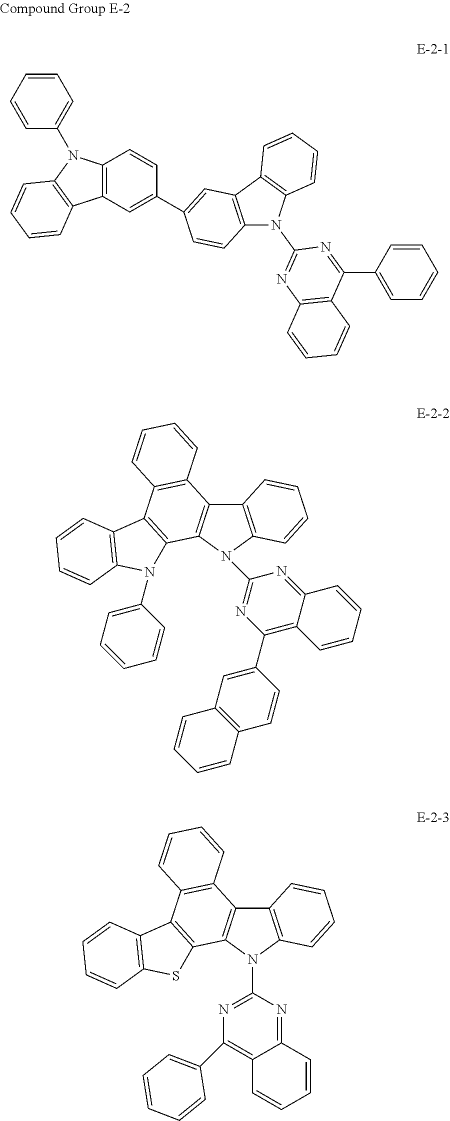 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

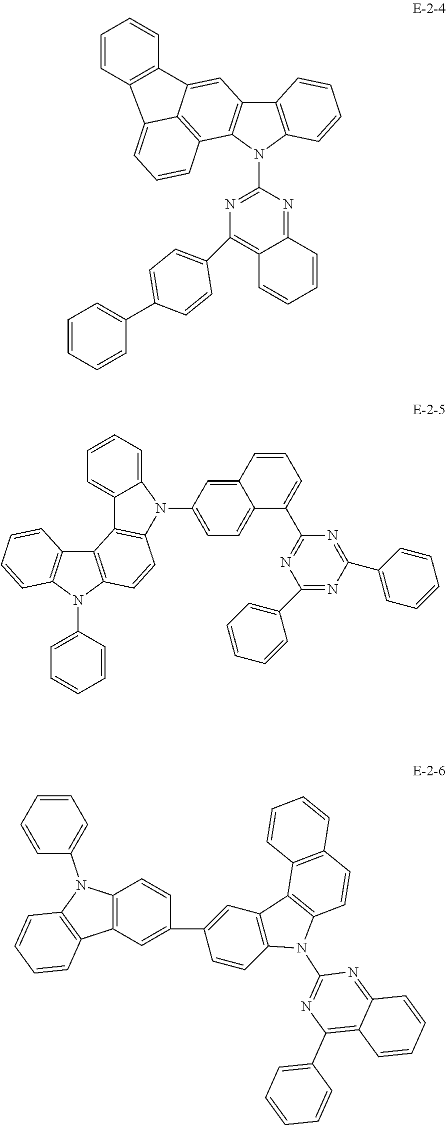 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

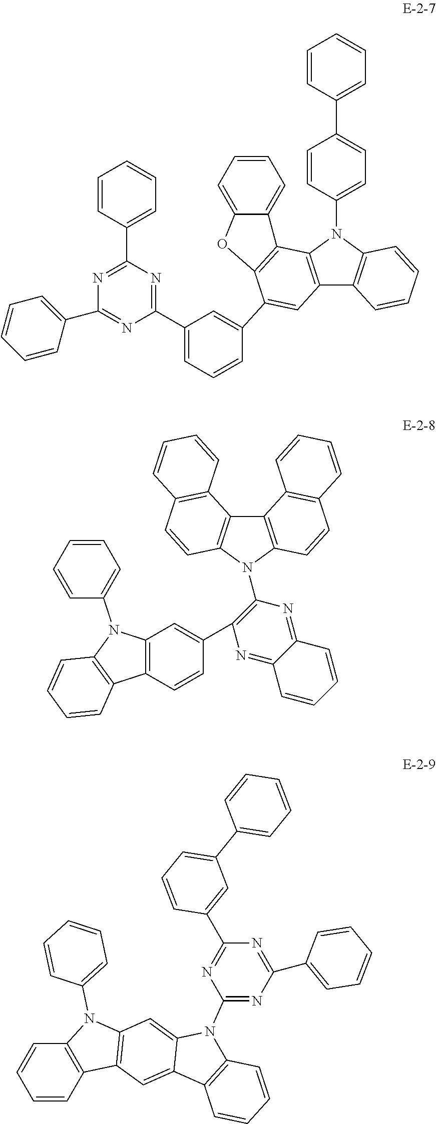 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

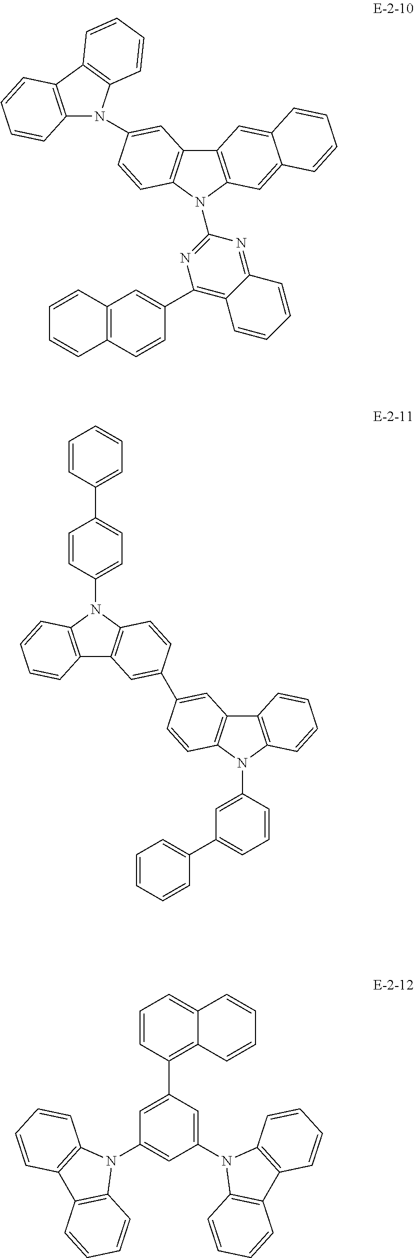 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

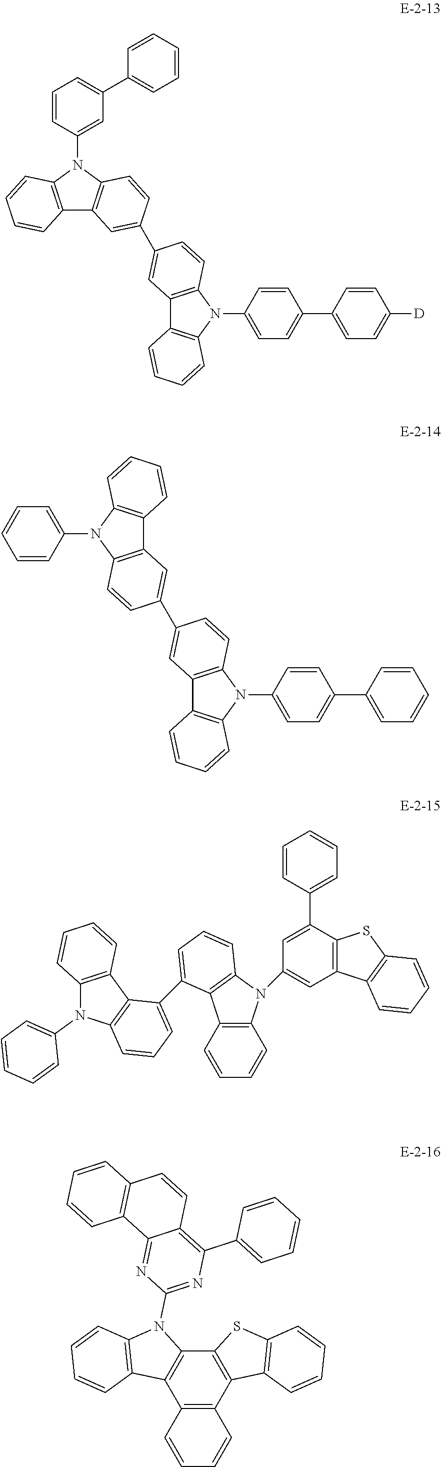 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

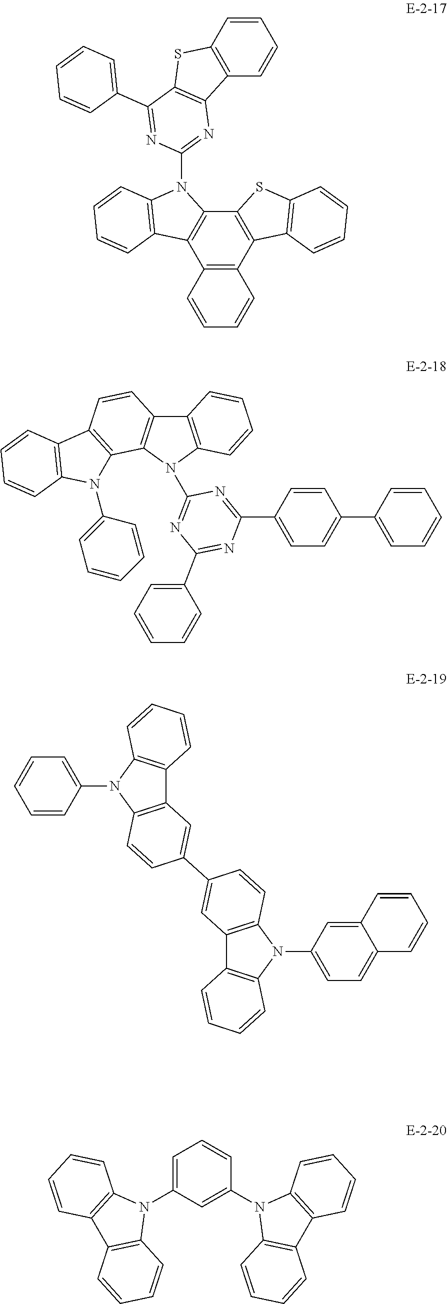 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

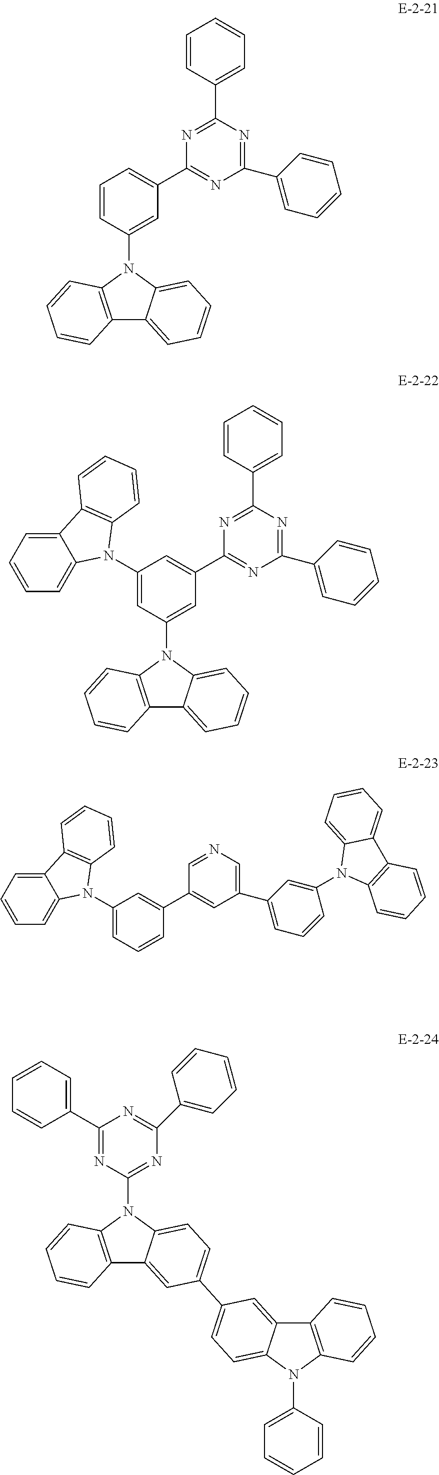 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The first emission layer EML-1 and/or the second emission layer EML-2 may further include a general material suitable in the art as a host material. At least one selected from among the first to third light emitting elements ED-1, ED-2, and ED-3 (see FIG. 2) may include a general material suitable in the art as a host material. For example, at least one selected from among bis(4-(9H-carbazol-9-yl)phenyl)diphenylsilane BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl) dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi) may be provided as a host material. However, the embodiment of the present disclosure is not limited thereto, for example, tris(8-hydroxyquinolino)aluminum (Alq3), 9,10-di(naphthalene-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl) benzene (UGH2), hexaphenylcyclotrisiloxane (DPSiO₃), octaphenylcyclotetra siloxane (DPSiO₄), and/or the like, may be provided as a host material.

The first emission layer EML-1 or the second emission layer EML-2 may include a compound represented by Formula M-a. At least one selected from among the first to third light emitting elements ED-1, ED-2, and ED-3 (see FIG. 2) may also include a compound represented by Formula M-a. The compound represented by Formula M-a may be utilized as a phosphorescent dopant material.

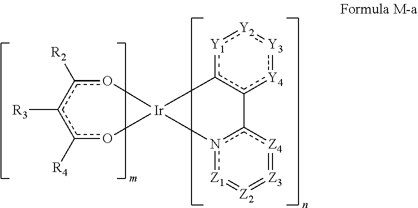

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant. The compound represented by Formula M-a may be represented by any one selected from among Compound M-a1 to Compound M-a25. However, Compounds M-a1 to M-a25 are example, and the compound represented by Formula M-a is not limited to those represented by Compounds M-a1 to M-a25:

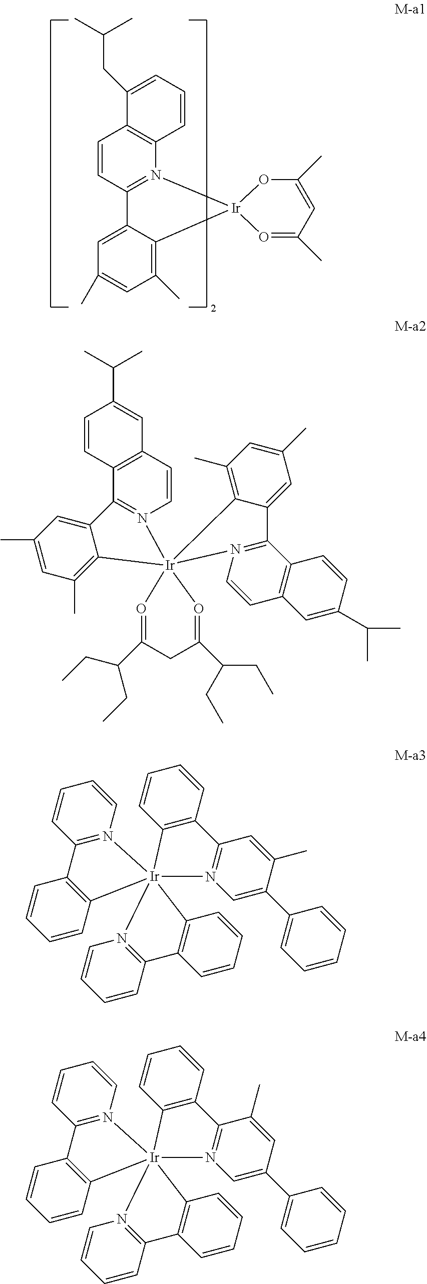

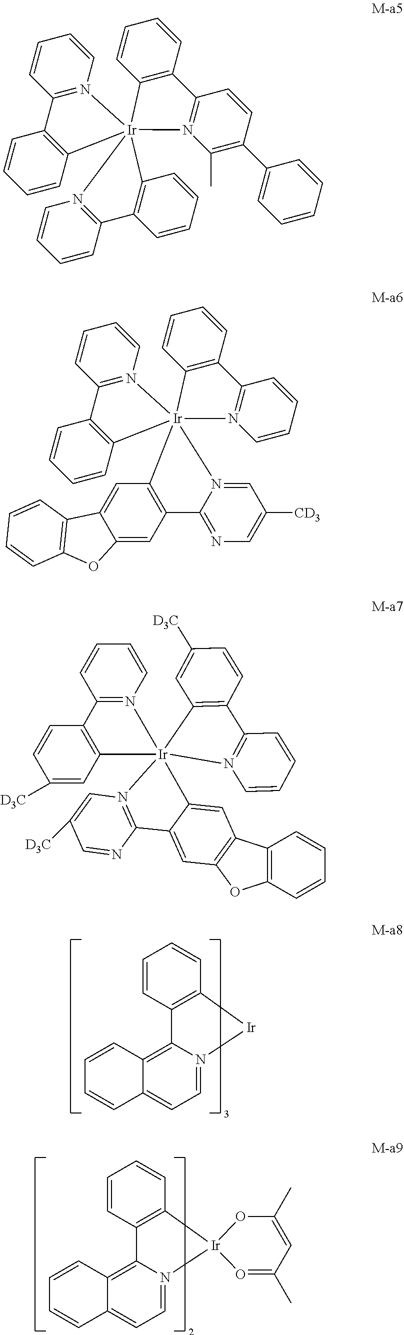

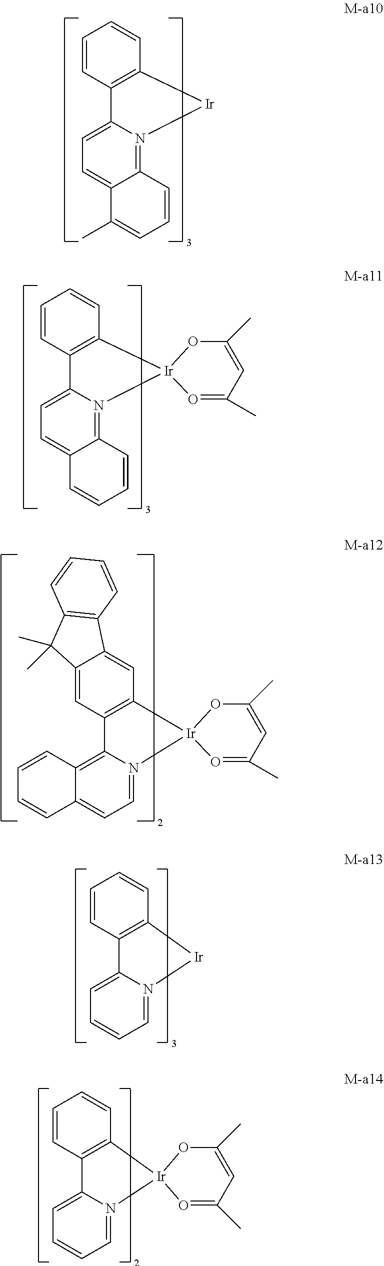

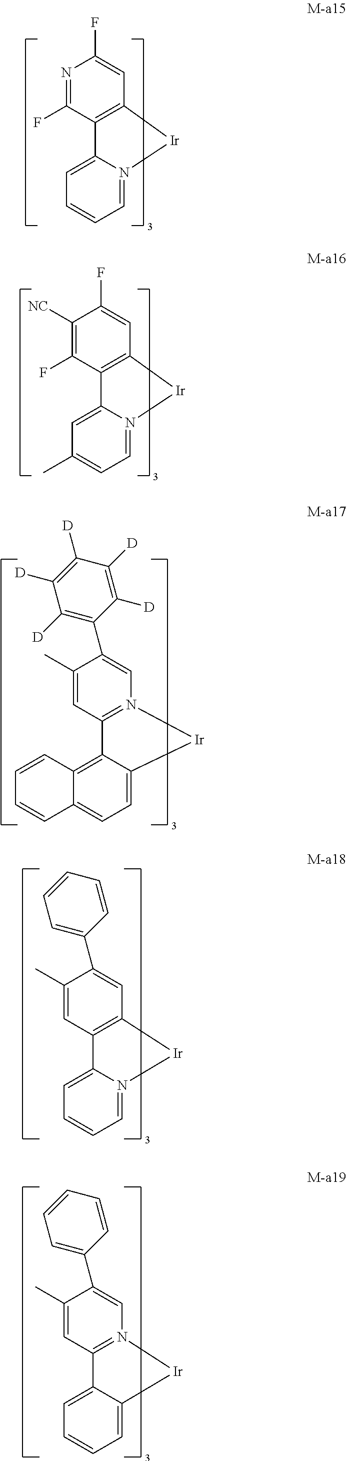

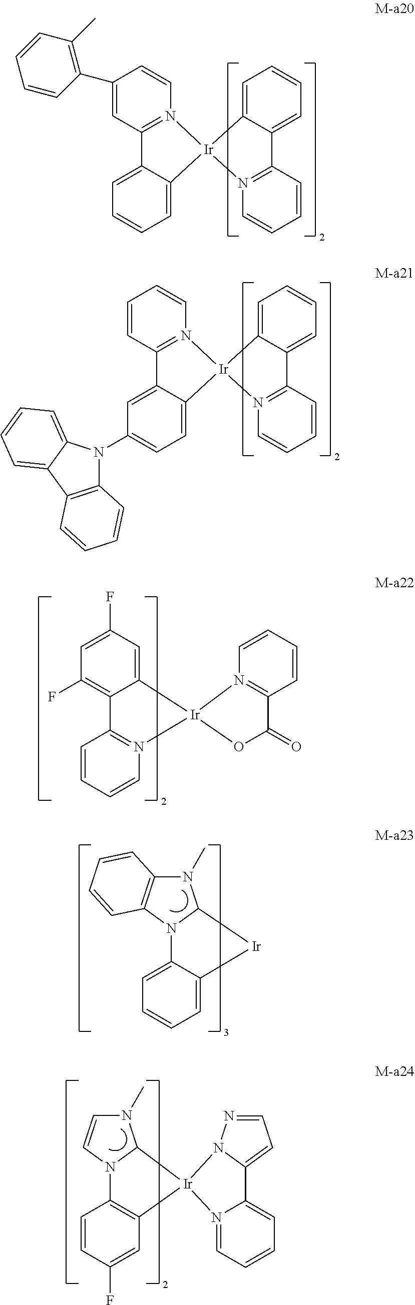

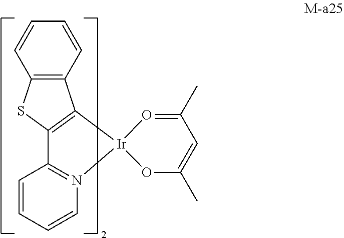

The first emission layer EML-1 or the second emission layer EML-2 may further include a compound represented by any one selected from among Formula F-a to Formula F-c. Any one or two of the first to third light emitting elements ED-1, ED-2, and/or ED-3 (see FIG. 2) may also include a compound represented by any one selected from among Formula F-a to Formula F-c.

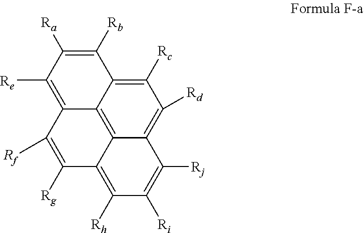

In Formula F-a above, two selected from among Rₐ to Rⱼ may each independently be substituted with *—NAr₁Ar₂. The others, which are not substituted with *—NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

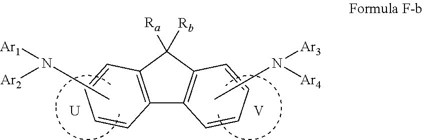

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may each independently be 0 or 1. For example, in Formula F-b, it refers to that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of Vis 0, the fused ring having a fluorene core in Formula F-b may be a cyclic compound having four rings. In some embodiments, when each number of U and V is 0, the fused ring having a fluorene core in Formula F-b may be a cyclic compound having three rings. In some embodiments, when each number of U and V is 1, the fused ring having a fluorene core in Formula F-b may be a cyclic compound having five rings.

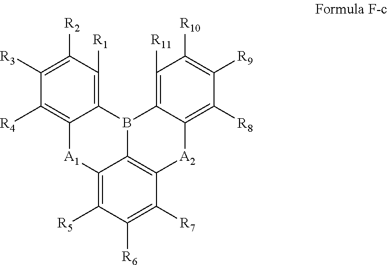

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

The first emission layer EML-1 or the second emission layer EML-2 may further include, as a suitable material, styryl derivatives (e.g., 1,4-bis[2-(3-N-ethylcarbazoryl)vinyl]benzene(BCzVB), 4-(di-p-tolylamino)-4′-[(di-p-tolylamino)styryl]stilbene(DPAVB), and N-(4-((E)-2-(6-((E)-4-(diphenylamino) styryl) naphthalen-2-yl) vinyl)phenyl)-N-phenylbenzenamine (N-BDAVBi), 4,4′-bis[2-(4-(N,N-diphenylamino)phenyl) vinyl]biphenyl(DPAVBi), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino) pyrene), and/or the like.

Any one or two of the first to third light emitting elements ED-1, ED-2, and/or ED-3 (see FIG. 2) may also include a quantum dot material. The core of the quantum dot may be selected from among a Group II-VI compound, a Group I—II-VI compound, a Group II—IV-VI compound, a Group I—II-IV-VI compound, a Group II—IV-V compound. III-VI compound, a Group I—III-VI compound, a Group III-V compound, a Group III—II-V compound, a Group IV-VI compound, a Group IV element, a Group IV compound, and a combination thereof.

The Group II-VI compound may be selected from among the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

In some embodiments, the Group II-VI compound may further include a Group I metal and/or a Group IV element. The Group I—II-VI compound may be selected from among CuSnS or CuZnS, and ZnSnS, and/or the like may be selected as the Group II—IV-VI compound. The Group I—II-IV-VI compound may be selected from a quaternary compound selected from the group consisting of CuZnSnS₂, Cu₂ZnSnS₄, Cu₂ZnSnSe₄, Ag₂ZnSnS₂, and a mixture thereof.

The Group II—IV-V compound may be a ternary compound selected from the group consisting of ZnSnP, ZnSnP₂, ZnSnAs₂, ZnGeP₂, ZnGeAs₂, CdSnP₂, CdGeP₂, and a mixture thereof.

The Group III-VI compound may include a binary compound such as GaS, GazS₃, GaSe, GazSes, GaTe, InTe, InS, InSe, In₂S₃, or In₂Se₃, a ternary compound such as InGaSs or InGaSes, or any combination thereof.

The Group I—III-VI compound may be selected from a ternary compound selected from the group consisting of AglnS, AglnS₂, CulnS, CulnS₂, AgGaS₂, CuGaS₂ CuGaO₂, AgGaO₂, AgAIO₂, and a mixture thereof, or a quaternary compound such as AgInGaS₂ or CulnGaS₂.

The Group III-V compound may be selected from the group consisting of a binary compound selected from the group consisting of GaN, GaP, GaAs, GaSb, AlN, AIP, AIAs, AISb, InN, InP, InAs, InSb, and a mixture thereof, a ternary compound selected from the group consisting of GaNP, GaNAs, GaNSb, GaPAs, GaPSb, AlNP, AlNAs, AlNSb, AIPAs, AIPSb, InGaP, InAIP, InNP, InNAs, InNSb, InPAs, InPSb, and a mixture thereof, and a quaternary compound selected from the group consisting of GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, and a mixture thereof. In some embodiments, the Group III-V compound may further include a Group II metal. For example, InZnP, and/or the like may be selected as a Group III—II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound such as the binary compound, the ternary compound, or the quaternary compound may be present in a particle with a substantially uniform or non-substantially uniform concentration distribution. For example, the formulae refer to the types (kinds) of elements included in the compounds, and the elemental ratio in the compound may be different. For example, AgInGaS₂ may refer to AglnxGa₁₋ₓS₂ (where x is a real number of 0 to 1).

In some embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An interface between the core and the shell may have a concentration gradient in which the concentration of an element present in the shell becomes lower towards the center.

In some embodiments, the quantum dot may have the herein-described core-shell structure including a core containing nanocrystals and a shell around (e.g., surrounding) the core. An example of the shell of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, and/or the like, but the embodiment of the present disclosure is not limited thereto.

Each element included in a polynary compound such as the binary compound, or the ternary compound may be present in a particle with a substantially uniform or non-substantially uniform concentration distribution. For example, the formulae refer to the types (kinds) of elements included in the compounds, and the elemental ratio in the compound may be different.

The quantum dot may have a full width of half maximum (FWHM) of an emission wavelength spectrum of about 45 nm or less, about 40 nm or less, and more about 30 nm or less, and color purity or color reproducibility may be improved in the above range. In some embodiments, light emitted through such a quantum dot is emitted in all directions, so that a wide viewing angle may be improved.

In some embodiments, although the form of the quantum dot is not particularly limited as long as it is a form commonly utilized in the art, more specifically, the quantum dot in the form of spherical, pyramidal, multi-arm, or cubic nanoparticles, nanotubes, nanowires, nanofibers, nanoplate particles, and/or the like may be utilized.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, the quantum dot as above (utilizing different sizes of quantum dots or different elemental ratios in the quantum dot compound) is utilized, and thus the light emitting element, which emits light in one or more suitable wavelengths, may be implemented. For example, the adjustment of the size of the quantum dot or the elemental ratio in the quantum dot compound may be selected to emit red, green, and/or blue light. In some embodiments, the quantum dots may be configured to emit white light by combining one or more suitable colors of light.

Referring to FIGS. 3A to 3B again, the first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the herein-described materials, and a transparent conductive film formed of ITO, IZO, ZnO, ITZO, and/or the like. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å. The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

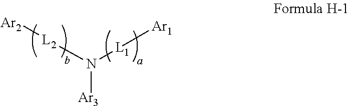

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

The compound represented by Formula H-1 herein may be a monoamine compound. In some embodiments, the compound represented by Formula H-1 herein may be a diamine compound in which at least one among Ar₁ to Ar₃ includes the amine group as a substituent. In some embodiments, the compound represented by Formula H-1 herein may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

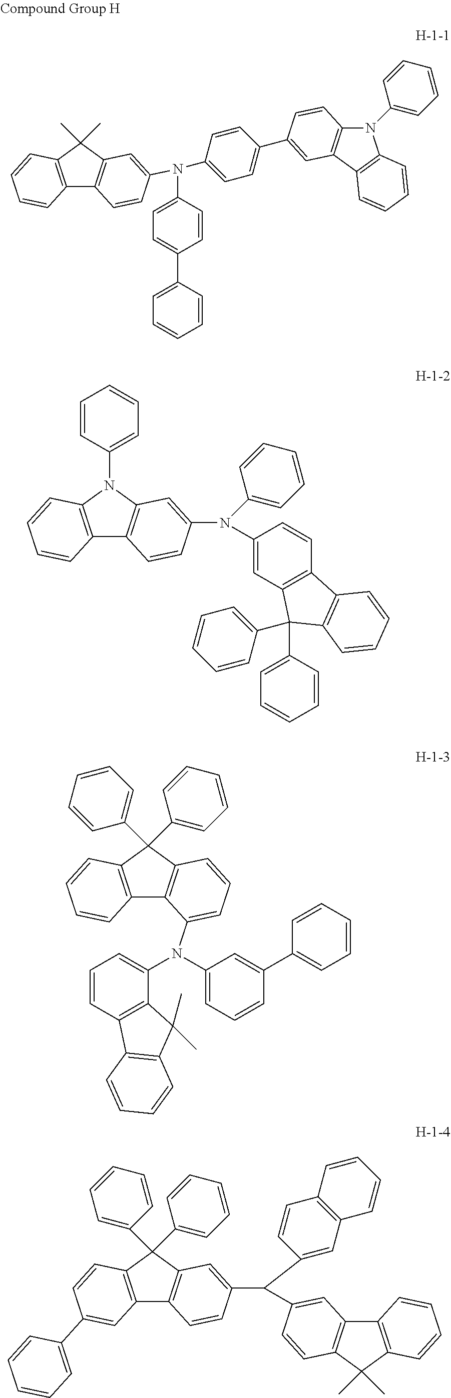

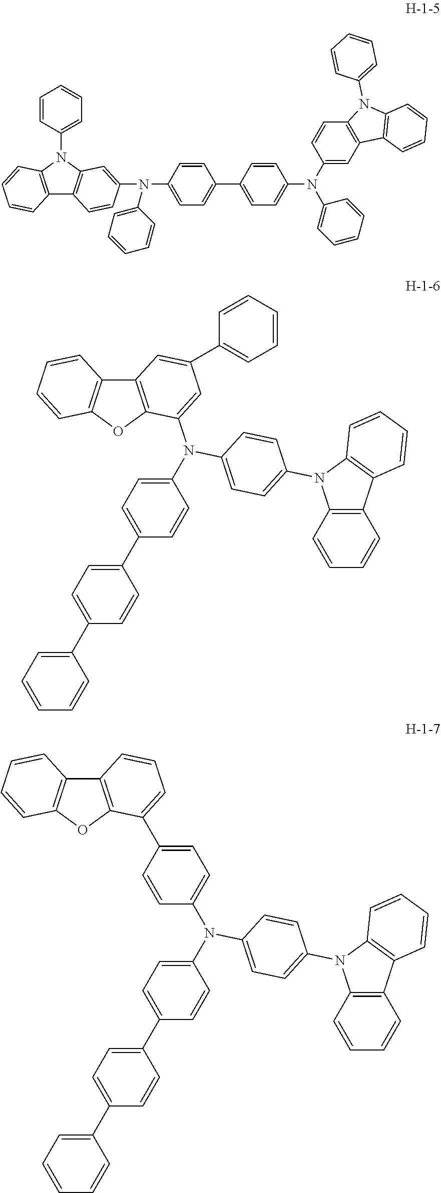

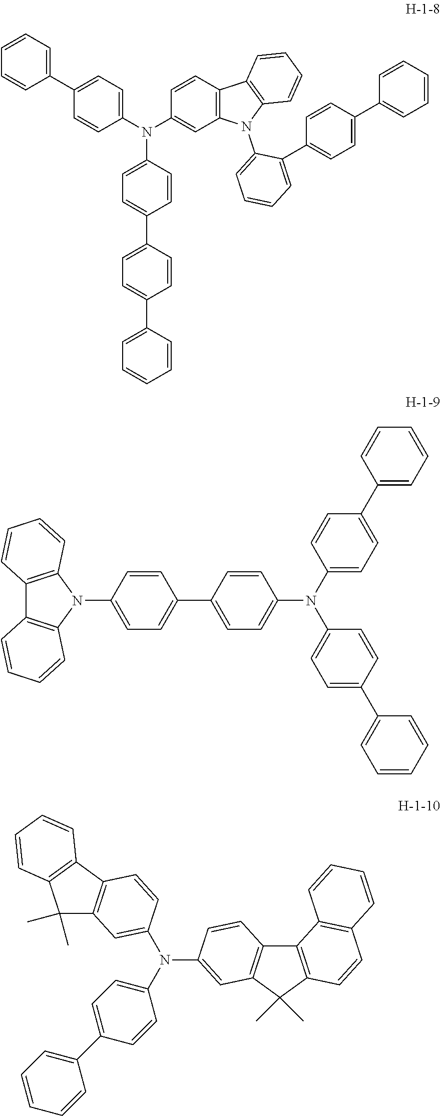 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

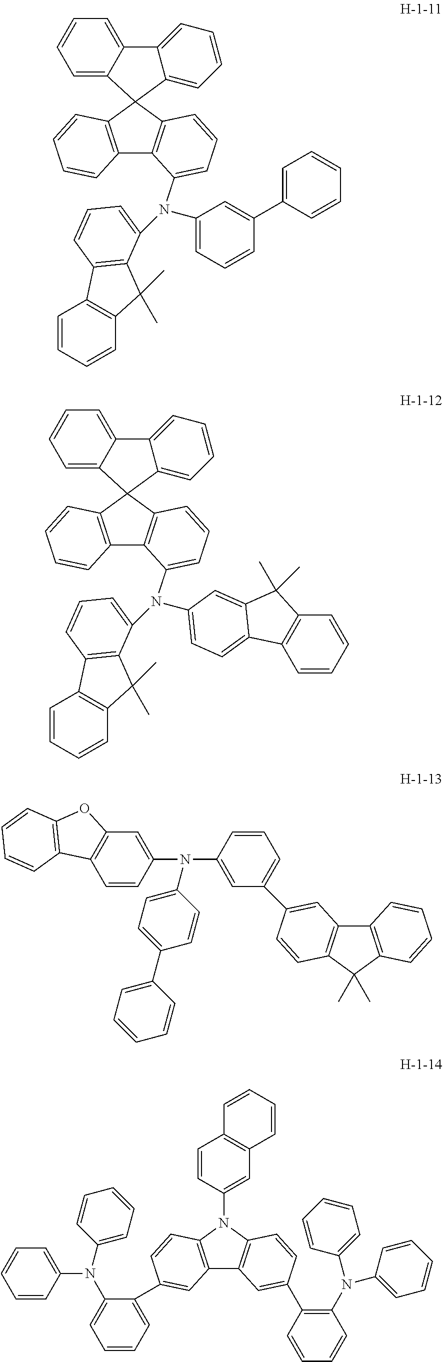

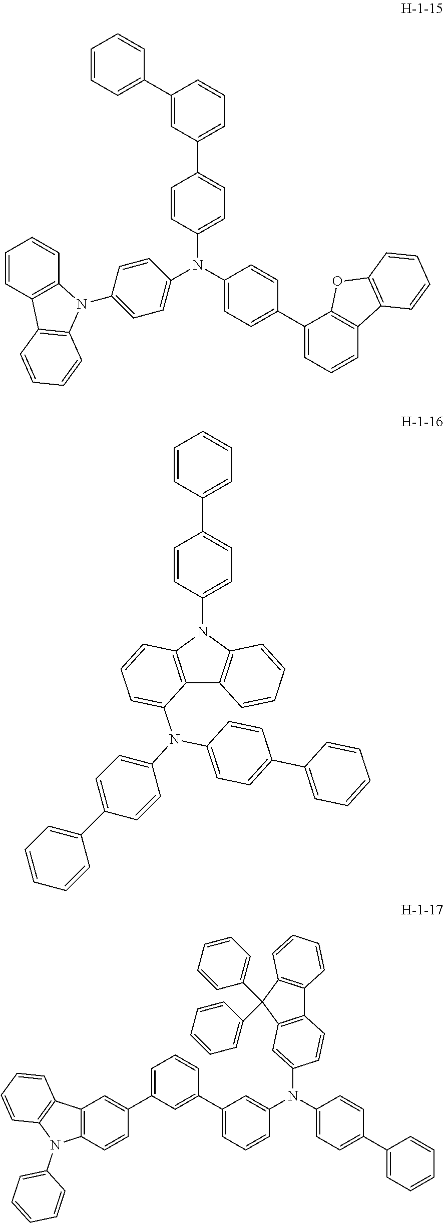 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

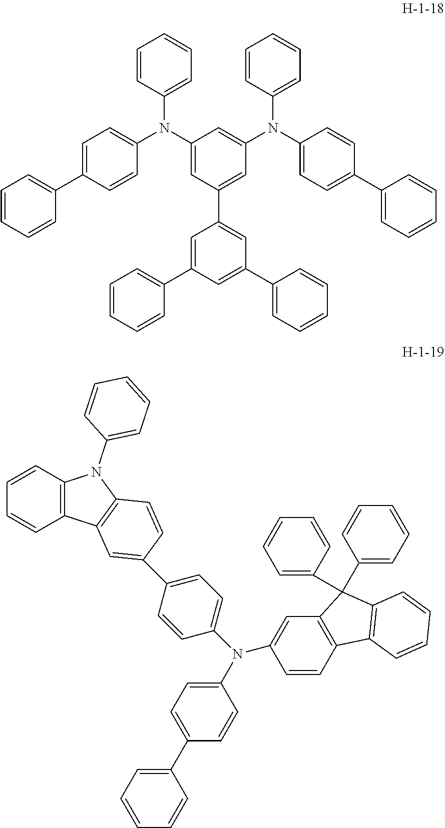

The hole transport region HTR may include at least one selected from among a phthalocyanine compound such as copper phthalocyanine; N1,N1′-([1,1′-biphenyl]-4,4′-diyl)bis(N1-phenyl-N4, N4-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium[tetrakis(pentafluorophenyl) borate], dipyrazino[2,3-f: 2′,3′-h]quinoxaline-2,3,6,7,10,11-hexacarbonitrile (HATCN), and/or the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl) triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as Cul or Rbl, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10, 11-hexacarbonitrile (HATCN) or 4-[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The electron transport region ETR may be provided on the second emission layer EML-2. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multi-layered structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single-layered structure formed of multiple different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

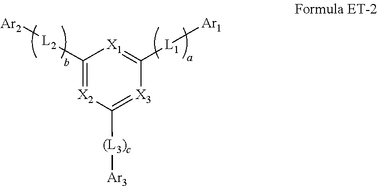

In Formula ET-2, at least one among X₁ to X₃ may be N, and the rest of X₁ to X₃ may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazol-1-yl)phenyl)-9,10-dinaphthylanthracene, 1,3,5-tri (1-phenyl-1 H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq₂), 9,10-di(naphthalene-2-yl) anthracene (ADN), 1,3-bis[3,5-di(pyridin-3-yl)phenyl]benzene (BmPyPhB), or a mixture thereof.

The electron transport region ETR may include at least one selected from among Compound ET1 to Compound ET36:

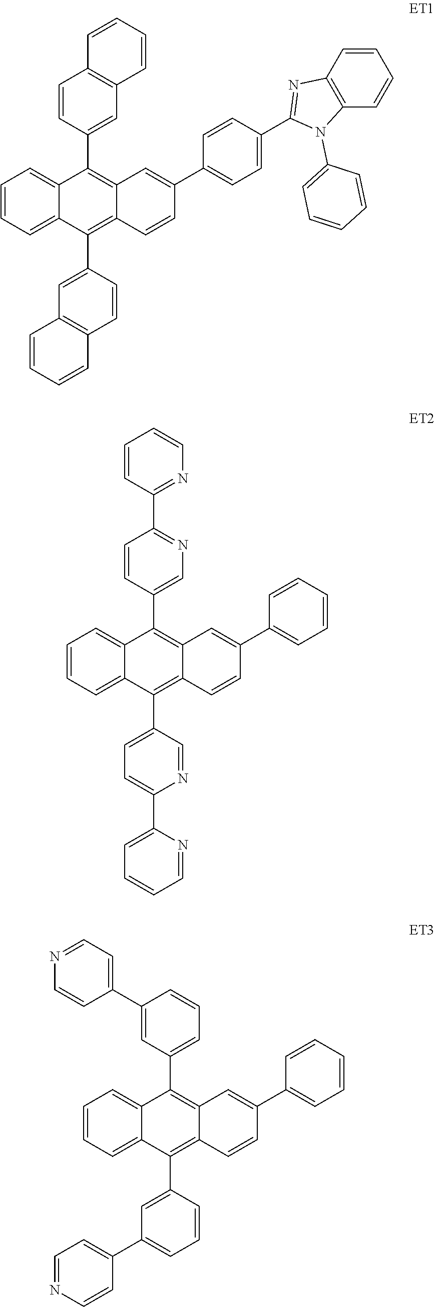 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

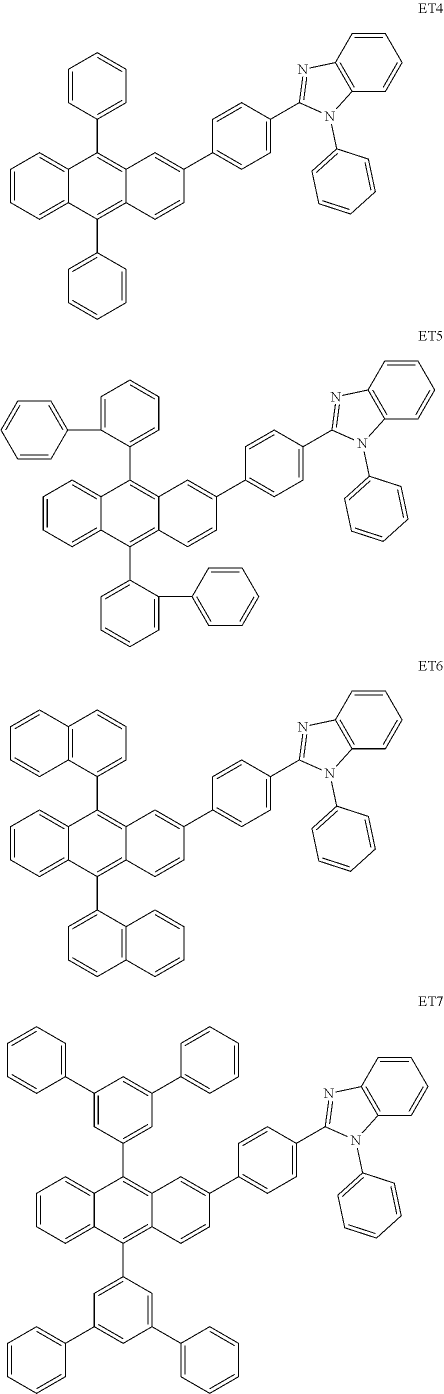 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

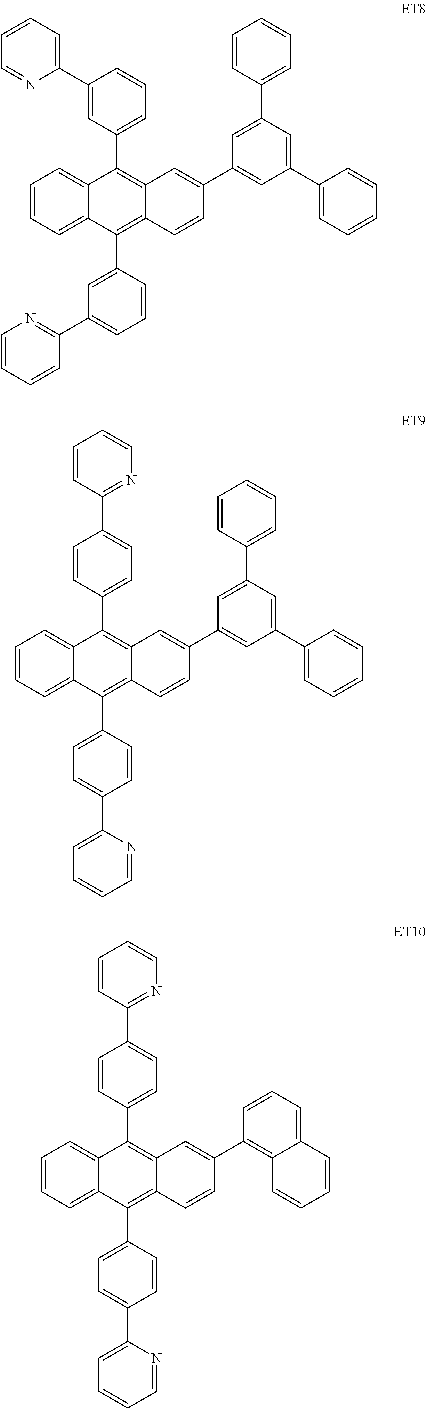 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

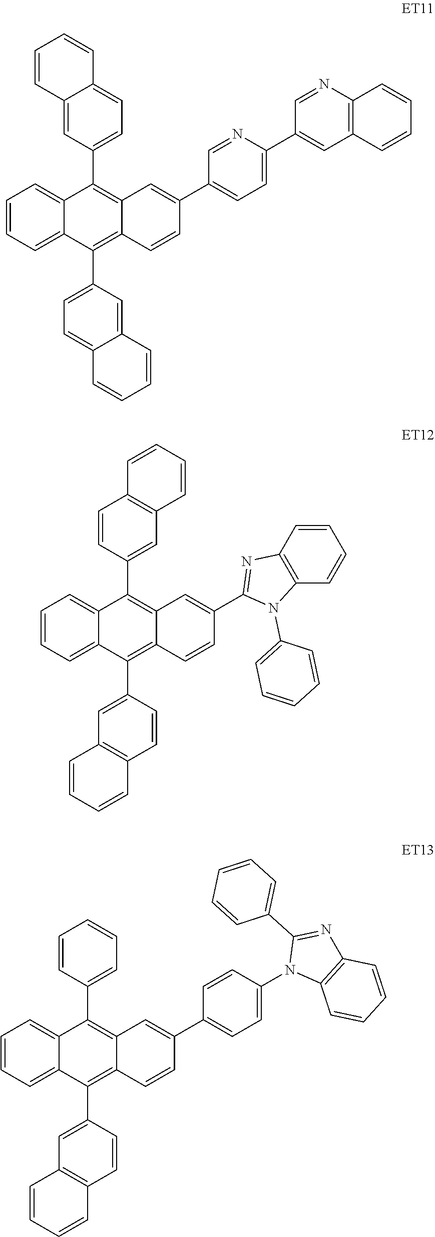 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

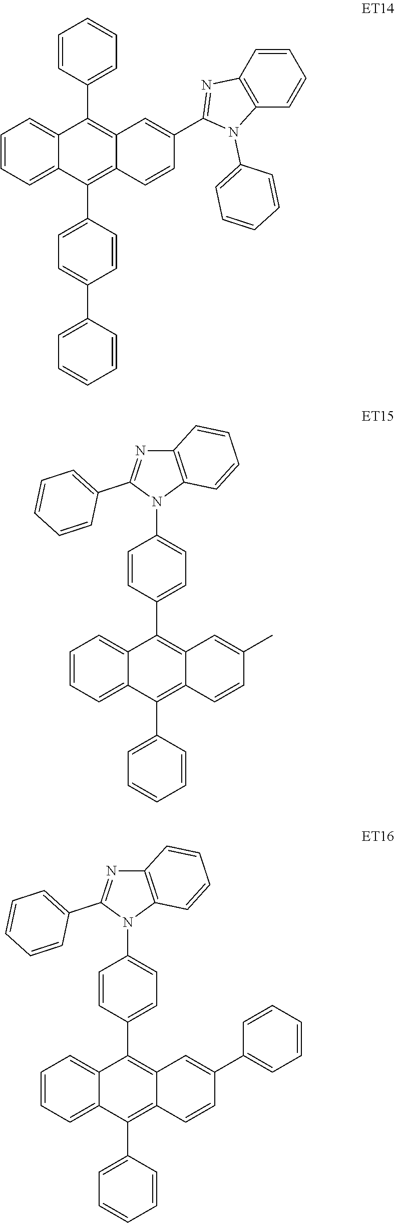

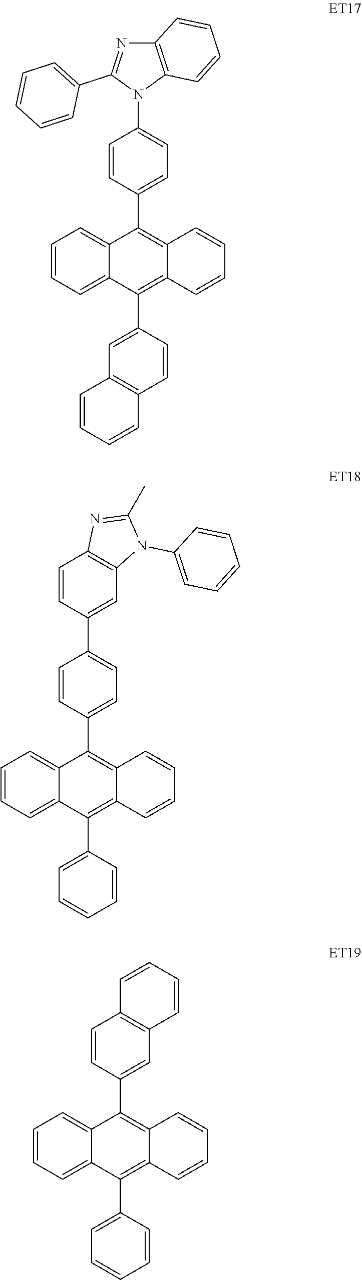

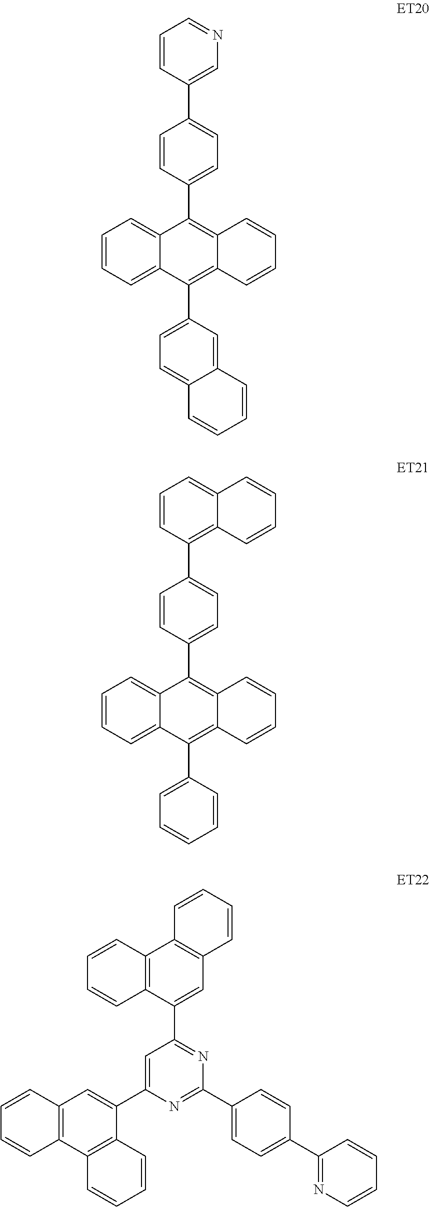

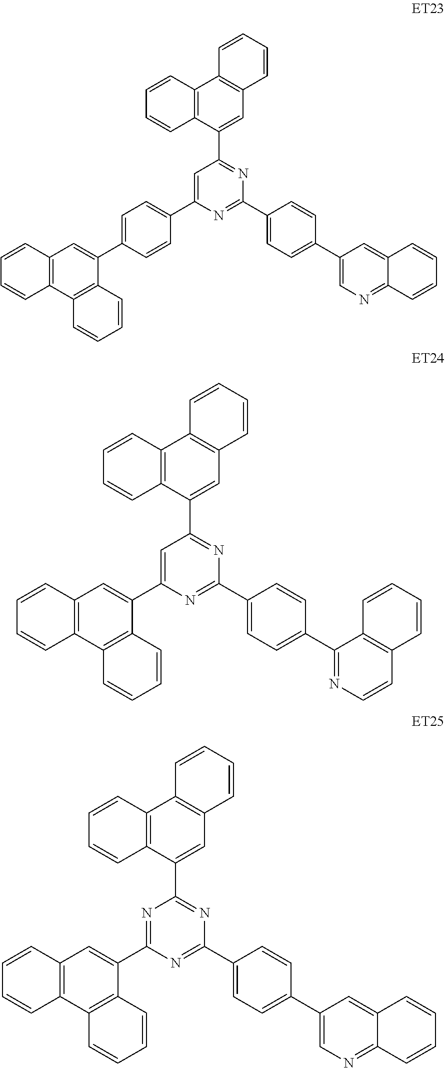 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

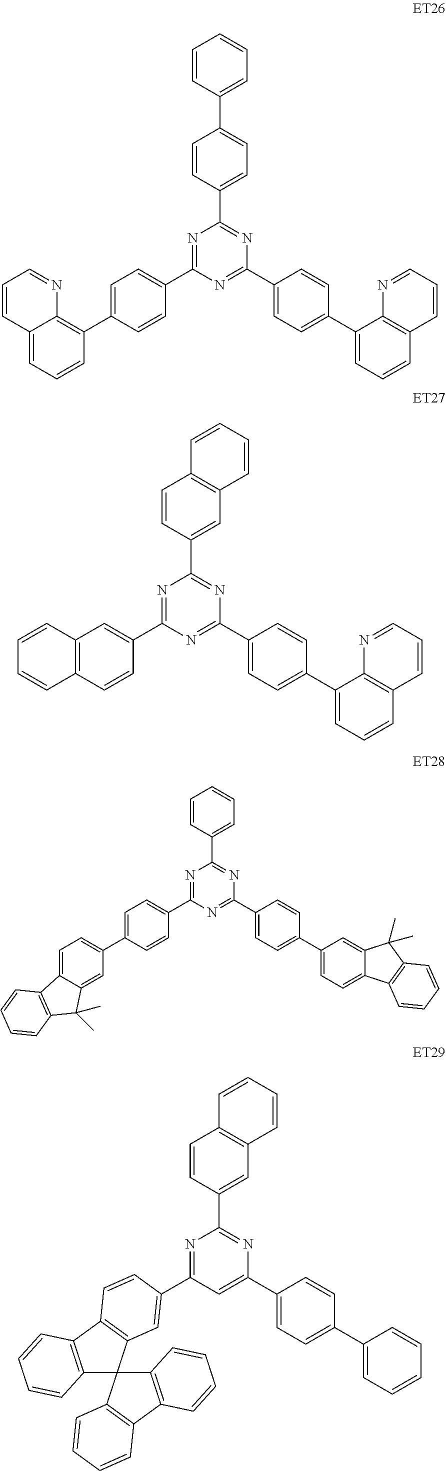 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

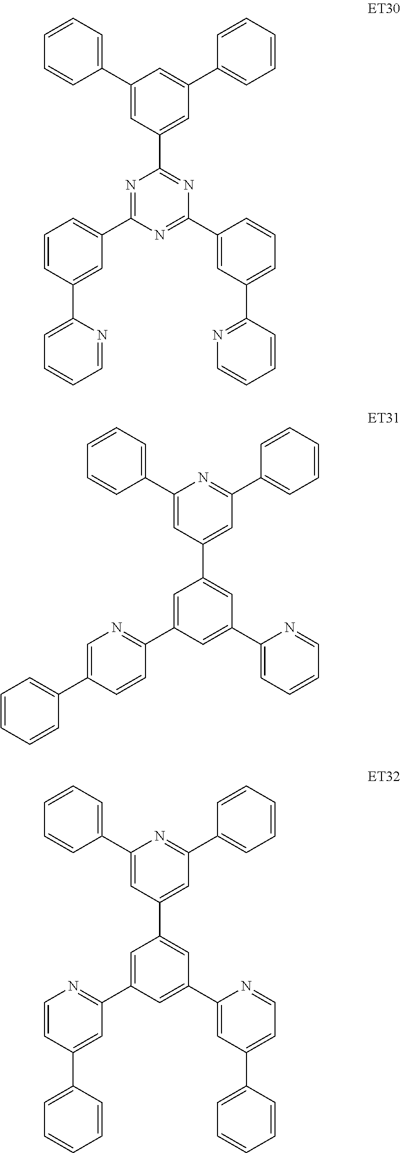 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

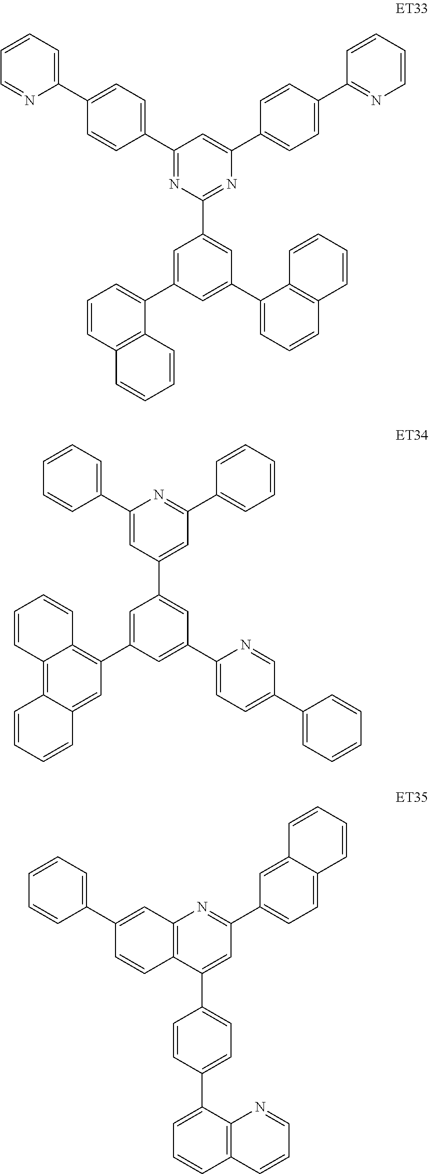 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

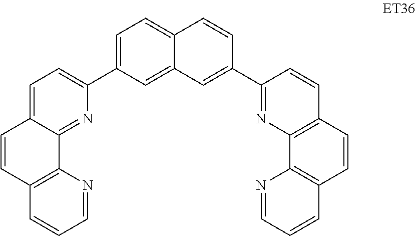 [SMILES: c1cnc2c(c1)ccc1ccc(-c3ccc4ccc(-c5ccc6ccc7cccnc7c6n5)cc4c3)nc12]

1 In some embodiments, the electron transport regions ETR may include a metal halide such as LiF, NaCl, CsF, RbCl, Rbl, Cul, or KI, a lanthanide metal such as Yb, and a co-deposited material of the metal halide and the lanthanide metal. For example, the electron transport region ETR may include KI: Yb, Rbl: Yb, LiF: Yb, and/or the like, as a co-deposited material. In some embodiments, the electron transport region ETR may be formed utilizing a metal oxide such as Li₂O or BaO, or 8-hydroxyl-lithium quinolate (Liq), and/or the like, but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl) phosphine oxide (TSPO1), or 4,7-diphenyl-1,10-phenanthroline (Bphen) in addition to the herein-described materials, but the embodiment of the present disclosure is not limited thereto. The electron transport region ETR may include the herein-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the herein-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., AgMg, AgYb, or MgAg). In some embodiments, the second electrode EL2 may have a multi-layered structure including a reflective film or a transflective film formed of the herein-described materials, and a transparent conductive film formed of ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

the second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light emitting element ED of one or more embodiments. The capping layer CPL may include a multilayer or a single layer.

The capping layer CPL may be an organic layer or an inorganic layer. For example, when the capping layer CPL includes (e.g., contains) an inorganic material, the inorganic material may include an alkaline metal compound (e.g., LiF), an alkaline earth metal compound (e.g., MgF₂), SiON, SiNₓ, SiOy, and/or the like.

For example, when the capping layer CPL includes an organic material, the organic material may include a-NPD, NPB, TPD, m-MTDATA, Alq3, CuPc, N4, N4,N4′, N4′-tetra(biphenyl-4-yl) biphenyl-4,4′-diamine (TPD15), 4,4′,4″-tris(carbazol sol-9-yl)triphenylamine (TCTA), and/or the like, or an epoxy resin, or acrylate such as methacrylate. However, the embodiment of the present disclosure is not limited thereto, and the capping layer CPL may include at least one selected from among Compounds P1 to P5:

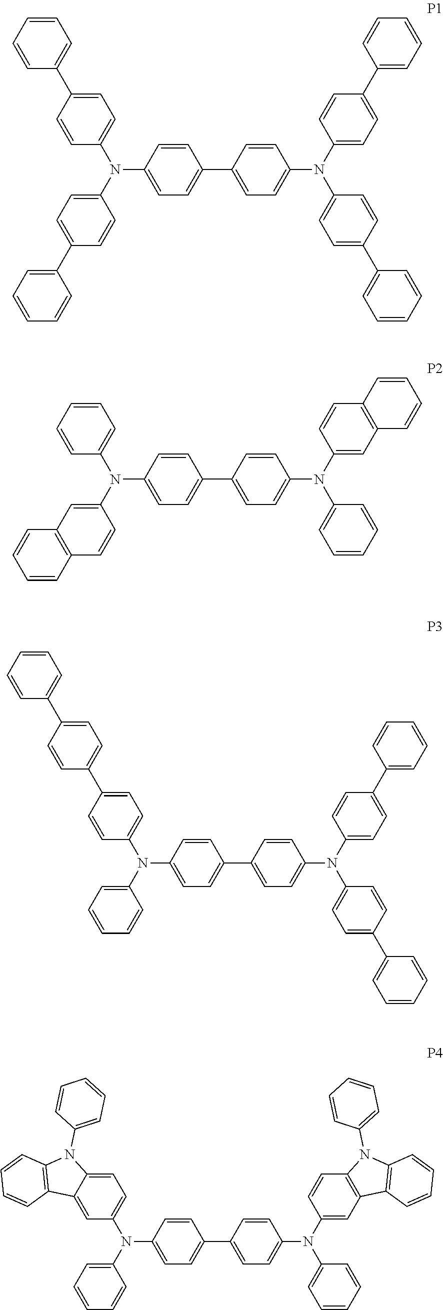 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

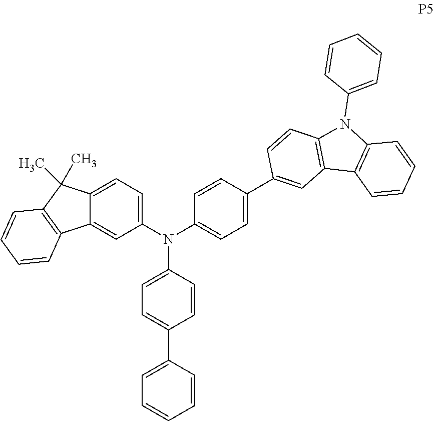 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

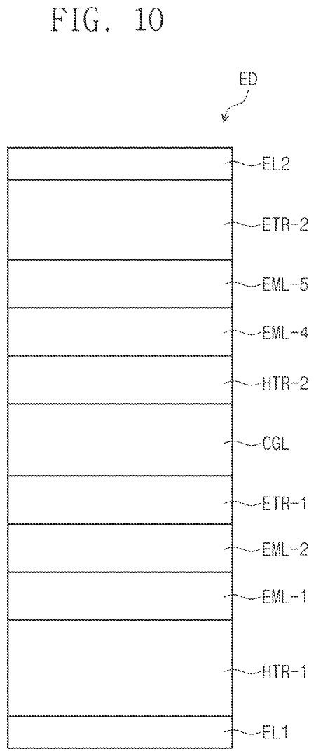

FIGS. 8 to 11 are cross-sectional views schematically illustrating light emitting elements according to other embodiments of the present disclosure. Hereinafter, in the description of FIGS. 8 to 11, the duplicated features which have been described with reference to FIGS. 1 to 7 are not described again, but their differences will be mainly described (e.g., in more detail).

Compared with FIG. 3, the light emitting elements illustrated in FIGS. 8 to 11 have a difference in further including a third emission layer EML-3, a fourth emission layer EML-4 and/or a fifth emission layer EML-5 spaced and/or apart from the first and second emission layers EML-1 and EML-2. FIGS. 8 to 11 may show light emitting elements in a tandem structure.

Referring to FIG. 8, the third emission layer EML-3 may be provided between the second emission layer EML-2 and the second electrode EL2. A charge generation layer CGL may be provided between the second emission layer EML-2 and the second electrode EL2. The charge generation layer CGL may include a p-type or kind charge generation layer and/or an n-type or kind charge generation layer. A third emission layer EML-3 may be provided between the charge generation layer CGL and the second electrode EL2. The third emission layer EML-3 may include the first dopant. For example, the third emission layer EML-3 may include a phosphorescent dopant capable of achieving high efficiency. The difference between the peak emission wavelength of the third emission layer EML-3 including the first dopant and the peak emission wavelength of the second emission layer EML-2 including the second dopant may be about 10 nm or less.

The light emitting element ED illustrated in FIG. 8 may include two hole transport regions HTR-1 and HTR-2 and two electron transport regions ETR-1 and ETR-2. A first hole transport region HTR-1 may be provided between the first electrode EL1 and the first emission layer EML-1, and a second hole transport region HTR-2 may be provided between the charge generation layer CGL and the third emission layer EML-3. A first electron transport region ETR-1 may be provided between the second emission layer EML-2 and the charge generation layer CGL. A second electron transport region ETR-2 may be provided between the third emission layer EML-3 and the second electrode EL2. The light emitting element ED illustrated in FIG. 8 may include the first electrode EL1, the first hole transport region HTR-1, the first emission layer EML-1, the second emission layer EML-2, the first electron transport region ETR-1, the charge generation layer CGL, the second hole transport region HTR-2, the third emission layer EML-3, the second electron transport region ETR-2, and the second electrode EL2, which are sequentially stacked.

The description of the hole transport region HTR as described herein may be equally applied to the first and second hole transport regions HTR-1 and HTR-2. The description of the electron transport region ETR as described herein may be equally applied to the first and second electron transport regions ETR-1 and ETR-2.

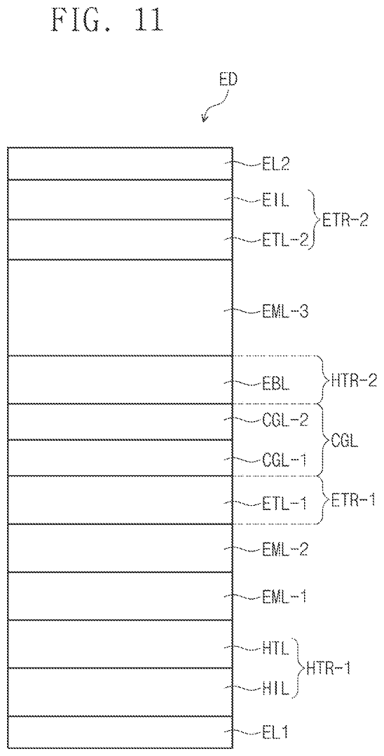

Unlike the light emitting element ED illustrated in FIG. 8, in the light emitting element ED illustrated in FIG. 9, there is a difference in that the third emission layer EML-3 is provided between the first electrode EL1 and the first emission layer EML-1. The third emission layer EML-3 may be provided between the first electrode EL1 and the charge generation layer CGL. The first and second emission layers EML-1 and EML-2 may be provided between the charge generation layer CGL and the second electrode EL2. The third emission layer EML-3 may include the first dopant. The difference between the peak emission wavelength of the third emission layer EML-3 including the first dopant and the peak emission wavelength of the second emission layer EML-2 including the second dopant may be about 10 nm or less. The light emitting element ED illustrated in FIG. 9 may include the first electrode EL1, the first hole transport region HTR-1, the third emission layer EML-3, the first electron transport region ETR-1, the charge generation layer CGL, the second hole transport region HTR-2, the first emission layer EML-1, the second emission layer EML-2, the second electron transport region ETR-2, and the second electrode EL2, which are sequentially stacked.

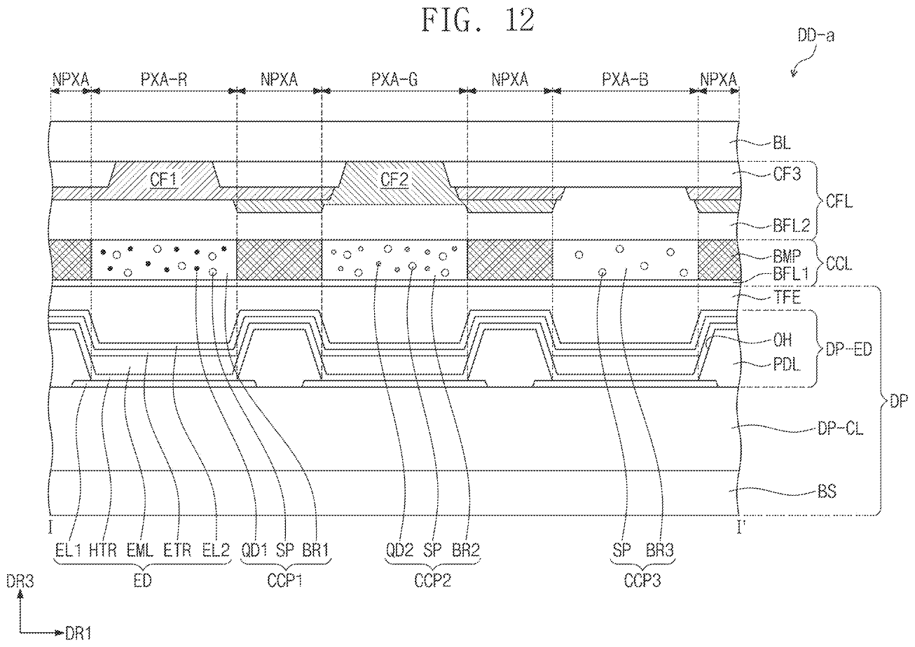

Unlike the light emitting element ED illustrated in FIG. 8, in the light emitting element ED illustrated in FIG. 10, there is a difference in that the fourth emission layer EML-4 and the fifth emission layer EML-5 spaced and/or apart from the first emission layer EML-1 and the second emission layer EML-2 are included. The fifth emission layer EML-5 may be directly provided on the fourth emission layer EML-4, and the fourth emission layer EML-4 may be in contact with the fifth emission layer EML-5. The fourth emission layer EML-4 may correspond to the first emission layer EML-1, and the fifth emission layer EML-5 may correspond to the second emission layer EML-2. The fourth emission layer EML-4 may include the first dopant according to one or more embodiments, and the fifth emission layer EML-5 may include the second dopant according to one or more embodiments. The thickness of the fourth emission layer EML-4 may be about 10% to about 50% based on 100% of the total thickness of the fourth and fifth emission layers EML-4 and EML-5.

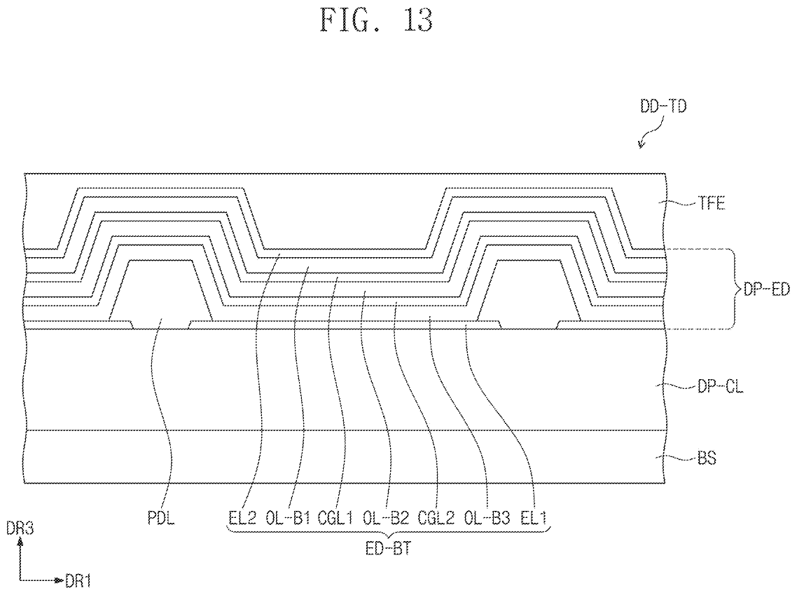

Compared with FIG. 8, FIG. 11 is a cross-sectional view illustrating the light emitting element ED in which the first hole transport region HTR-1 includes the hole injection layer HIL and the hole transport layer HTL, the first electron transport region ETR-1 includes the first electron transport layer ETL-1, the charge generation layer CGL includes a first charge generation layer CGL-1 and a second charge generation layer CGL-2, the second hole transport region HTR-2 includes the electron blocking layer EBL, and the second electron transport region ETR-2 includes a second electron transport layer ETL-2 and the electron injection layer EIL. The first charge generation layer CGL-1 may be an n-type or kind charge (e.g., N-charge) generation layer, and the second charge generation layer CGL-2 may be a p-type or kind charge (e.g., P-charge) generation layer.

The light emitting element ED illustrated in FIG. 11 may include the first electrode EL1, the hole injection layer HIL, the hole transport layer HTL, the first emission layer EML-1, the second emission layer EML-2, the first electron transport layer ETL-1, the first charge generation layer CGL-1, the second charge generation layer CGL-2, the electron blocking layer EBL, the third emission layer EML-3, the second electron transport layer ETL-2, the electron injection layer EIL, and the second electrode EL2, which are sequentially stacked.

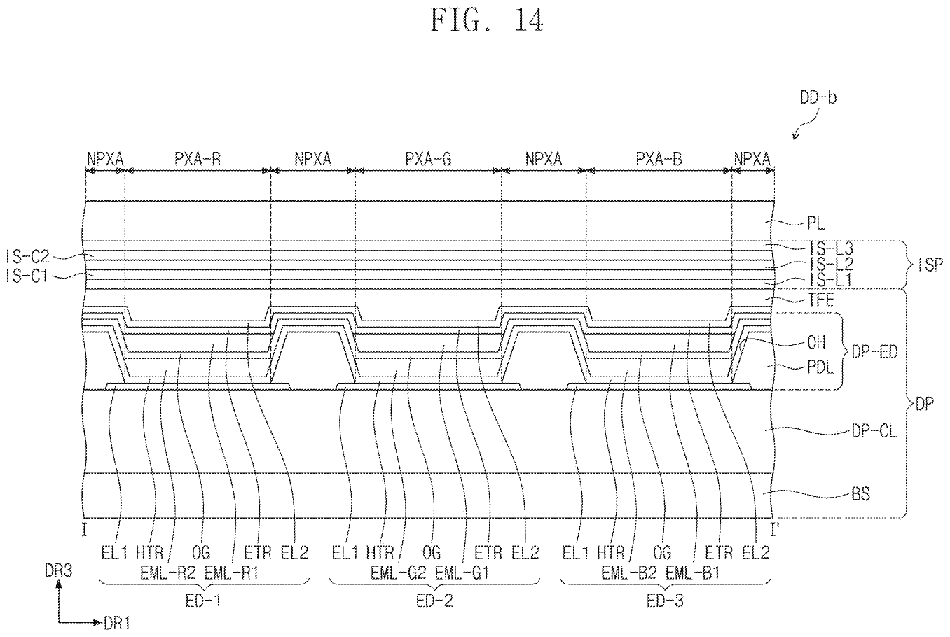

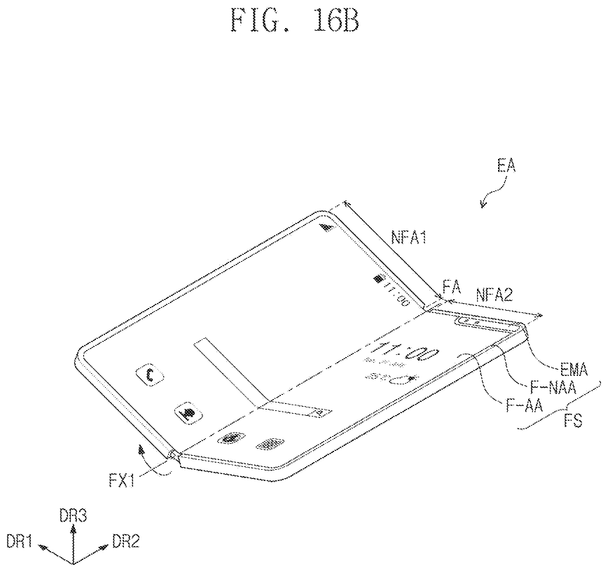

FIGS. 12 to 15 are cross-sectional views illustrating display devices according to embodiments. Hereinafter, in the description of FIGS. 12 to 15, the duplicated features which have been described with reference to FIGS. 1 to 11 are not described again, but their differences will be mainly described.

Referring to FIG. 12, the display device DD-a according to one or more embodiments may include a display panel DP including a display element layer DP-ED, a light control layer CCL provided on the display panel DP, and a color filter layer CFL. In one or more embodiments illustrated in FIG. 12, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. The emission layer EML may be provided in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display device DD-a of one or more embodiments, the emission layer EML may be to emit blue light. In some embodiments, unlike the configuration illustrated, in one or more embodiments, the emission layer EML may be provided as a common layer in the entire light emitting regions PXA-R, PXA-G, and PXA-B.

In some embodiments, the structures of the light emitting elements illustrated in FIGS. 3 to 11 may be equally applied to the structure of the light emitting element ED illustrated in FIG. 8. At least one of the emission layers EML provided corresponding to the light emitting regions PXA-R, PXA-G, and PXA-B, respectively, may include the first emission layer EML-1 (see FIGS. 3 to 11) including the first dopant and the second emission layer EML-2 (see FIGS. 3 to 11) provided on the first emission layer EML-1 (see FIGS. 3 to 11) and including the second dopant. The display device DD-a illustrated in FIG. 12 may include the first emission layer EML-1 (see FIGS. 3 to 11) and the second emission layer EML-2 (see FIGS. 3 to 11) to improve the side-surface luminance ratio and exhibit excellent or suitable display efficiency.

The light control layer CCL may be provided on the display panel DP. The light control layer CCL may be provided on the display element layer DP-ED. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart from each other.

Referring to FIG. 12, divided patterns BMP may be provided between the light control parts CCP1, CCP2 and CCP3 which are spaced and/or apart from each other, but the embodiment of the present disclosure is not limited thereto. FIG. 12 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

The first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described herein may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be provided on the light control parts CCP1, CCP2, and CCP3 to block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In some embodiments, the barrier layers BFL1 and BFL2 may further include an organic film. The barrier layers BFL1 and BFL2 may be formed of a single layer or a plurality of layers.

In the display device DD-a, the color filter layer CFL may be provided on the light control layer CCL. For example, the color filter layer CFL may be directly provided on the light control layer CCL. In this case, the barrier layer BFL2 may not be provided (e.g., may be excluded0.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. The first to third filters CF1, CF2, and CF3 may be provided corresponding to the red light emitting region PXA-R, the green light emitting region PXA-G, and the blue light emitting region PXA-B, respectively.

For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3. In some embodiments, the light shielding part may be formed with a blue filter.

A base substrate BL may be provided on the color filter layer CFL. The base substrate BL may be a member which provides a base surface in which the color filter layer CFL, the light control layer CCL, and/or the like are provided. The base substrate BL may be a glass substrate, a metal substrate, a plastic substrate, and/or the like. However, the embodiment is not limited thereto, and the base substrate BL may be an inorganic layer, an organic layer, or a composite material layer. In some embodiments, unlike the configuration illustrated, in one or more embodiments, the base substrate BL may not be provided.

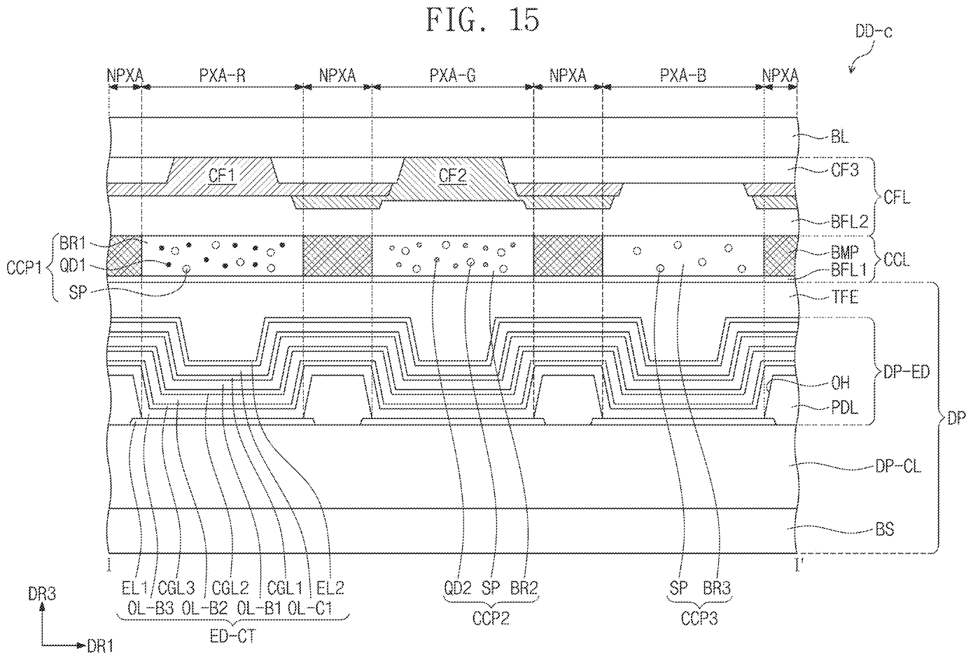

FIG. 13 is a cross-sectional view of a part of a display device DD-TD according to one or more embodiments. In the display device DD-TD of one or more embodiments, the light emitting element ED-BT may include a plurality of light emitting structures OL-B1, OL-B2, and OL-B3. At least one among the plurality of light emitting structures OL-B1, OL-B2, and OL-B3 may include the first emission layer EML-1 (see FIGS. 3 to 11) including the first dopant and the second emission layer EML-2 (see FIGS. 3 to 11) provided on the first emission layer EML-1 (see FIGS. 3 to 11) and including the second dopant.

The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (see FIG. 12) and a hole transport region HTR (see FIG. 12) and an electron transport region ETR (see FIG. 12) spaced and/or apart with the emission layer EML (see FIG. 12) located therebetween. For example, the light emitting element ED-BT included in the display device DD-TD may be a light emitting element having a tandem structure and including a plurality of emission layers.

In one or more embodiments illustrated in FIG. 13, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may be to emit white light.

A charge generation layer CGL may be provided between the neighboring light emitting structures OL-B1, OL-B2, and OL-B3. The charge generation layer CGL may include a p-type or kind charge (e.g., P-charge) generation layer and/or an n-type or kind charge (e.g., N-charge) generation layer.

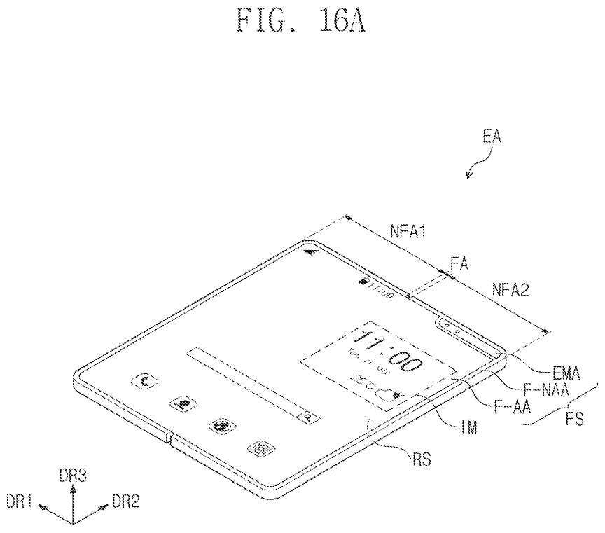

Referring to FIG. 14, the display device DD-b according to one or more embodiments may include light emitting elements ED-1, ED-2, and ED-3 in which two emission layers are stacked. Compared with the display device DD of one or more embodiments illustrated in FIG. 2, one or more embodiments illustrated in FIG. 14 has a difference in that the first to third light emitting elements ED-1, ED-2, and ED-3 each include two emission layers stacked in the thickness direction. In each of the first to third light emitting elements ED-1, ED-2, and ED-3, the two emission layers may be to emit light in substantially the same wavelength region. At least one among two emission layers of each of the light emitting elements ED-1, ED-2, and ED-3 may include the first emission layer EML-1 (see FIGS. 3 to 11) including the first dopant and the second emission layer EML-2 (see FIGS. 3 to 11) provided on the first emission layer EML-1 (see FIGS. 3 to 11) and including the second dopant. For example, the second light emitting element ED-2 may include the first emission layer EML-1 (FIGS. 3 to 11) and the second emission layer EML-2, and at least one among two emission layers EML-G1 and EML-G2 in the second light emitting element ED-2 may include the first emission layer EML-1 (see FIGS. 3 to 11) and the second emission layer EML-2 (see FIGS. 3 to 11).

The first light emitting element ED-1 may include a first red emission layer EML-R₁ and a second red emission layer EML-R₂. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. An emission auxiliary part OG may be provided between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R₁, the first green emission layer EML-G1, and the first blue emission layer EML-B1 may be provided between the emission auxiliary part OG and the electron transport region ETR. The second red emission layer EML-R₂, the second green emission layer EML-G2, and the second blue emission layer EML-B2 may be provided between the hole transport region HTR and the emission auxiliary part OG.

For example, the first light emitting element ED-1 may include the first electrode EL1, the hole transport region HTR, the second red emission layer EML-R₂, the emission auxiliary part OG, the first red emission layer EML-R₁, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display element layer DP-ED. The optical auxiliary layer PL may include a polarizing layer. The optical auxiliary layer PL may be provided on the display panel DP and control reflected light in the display panel DP due to external light. Unlike the configuration illustrated, the optical auxiliary layer PL in the display device according to one or more embodiments may not be provided (e.g., may be excluded).

Unlike FIGS. 13 and 14, FIG. 15 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. At least one among the light emitting structures OL-B1, OL-B2, OL-B3, and OL-C1 may include the first emission layer EML-1 (see FIGS. 3 to 11) including the first dopant and the second emission layer EML-2 (see FIGS. 3 to 11) provided on the first emission layer EML-1 (see FIGS. 3 to 11) and including the second dopant.

Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light beams in different wavelength regions. The charge generation layers CGL1, CGL2, and CGL3 provided between adjacent light emitting structures OL-B1, OL-B2, OL-B3, and OL-C1 may include a p-type or kind charge (e.g., P-charge) generation layer and/or an n-type or kind charge (e.g., N-charge) generation layer.

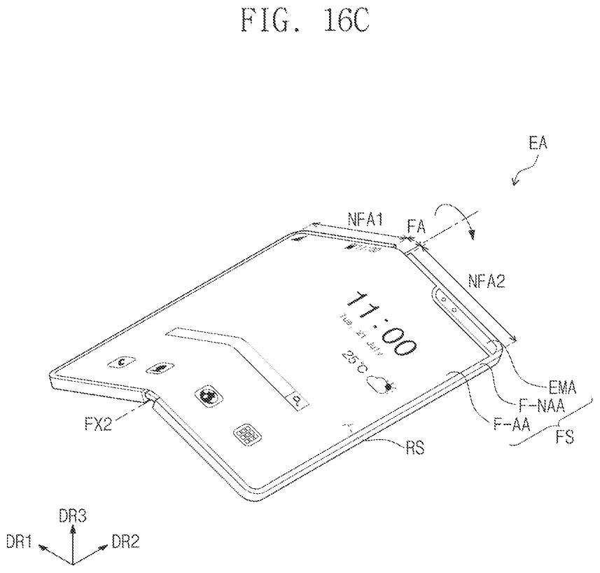

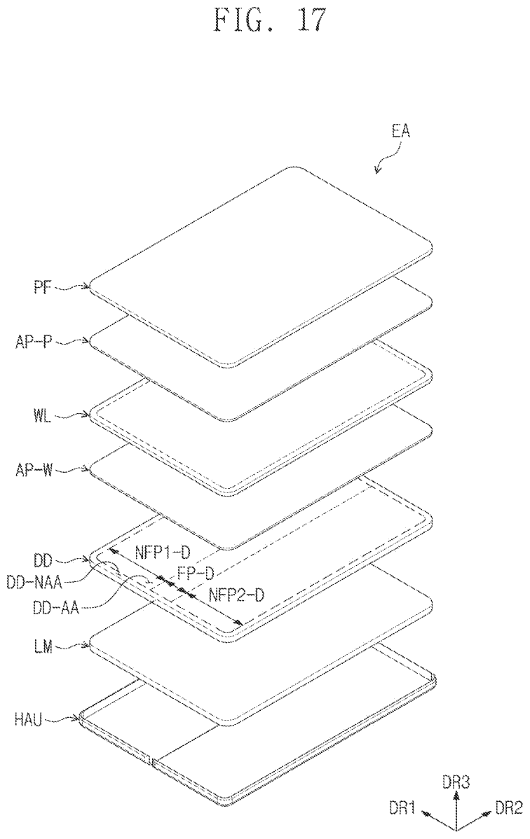

FIGS. 16A to 17 are views illustrating an electronic device EA including a display device according to one or more embodiments. FIG. 16A is a perspective view of an electronic device EA in an unfolded state according to one or more embodiments. FIG. 16B is a perspective view illustrating a folding operation of the electronic device EA according to the embodiment. FIG. 16C is a perspective view illustrating a folding operation of the electronic device EA according to the embodiment. FIG. 17 is an exploded perspective view of the electronic device EA according to the embodiment.

The electronic device EA may be a device that is activated according to an electrical signal. For example, the electronic device EA may be a mobile phone, a tablet, a car navigation device, a game console, or a wearable device, but the embodiment of the present disclosure is not limited thereto. FIG. 16A exemplarily illustrates that the electronic device EA is a mobile phone.

The electronic device EA may include a first display surface FS defined by a first directional axis DR1 and a second directional axis DR2 crossing the first directional axis DR1. The electronic device EA may provide an image IM to a user through the first display surface FS. The electronic device EA may display an image IM towards the direction of a third directional axis DR3 on the first display surface FS parallel to each of the first directional axis DR1 and the second directional axis DR2.

The electronic device EA may include the first display surface FS and a second display surface RS. The first display surface FS include a display region F-AA, a non-display region F-NAA, and an electronic module region EMA. The second display surface RS may be defined as a surface facing at least a part of the first display surface FS. For example, the second display surface RS may be defined as a part of the rear surface of the electronic device EA.

The display region F-AA may be a region which is activated in response to an electrical signal. The display region F-AA may be a region capable of displaying an image IM and sensing one or more suitable forms of external inputs.

The non-display region F-NAA may be adjacent to the display region F-AA. The non-display region F-NAA may have a certain color. The non-display region F-NAA may surround the display region F-AA. Accordingly, the shape of the display region F-AA may be substantially defined by the non-display region F-NAA. However, this is example, and the non-display region F-NAA may be provided adjacent to only one side of the display region F-AA, or may not be provided.

The electronic module region EMA may have one or more suitable electronic modules provided. For example, the electronic module may include at least any one among a camera, a speaker, a light detection sensor, and a heat detection sensor. The electronic module region EMA may detect an external subject received through the display surfaces FS and RS, or provide sound signals such as voice to the outside through the display surfaces FS and RS. The electronic module may include a plurality of components, and is not limited to any one embodiment.

The electronic module region EMA may be surrounded by the non-display region F-NAA. However, this is example, and the embodiment of the present disclosure is not limited thereto. For example, the electronic module region EMA may be surrounded by the display region F-AA and the non-display region F-NAA, and the electronic module region EMA may be provided in the display region F-AA.

The electronic device EA according to one or more embodiments may include at least one folding part FA and a plurality of non-folding parts NFA1 and NFA2 extending from the folding part FA. For example, a first non-folding part NFA1, the folding part FA, and a second non-folding part NFA2 may be defined along the second direction DR2. The electronic device EA may include the first non-folding part NFA1 and the second non-folding part NFA2 spaced and/or apart from each other in the second direction DR2 with the folding part FA located therebetween. For example, the first non-folding part NFA1 may be provided on one side of the folding part FA in the second direction DR2, and the second non-folding part NFA2 may be provided on the other side of the folding part FA in the second direction DR2.

Although FIG. 16A, and/or the like illustrates the electronic device EA including one folding part FA, the embodiment of the present disclosure is not limited thereto, and a plurality of folding parts may be defined in the electronic device EA. For example, the electronic device according to one or more embodiments may include two or more folding parts, and may also include three or more non-folding parts provided with each of the folding parts located therebetween.

Referring to FIG. 16B, the electronic device EA according to one or more embodiments may be folded with respect to a first folding axis FX1 extending in the first direction DR1. While the electronic device EA is folded, the folding part FA may have a set or predetermined curvature and radius of curvature. The electronic device EA may be folded with respect to the first folding axis FX1 to be transformed into an inner-folded state so that the first non-folding part NFA2 and the second non-folding part NFA2 face each other and the first display surface FS is not exposed to the outside.

Referring to FIG. 16C, the electronic device EA according to one or more embodiments may be folded with respect to a second folding axis FX2 extending in the first direction DR1. The electronic device EA may be folded with respect to the second folding axis FX2 and may be transformed into an outer-folded state so that the first display surface FS is exposed to the outside. The electronic device EA may be configured so that in-folding and out-folding operations are repeated from an unfolding operation, but is not limited thereto.

Although FIGS. 16A to 16C illustrate, as one or more examples, folding with respect to one folding axis FX1 or FX2, the number of folding axes and the number of non-folding parts according thereto are not limited thereto. For example, the electronic device may be folded with respect to a plurality of folding axes, and thus may be folded so that a part of each of the first display surface FS and the second display surface RS faces each other. In some embodiments, although the first and second folding axes FX1 and FX2 are illustrated as being parallel to the long side of the electronic device EA, the embodiment of the present disclosure is not limited thereto, and the first and second folding axes FX1 and FX2 may be parallel to the short side of the electronic device EA.

In the electronic device EA, the first non-folding part NFA1 and the second non-folding part NFA2 may be defined as parts having display surfaces FS and RS parallel to a plane defined by the first directional axis DR1 and the second directional axis DR2 in a folded state, and the folding part FA may be defined as a region between the first non-folding part NFA1 and the second non-folding part NFA2. The folding part FA may include a curved part bent so as to have a set or predetermined curvature in the folded state.

The electronic device EA may be a flexible device including the display device DD (see FIGS. 1 and 17) according to one or more embodiments. Although FIGS. 16A to 16C illustrate a flexible device capable of folding and unfolding, the operation of the electronic device EA is not limited thereto. For example, the electronic device EA may be a flexible device capable of rolling, sliding, and/or the like. The flexible device may be visually recognized by a user from one or more suitable angles. The electronic device EA including the display device DD according to one or more embodiments may achieve excellent or suitable display quality not only in the front surface but also in the side surface. The electronic device EA may include the first emission layer EML-1 (see FIGS. 3 to 11) including the first dopant and the second emission layer EML-2 (see FIGS. 3 to 11) provided on the first emission layer EML-1 (see FIGS. 3 to 11) and including the second dopant. Accordingly, the electronic device EA may have improved side-surface luminance ratio and exhibit excellent or suitable display efficiency.

Referring to FIG. 17, the electronic device EA may include a lower module LM, a display device DD provided on the lower module LM, a window WL provided on the display device DD, and a protective layer PF provided on the window WL. In some embodiments, the electronic device EA may further include a housing HAU.

The housing HAU may include a material having a relatively higher or greater rigidity. For example, the housing HAU may include a plurality of frames and/or plates formed of glass, plastic, or metals. The housing HAU may provide a certain accommodating space. The display device DD may be accommodated in an accommodating space and be protected from an external impact.

The lower module LM may include a support member, a digitizer, a cushion layer, a shielding layer, and/or the like. The support member may be provided in plurality. The support member may include a metal material or a polymer material. For example, the support member may be formed including stainless steel, aluminum, or an alloy thereof, or may be formed of carbon fiber reinforced plastic (CFRP), and/or the like. The cushion layer may include an elastomer such as sponge, foam, or a urethane resin. The shielding layer may be an electromagnetic wave shielding layer or a heat dissipating layer.

An active region DD-AA and a peripheral region DD-NAA may be defined in the display device DD. The active region DD-AA may correspond to at least a part of the display region F-AA (see FIG. 16A). The display device DD may include a folding region FP-D and first and second non-folding regions NFP1-D and NFP2-D adjacent to the folding region FP-D. The first non-folding region NFP1-D and the second non-folding region NFP2-D may be spaced and/or apart from each other with the folding region FP-D located therebetween. The folding region FP-D may correspond to the folding part FA (see FIG. 16A), the first non-folding region NFP1-D may correspond to the first non-folding part NFA1 (see FIG. 16A), and the second non-folding region NFP2-D may correspond to the second non-folding part NFA2 (see FIG. 16A). As illustrated in FIGS. 16B and 16C, when the electronic device EA is folded, the folding region FP-D may be folded with respect to the first and second folding axes FX1 and FX2.

The window WL may include a polymer substrate or glass substrate. For example, the window WL may include a glass substrate. The image IM (see FIG. 16A) generated in the display device DD may be transmitted through the window WL to be provided to a user. For example, the window WL may include ultra-thin glass (UTG).

The protective layer PF may be a functional layer that protects one surface of the window WL. The protective layer PF may include an anti-fingerprint coating agent, a hard coating agent, an antistatic agent, and/or the like.

The electronic device EA may further include a window adhesive layer AP-W and a protective-layer adhesive layer AP-P. The window adhesive layer AP-W may be provided between the display device DD and the window WL. The display device DD and the window WL may be coupled by the window adhesive layer AP-W. The protective-layer adhesive layer AP-P may be provided between the window WL and the protective layer PF. The window WL and the protective layer PF may be coupled by the protective-layer adhesive layer AP-P.

The window adhesive layer AP-W and the protective-layer adhesive layer AP-P may include a typical adhesive or pressure adhesive. For example, the window adhesive layer AP-W and the protective-layer adhesive layer AP-P may include a pressure sensitive adhesive (PSA), an optically clear adhesive film (OCA) or an optically clear adhesive resin layer (OCR). However, this is example, and the embodiment of the present disclosure is not limited thereto. Unlike the configuration illustrated, at least one among the window adhesive layer AP-W or the protective-layer adhesive layer AP-P may not be provided.

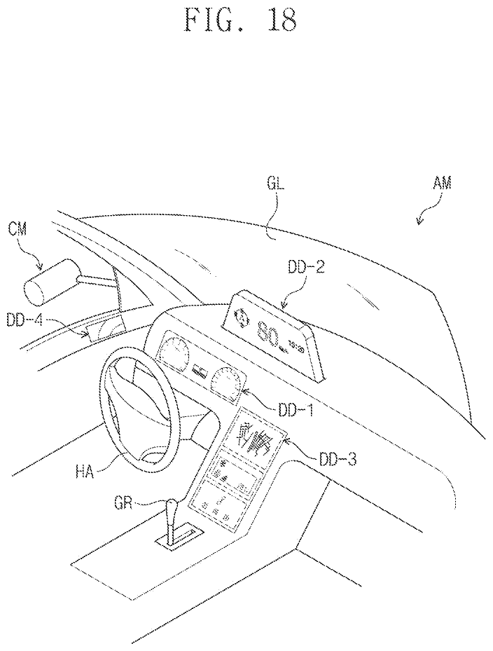

FIG. 18 is a view illustrating a vehicle AM in which first to fourth display devices DD-1, DD-2, DD-3, and DD-4 are provided. At least one among the first to fourth display devices DD-1, DD-2, DD-3, and DD-4 may include the same configuration as the display devices DD, DD-TD, DD-a, DD-b, and DD-c as described with reference to FIGS. 1, and 2, and 12 to 15.

FIG. 18 illustrates a vehicle AM, but this is an example, and the first to fourth display devices DD-1, DD-2, DD-3, and DD-4 may be provided in another transportation refers to such as bicycles, motorcycles, trains, ships, and airplanes. In some embodiments, at least one among the first to fourth display devices DD-1, DD-2, DD-3, and DD-4 including the same configuration as the display devices DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other electronic apparatuses unless departing from the present disclosure.

At least one among the first to fourth display devices DD-1, DD-2, DD-3, and DD-4 may include the light emitting element ED as described with reference to FIGS. 3 to 11. At least one among the light display devices DD-1, DD-2, DD-3, and DD-4 may include the first emission layer EML-1 (see FIGS. 3 to 11) including the first dopant and the second emission layer EML-2 (see FIGS. 3 to 11) provided on the first emission layer EML-1 (see FIGS. 3 to 11) and including the second dopant. As illustrated in FIG. 18, the first to fourth display devices DD-1, DD-2, DD-3, and DD-4 are provided in one or more suitable positions in the vehicle AM, and may be viewed by a user in one or more suitable angles. The first to fourth display devices DD-1, DD-2, DD-3, and DD-4 including the first emission layer EML-1 and the second emission layer EML-2 may achieve excellent or suitable display quality in the side surface as well as in the front surface. The first to fourth display devices DD-1, DD-2, DD-3, and DD-4 including the first emission layer EML-1 and the second emission layer EML-2 may have improved side-surface luminance ratio and exhibit excellent or suitable display quality.

Referring to FIG. 18, the vehicle AM may include a steering wheel HA and a gear GR for driving the vehicle AM, and a front window GL may be provided so as to face the driver.

The first display device DD-1 may be provided in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display device DD-2 may be provided in a second region facing the driver's seat and overlapping the front window GL. The driver's seat may be a seat in which the steering wheel HA is provided. For example, the second display device DD-2 may be a head up display (HUD) which displays second information of the vehicle AM. The second display device DD-2 may be optically transparent. The second information may include digital numbers which indicate a driving speed, and may further include information such as the current time. Unlike the configuration illustrated, the second information of the second display device DD-2 may be projected to the front window GL to be displayed.

The third display device DD-3 may be provided in a third region adjacent to the gear GR. For example, the third display device DD-3 may be provided between the driver's seat and the passenger seat and may be a center information display (CID) for a vehicle for displaying third information. The passenger seat may be a seat spaced and/or apart from the driver's seat with the gear GR provided therebetween. The third information may include information about traffic (e.g., navigation information), playing music or radio, playing video, temperatures inside the vehicle AM, and/or the like.

The fourth display device DD-4 may be spaced and/or apart from the steering wheel HA and the gear GR, and may be provided in a fourth region adjacent to the side of the vehicle AM. For example, the fourth display device DD-4 may be a digital side-view mirror which displays fourth information. The fourth display device DD-4 may display an image outside the vehicle AM taken by a camera module CM provided outside the vehicle AM. The fourth information may include an image outside the vehicle AM.

The herein-described first to fourth information may be examples, and the first to fourth display devices DD-1, DD-2, DD-3, and DD-4 may further display information about the inside and outside of the vehicle. The first to fourth information may include different information. However, the embodiment of the present disclosure is not limited thereto, and a part of the first to fourth information may include the same information as one another.

The display device of one or more embodiments may include the light emitting element, and the light emitting element may include the first emission layer and the second emission layer. The first emission layer may include the first dopant, and the second emission layer may include the second dopant different from the first dopant. The second emission layer may be provided on the first emission layer. The triplet excited state energy level of the second dopant may be higher or greater than that of the first dopant. The thickness of the first emission layer may be about 10% to about 50% based on 100% of the total thickness of the first and second emission layers. Accordingly, the display device of one or more embodiments may have improved side-surface luminance ratio and exhibit excellent or suitable display efficiency.

The display device of one or more embodiments includes a first emission layer having a specific thickness and including a first dopant, and a second emission layer including a second dopant having the triplet excited state energy level higher or greater than the first dopant, thereby improving a ratio of luminance in the side surface thereof and exhibiting excellent or suitable display efficiency.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the device and/or element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalents thereof.

What is claimed is:

1. A display device, the display device comprising
a circuit layer and
a display element layer which is on the circuit layer and comprises a light emitting element,
wherein the light emitting element comprises:
a first electrode;
a first emission layer which comprises a first dopant and is on the first electrode;
a second emission layer which comprises a second dopant different from the first dopant and is on the first emission layer; and
a second electrode on the second emission layer, and
wherein a triplet excited state energy level of the second dopant is higher than a triplet excited state energy level of the first dopant, and
a thickness of the first emission layer is about 10% to about 50% based on 100% of a sum of the thickness of the first emission layer and a thickness of the second emission layer.

2. The display device of claim 1, wherein the second emission layer is directly on the first emission layer.

3. The display device of claim 1, wherein a difference between the triplet excited state energy level of the second dopant and the triplet excited state energy level of the first dopant is at most about 0.15 electron volt (eV).

4. The display device of claim 1, wherein the triplet excited state energy level of the first dopant is about 2.05 eV to about 2.25 eV.

5. The display device of claim 1, wherein the triplet excited state energy level of the second dopant is about 2.26 eV to about 2.35 eV.

6. The display device of claim 1, wherein a peak emission wavelength of the first dopant is longer than a peak emission wavelength of the second dopant.

7. The display device of claim 6, wherein a difference between the peak emission wavelength of the first dopant and the peak emission wavelength of the second dopant is at most about 10 nanometer (nm).

8. The display device of claim 6, wherein the peak emission wavelength of the first dopant is about 520 nm to about 570 nm.

9. The display device of claim 6, wherein the peak emission wavelength of the second dopant is about 500 nm to about 560 nm.

10. The display device of claim 1, wherein a highest occupied molecular orbital (HOMO) energy level of the first dopant is greater than a highest occupied molecular orbital (HOMO) of the second dopant.

11. The display device of claim 1, wherein a difference between a HOMO energy level of the first dopant and a HOMO energy level of the second dopant is at most about 0.25 eV.

12. The display device of claim 1, wherein a HOMO energy level of the first dopant is about −4.5 eV to about −4.4 eV.

13. The display device of claim 1, wherein a HOMO energy level of the second dopant is about −4.7 eV to about −4.55 eV.

14. The display device of claim 1, wherein an overlap degree of an emission spectrum of the first dopant and a spectrum tristimulus value is greater than an overlap degree of an emission spectrum of the second dopant and the spectrum tristimulus value.

15. The display device of claim 1, wherein at least one of the first dopant or the second dopant comprises a metal complex compound comprising platinum (Pt) as a central metal.

16. The display device of claim 1, wherein a first one of the first dopant or the second dopant comprises a first metal complex compound comprising platinum (Pt) as a central metal, and a second one of the first dopant or the second dopant comprises a second metal complex compound comprising platinum (Pt), iridium (Ir), titanium (Ti), cobalt (Co), copper (Cu), zinc (Zn), zirconium (Zr), ruthenium (Ru), rhodium (Rh), palladium (Pd), rhenium (Re), gold (Au), or osmium (Os) as a central metal.

17. The display device of claim 1, wherein the first dopant comprises a compound represented by Formula DA-1: 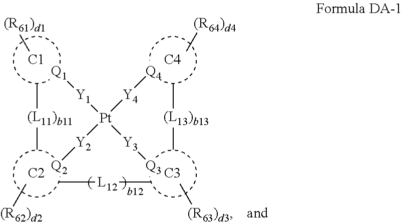
wherein, in Formula DA-1,
Q₁ to Q₄ are each independently C or N,
C1 to C4 are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
Y₁ to Y₄ are each independently a direct linkage, *—O—*, *—S—*, a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
L₁₁ to L₁₃ are each independently a direct linkage, *—O—*, *—S—*, 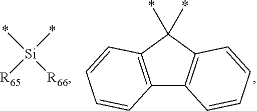
a substituted or unsubstituted divalent amine group, a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring, and
d1 to d4 are each independently an integer of 0 to 4.

18. The display device of claim 1, wherein the light emitting element further comprises:
a charge generation layer between the first electrode and the first emission layer; and
a third emission layer between the first electrode and the charge generation layer, and
a difference between a peak emission wavelength of the third emission layer and a peak emission wavelength of the second emission layer is at most about 10 nm.

19. The display device of claim 1, wherein the light emitting element further comprises:
a charge generation layer between the second emission layer and the second electrode; and
a third emission layer between the charge generation layer and the second electrode, and
a difference between a peak emission wavelength of the third emission layer and a peak emission wavelength of the second emission layer is at most about 10 nm.

20. The display device of claim 1, wherein a side-surface luminance ratio is at least about 41.

21. The display device of claim 1, wherein the display device comprises at least one folding axis and the display device is divided into a folding region which is foldable with respect to the at least one folding axis and a non-folding region adjacent to the folding region.

22. A display device, the display device comprising
a circuit layer and
a display element layer which is on the circuit layer and comprises
a first light emitting element,
a second light emitting element, and
a third light emitting element spaced apart in one direction perpendicular to a thickness direction,
wherein the first light emitting element is to emit a first light, the second light emitting element is to emit a second light having a wavelength shorter than a wavelength of the first light, and the third light emitting element is to emit a third light having a wavelength shorter than the wavelength of the second light,
the second light emitting element comprises:
a first electrode;
a first emission layer which comprises a first dopant and is on the first electrode;
a second emission layer which comprises a second dopant different from the first dopant and is on the first emission layer; and
a second electrode on the second emission layer,
wherein a triplet excited state energy level of the second dopant is higher than a triplet excited state energy level of the first dopant, and
a thickness of the first emission layer is about 10% to about 50% based on 100% of a sum of the thickness of the first emission layer and a thickness of the second emission layer.

23. The display device of claim 22, wherein a side-surface luminance ratio is at least about 41.
